(19) United States
(12) Patent Application Publication
(10) Pub. No.: US 2026/0006960 A1
(43) Pub. Date: Jan. 1, 2026

(54) PANEL RELEASE SYSTEM AND A METHOD OF OPERATING THE SAME

(71) Applicant: PYXIS CF PTE. LTD., Singapore (SG)

(72) Inventor: AMLAN SEN, Singapore (SG)

(21) Appl. No.: 19/249,002

(22) Filed: Jun. 25, 2025

(30) Foreign Application Priority Data
Jun. 26, 2024 (SG) 10202401897T

(51) Int. Cl. H10H 29/03; H01L 25/075; H10H 29/02

(52) U.S. Cl. CPC H10H 29/03; H01L 25/0753; H10H 29/02

(57) ABSTRACT

There may be provided a release workstation, processing or panel release system including the release workstation, and methods of operating the same. The processing or panel release system may include a carrier-support deck having a deck surface capable of supporting an intermediate panel-carrier assembly thereon, and a release-heater associated with the deck surface and operable to heat the intermediate panel-carrier assembly to a heat release temperature. The release workstation may include a release unit having a release-head movable towards the deck surface of the carrier-support deck to engage a molded panel of the intermediate panel-carrier assembly on the deck surface. The release-head may include a retaining member configured to releasably retain the molded panel to an engagement surface of the release-head. The release-head may further be movable away from the deck surface of the carrier-support deck, with the retaining member of the release-head releasably retaining the molded panel.

### CROSS REFERENCES TO RELATED APPLICATIONS

The present application claims the benefit of the Singapore patent application Ser. No. 10202401897T filed on 26 Jun. 2024. The entire content of the application is incorporated herein by reference in its entirety and for all purposes.

### FIELD OF THE INVENTION

The present disclosure relates to a field of semiconductor technologies; and particularly to a panel release system and a method of operating the same for processing an intermediate panel-carrier assembly including a molded panel and a carrier. The panel release system includes a release workstation for releasing the molded panel from the carrier.

### BACKGROUND OF THE INVENTION

In a typical panel-level packaging process, electronic elements, such as dies, wafers, passive components and metallic components are mounted onto a first carrier and molded in a first molding process into a molded panel on the first carrier. The molded panel containing the electronic elements is then released from the first carrier, and further mounted on a second carrier in a flipped manner so as to expose the active surface of the electronic elements in order for circuits to be formed on the active surface of the electronic elements. Finally, the molded panel and the formed circuits are molded in a second molding process and then released from the second carrier.

Conventionally, in a panel release process from a carrier, the molded panel is released by means of heat or ultraviolet (UV) light. These are the two main methods of releasing the molded panel.

In order to utilize the UV light method for releasing the molded panel, glass carrier has to be used. Accordingly, a glass carrier is laminated with a UV release tape. Silicon chips or wafers are then assembled over the UV release tape on the glass carrier. The glass carrier is then molded to form the molded panel on the glass carrier. To release the molded panel, UV light is shined through the back of the glass carrier to release the UV release tape for separating the molded panel from the glass carrier. However, the UV light method is not ideal because glass is expensive, fragile and sensitive to a lot of processes in the panel-level packaging process. Further, usage of glass carrier would limit the size of the carrier as industry players are generally reluctant to adopt usage of large size glass carrier due to its fragile nature. Furthermore, the use of glass carrier also requires some manual delicate handling during the release and transfer process as glass is fragile. For example, during separating of the glass carrier from the molded panel and removing the UV release tap. Such manual process of separation and removal may be prone to electrostatic discharge which contributes to significant failures in panel-level packaging process.

To utilize the heat method for releasing the molded panel, the conventional glass carrier is typically laminated with heat release tape instead of the UV release tape. Electronic elements, such as die, wafer, passive component and metallic component are then assembled over the heat release tape on the glass carrier. The glass carrier is then molded to form the molded panel on the glass carrier. To release the molded panel, heat is applied to the glass to release the heat release tape for separating the molded panel from the glass carrier. However, direct heat exposure to the glass carrier may damage the glass carrier. Heating through the glass carrier may also cause uncontrolled warpage of the molded panel. Further, similar to the UV method, the usage of glass carrier would limit the size of the carrier, and require some manual delicate handling during the release and transfer process as glass is fragile. Furthermore, such manual process of separation and removal may be prone to electrostatic discharge which contributes to significant failures in panel-level packaging process.

Accordingly, there is a need for a more effective panel release system and a method thereof so as to address the above issues, particularly for releasing the molded panel with the formed circuits from the second carrier after the second molding process.

### SUMMARY OF THE INVENTION

The present invention provides a release workstation for processing an intermediate panel-carrier assembly. The release workstation may include a carrier-support deck having a deck surface capable of supporting the intermediate panel-carrier assembly thereon, the intermediate panel-carrier assembly having a molded panel attached to a carrier via a thermal release adhesive tape, and a release-deck-heater associated with the deck surface and operable to heat the intermediate panel-carrier assembly to a heat release temperature of the thermal release adhesive tape of the intermediate panel-carrier assembly, when the intermediate panel-carrier assembly is supported on the deck surface. The release workstation may further include a release unit including a release-head movable towards the deck surface of the carrier-support deck to engage the molded panel of the intermediate panel-carrier assembly on the deck surface, for which, the release-head may include a release-head-retaining member configured to releasably retain the molded panel to an engagement surface of the release-head, when the release-head is moved to engage with the separated molded panel, for which, the release-head may be further movable away from the deck surface of the carrier-support deck, with the release-head-retaining member of the release-head releasably retaining the molded panel to the engagement surface of the release-head, after the release-deck-heater of the carrier-support deck has heated the intermediate panel-carrier assembly to the heat release temperature, thereby separating the molded panel from the carrier such that the separated molded panel is at the engagement surface of the release-head and the carrier with the thermal release adhesive tape on the deck surface of the carrier-support deck.

According to various embodiments, there may be provided a processing system (e.g. panel release system) for processing the intermediate panel-carrier assembly. The processing system (e.g. panel release system) may include the release workstation and a panel-handling workstation capable of receiving the separated molded panel from the release workstation. The panel-handling workstation may include a panel-support deck which may be movable between the panel-handling workstation and the release workstation, for which, when the panel-support deck is positioned within the release workstation to align with the release-head of the release unit of the release workstation, the release-head may be operable to release the separated molded panel onto the panel-support deck, for which, with the separated molded panel released onto the panel-support deck at the release workstation, the panel-support deck may be operable to be moved from the release workstation to the panel-handling workstation, thereby conveying the separated molded panel from the release workstation to the panel-handling workstation. The panel-handling workstation may further include a panel-handling unit having a panel-handling head which may be movable towards the panel-support deck, when the panel-support deck is within the panel-handling workstation with the separated molded panel thereon, to engage the separated molded panel. The panel-handling head may include a panel-handling-head-retaining member configured to releasably retain the separated molded panel to an engagement surface of the panel-handling head of the panel-handling unit, when the panel-handling-head is moved to engage with the separated molded panel, and moving the separated molded panel, releasably retained thereto, away from the panel-support deck for transferring the separated molded panel out of the processing system (e.g. panel release system).

According to various embodiments, there may be provided a method of operating the processing system (e.g. panel release system). The method may include heating, via the release-deck-heater associated with the deck surface of the carrier-support deck, the intermediate panel-carrier assembly, when the intermediate panel-carrier assembly is supported on the deck surface of the carrier-support deck, for which, the intermediate panel-carrier assembly may be heated to the heat release temperature of the thermal release adhesive tape. The method may further include moving the release-head of the release unit of the release workstation towards the deck surface of the carrier-support deck to engage the intermediate panel-carrier assembly on the deck surface of the carrier-support deck, when the carrier-support deck is aligned with the release-head within the release workstation, and releasably retaining the molded panel to the engagement surface of the release-head. The method may further include moving the release-head with the molded panel releasably retained thereto, away from the deck surface of the carrier-support deck, after the release-deck-heater of the carrier-support deck has heated the intermediate panel-carrier assembly to the heat release temperature, thereby separating the molded panel from the carrier such that the separated molded panel is at the engagement surface of the release-head and the carrier with the thermal release adhesive tape on the deck surface of the carrier-support deck.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1A and FIG. 1B shows schematically a release workstation of a processing system, according to various embodiments; and FIG. 1S and FIG. 1T are exploded views of elements 102 and 104, respectively, of FIG. 1A;

FIG. 1C and FIG. 1D show schematically the processing system having the release workstation of FIG. 1A, together with a panel-handling workstation and a carrier-handling workstation, according to various embodiments;

FIG. 1E shows schematically the processing system having an offload workstation linked to the carrier-handling workstation of FIG. 1C and FIG. 1D, according to various embodiments;

FIG. 1F shows schematically the processing system having the offload workstation linked directly to the release workstation, according to various other embodiments;

FIG. 1G to FIG. 1J show schematically an adhesive-removal tool in operation, according to various embodiments;

FIG. 1K to FIG. 1N show schematically another mode of operation of the adhesive-removal tool, according to various other embodiments;

FIG. 10 and FIG. 1P show schematically a mechanism for operating the adhesive-removal tool, according to various embodiments;

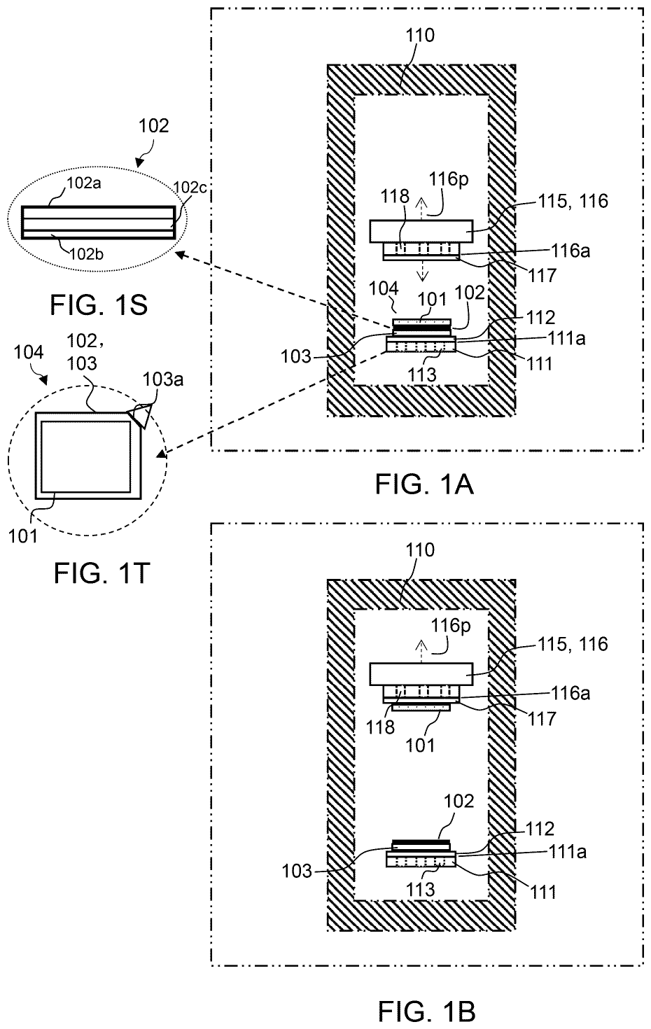

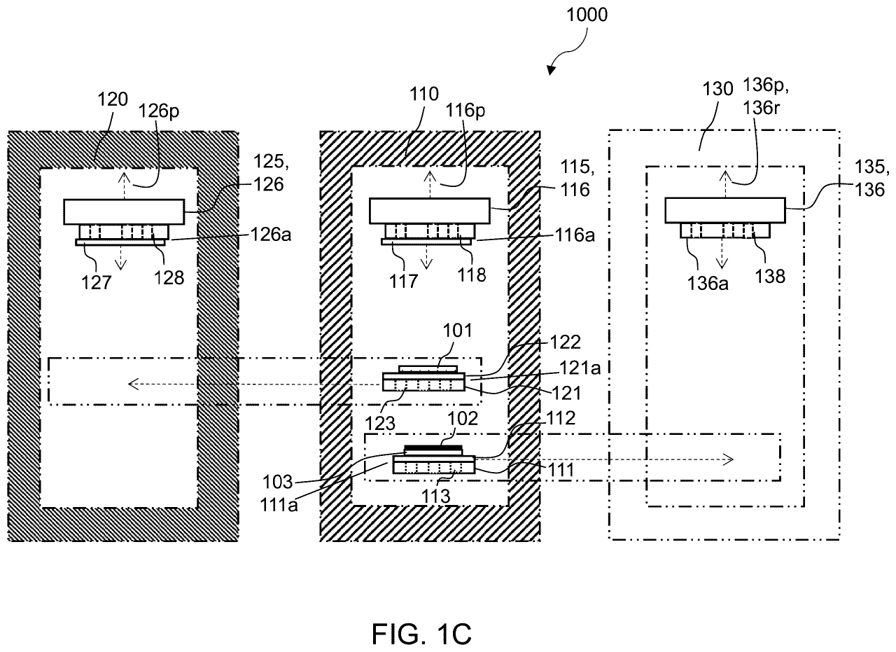

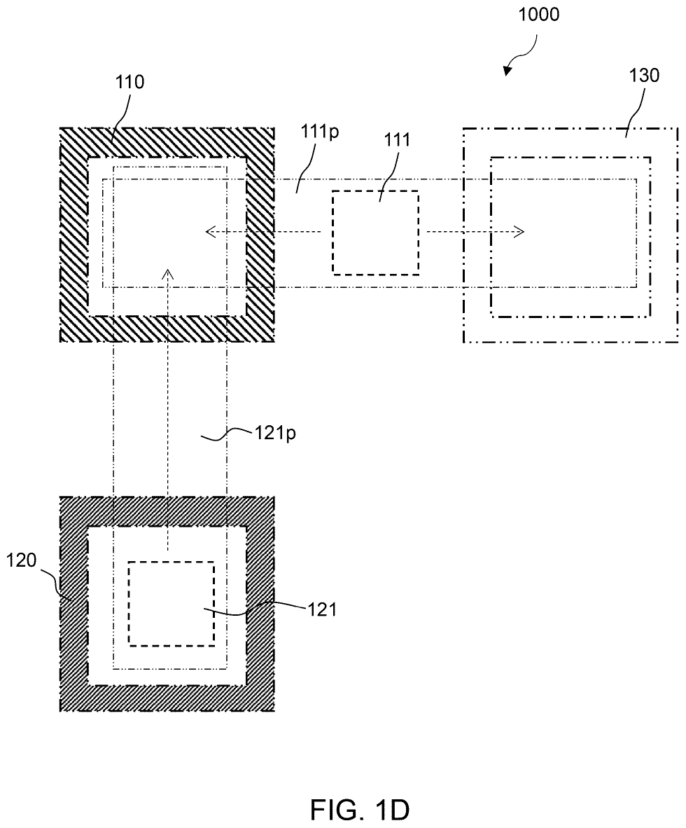

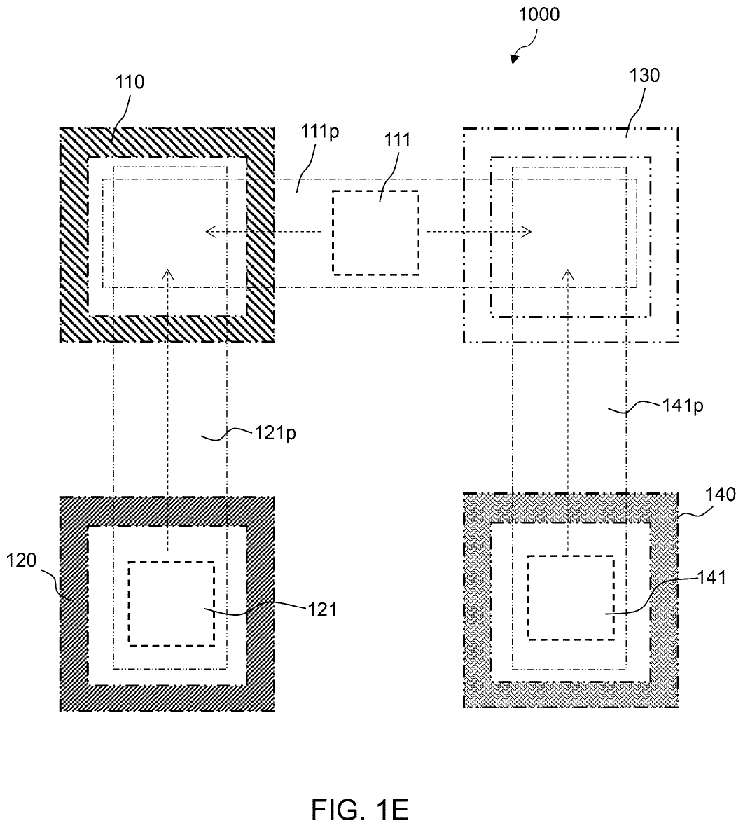

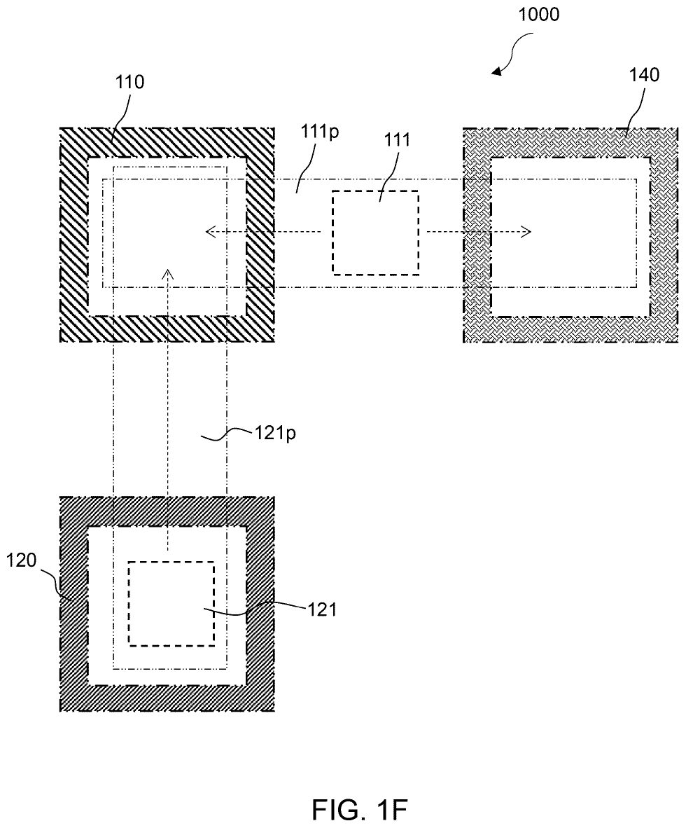

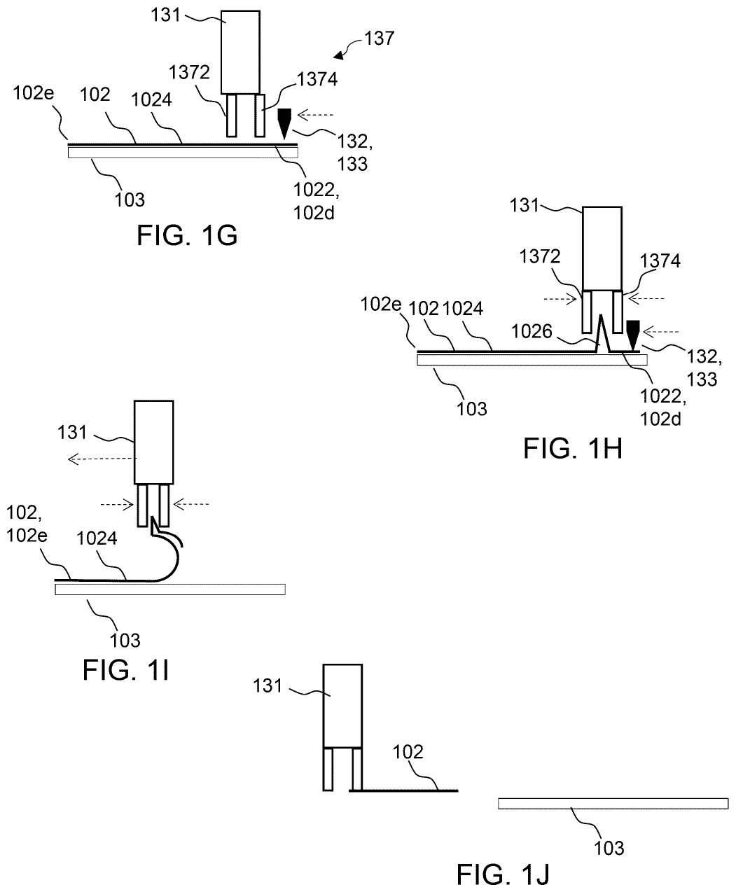

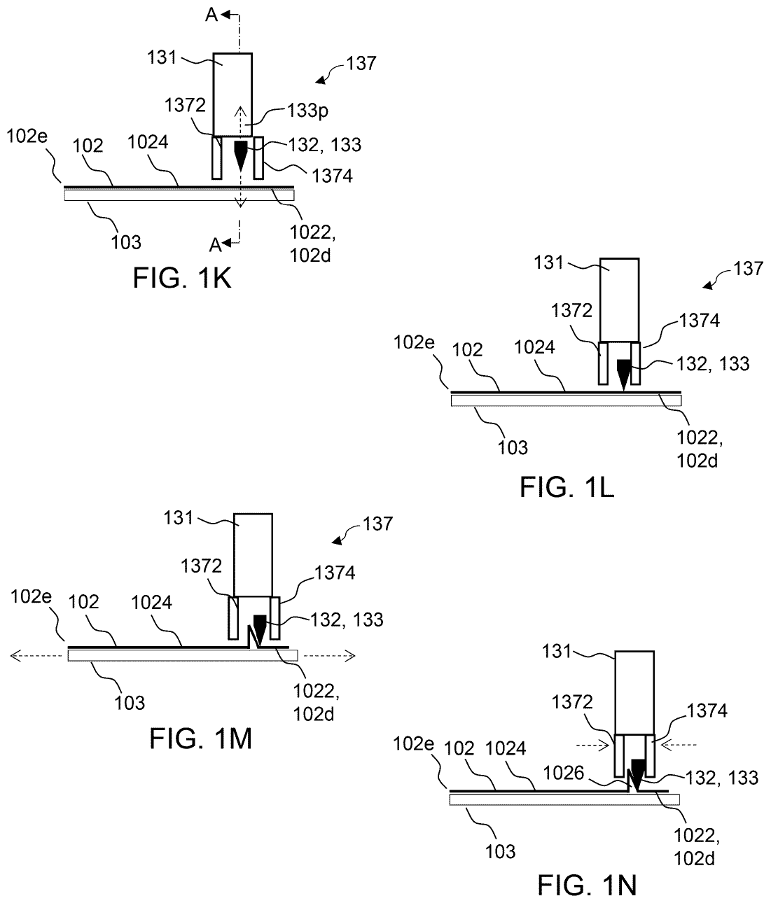

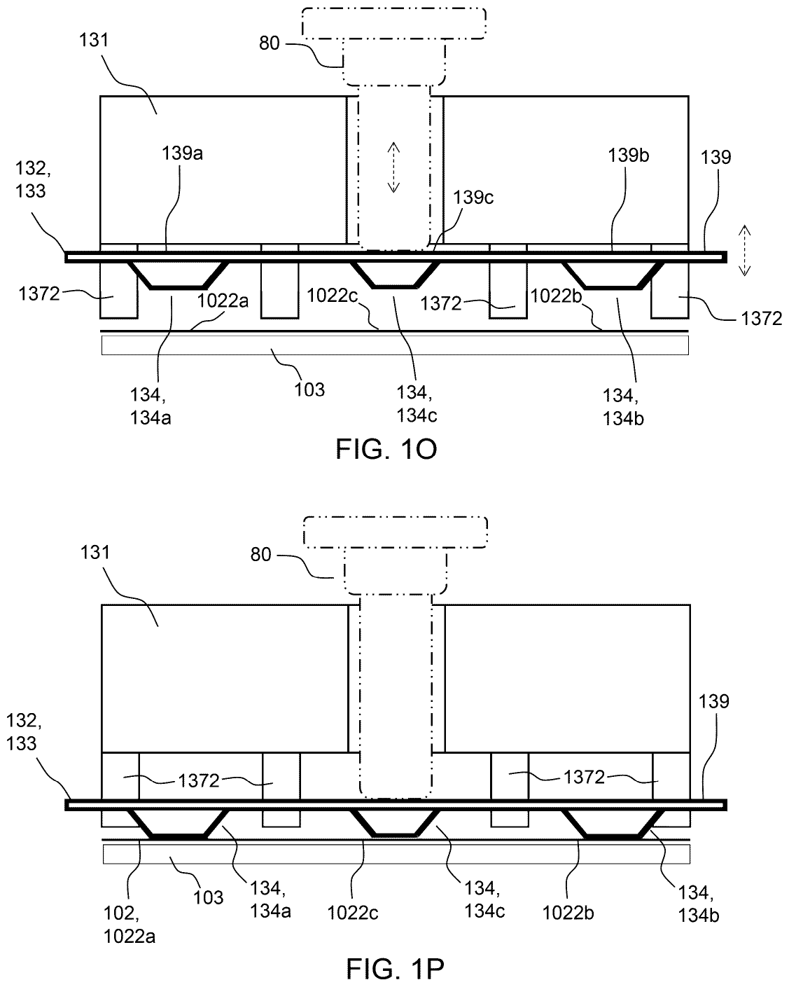

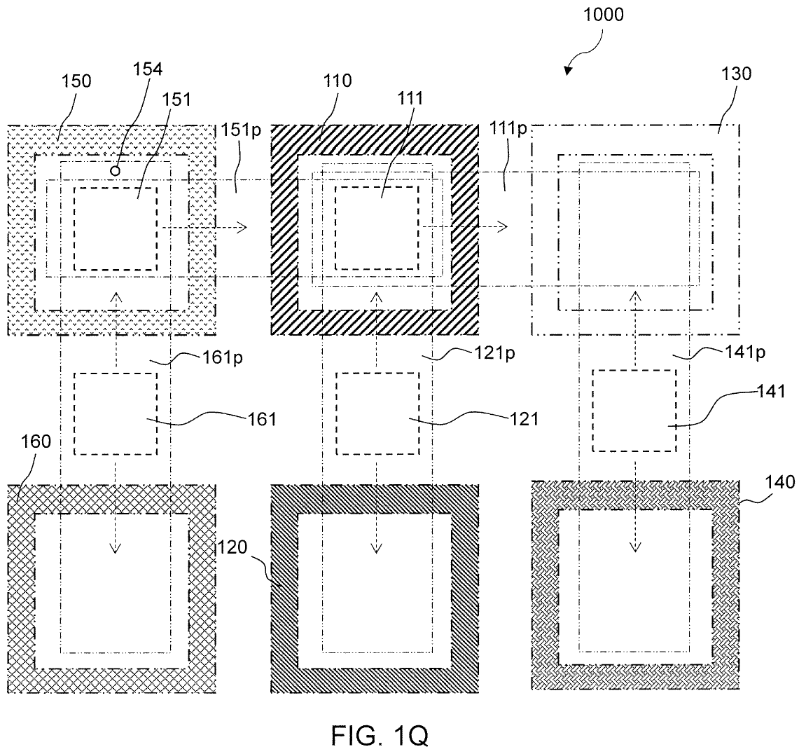

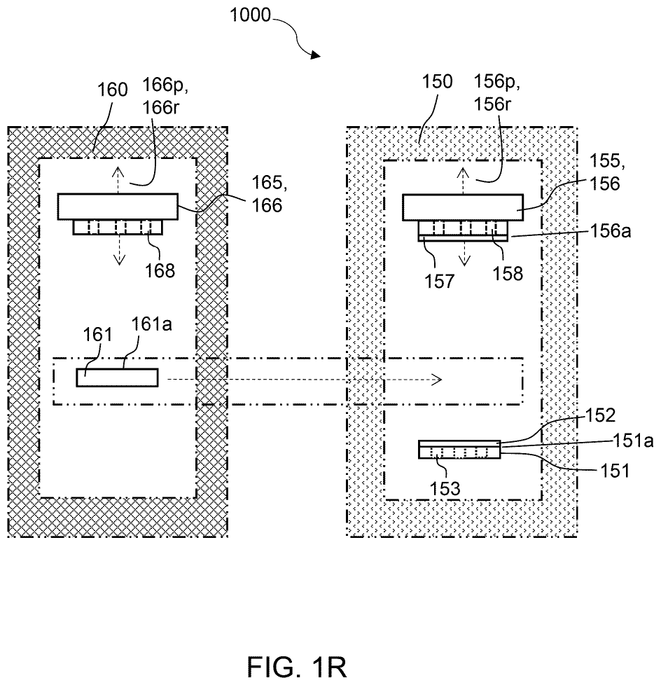

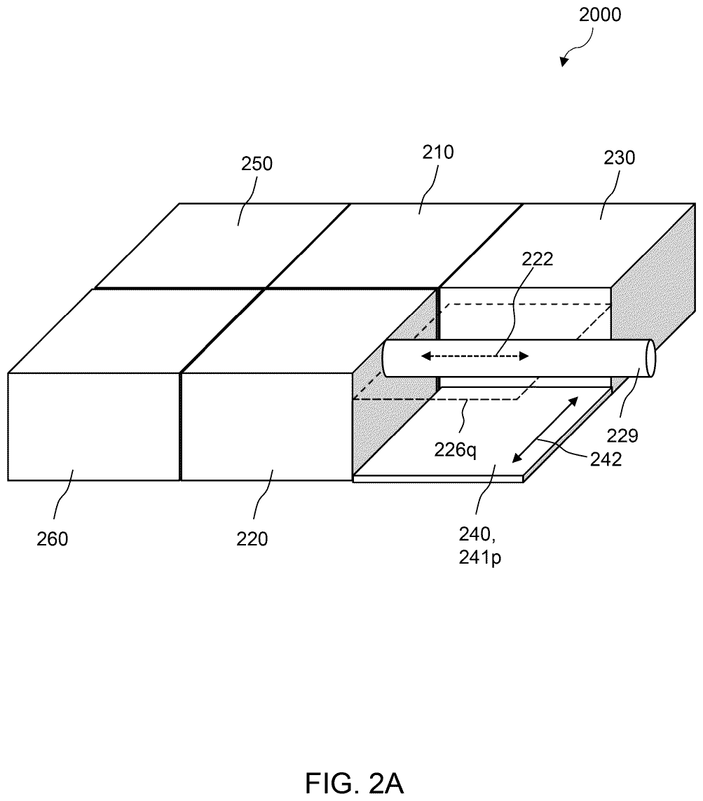

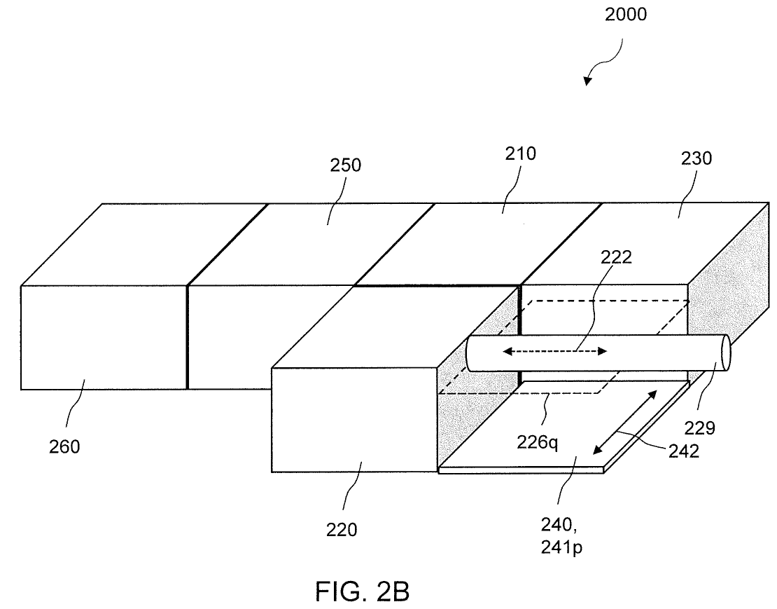

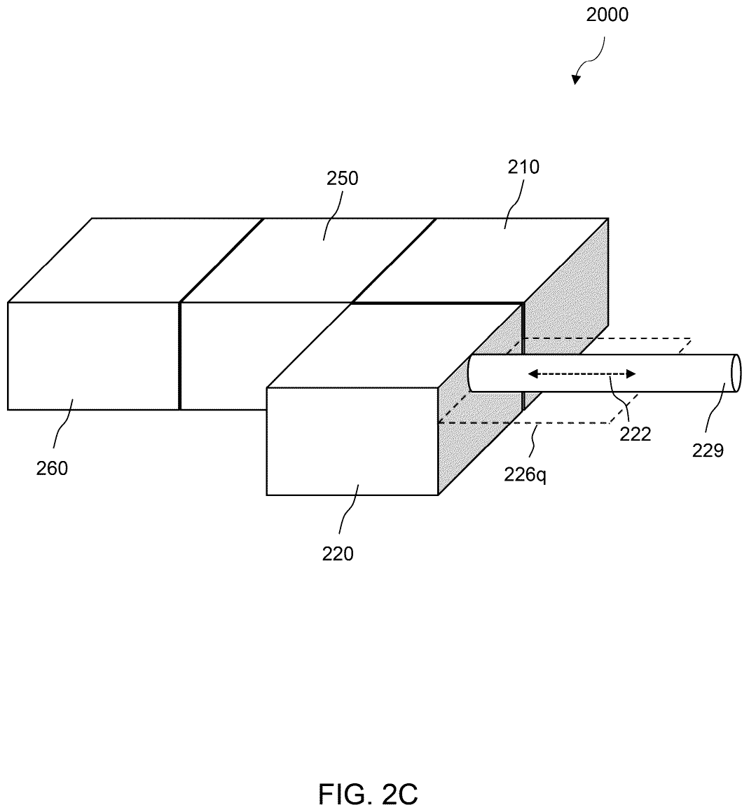

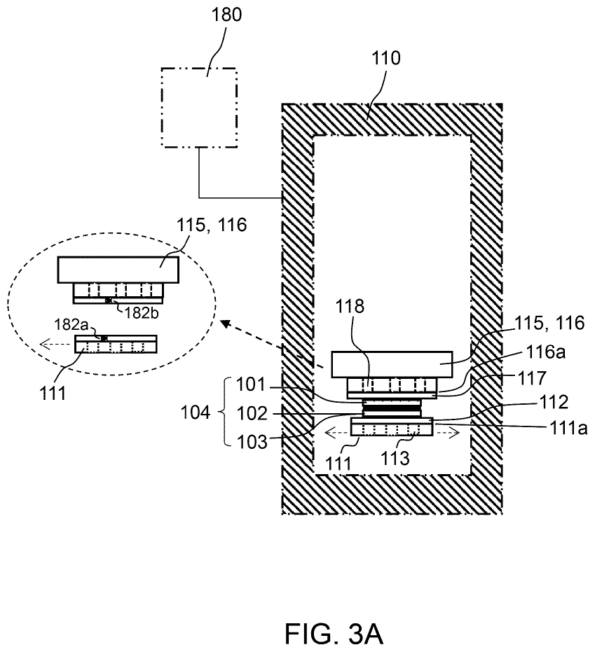

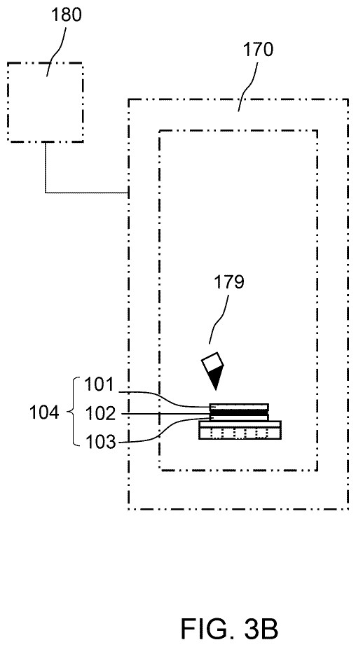

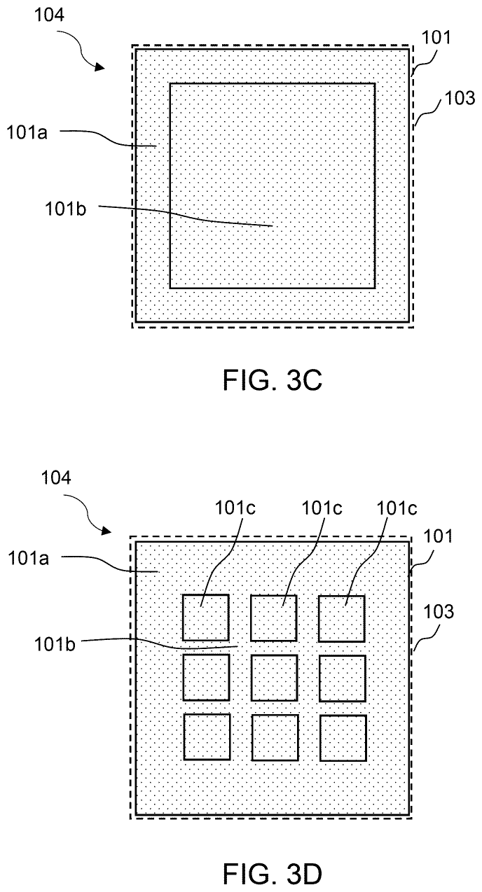

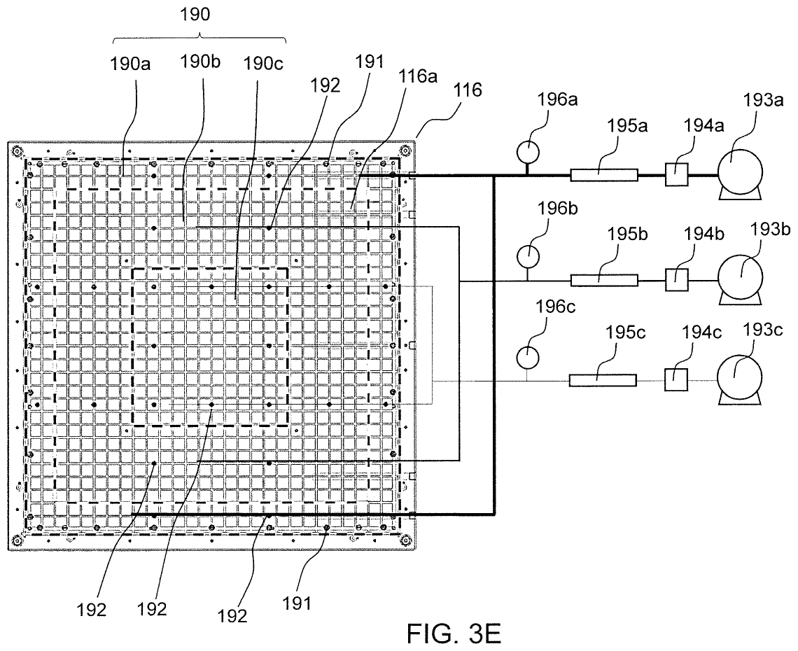

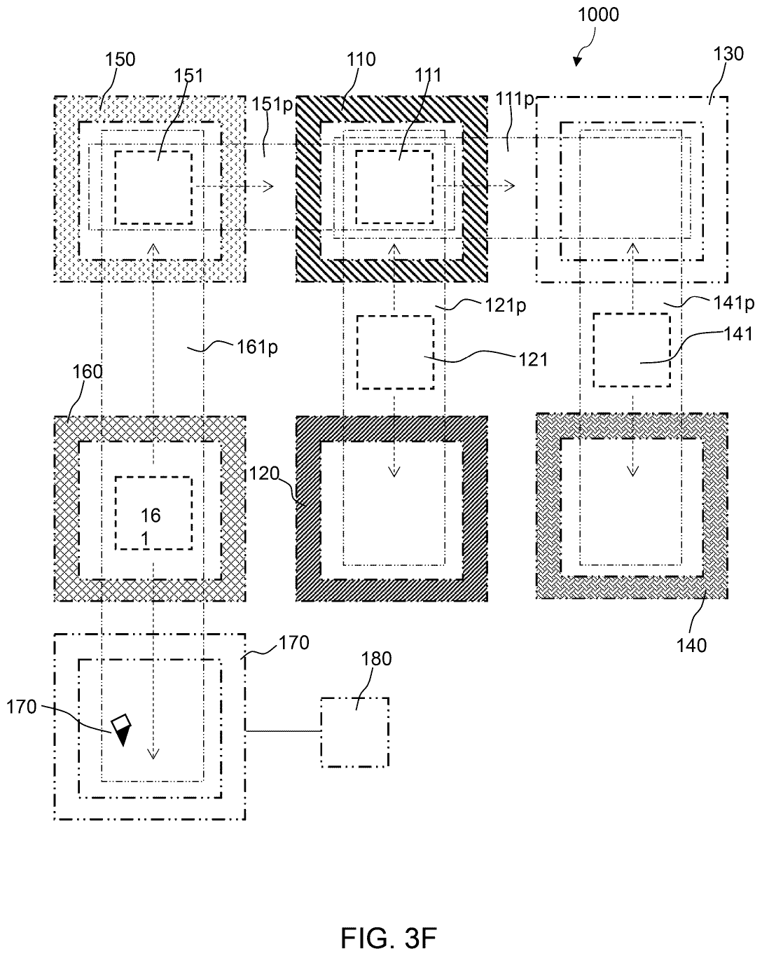

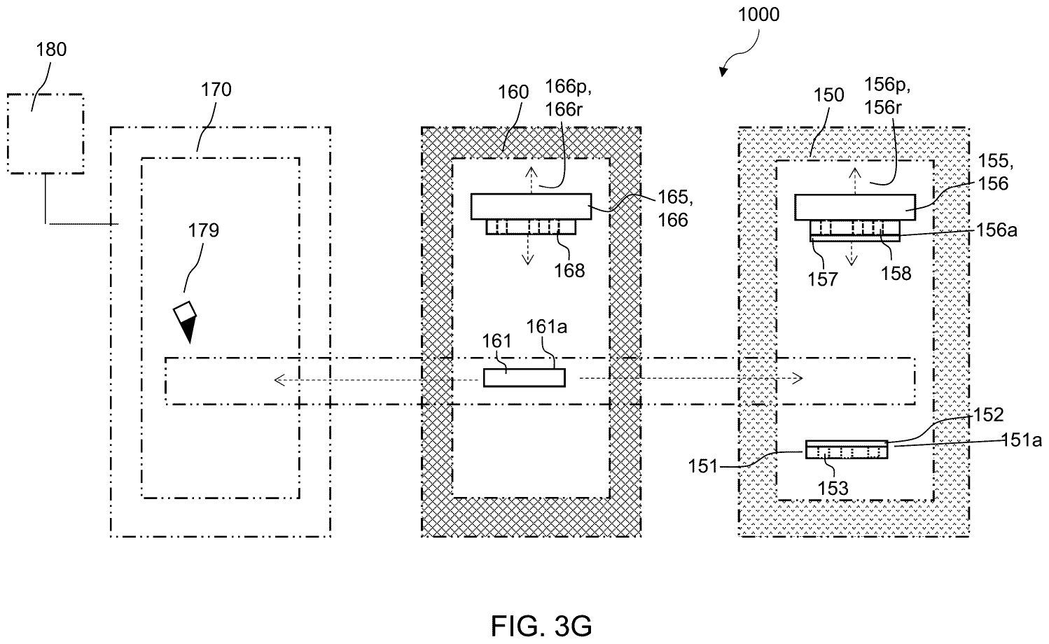

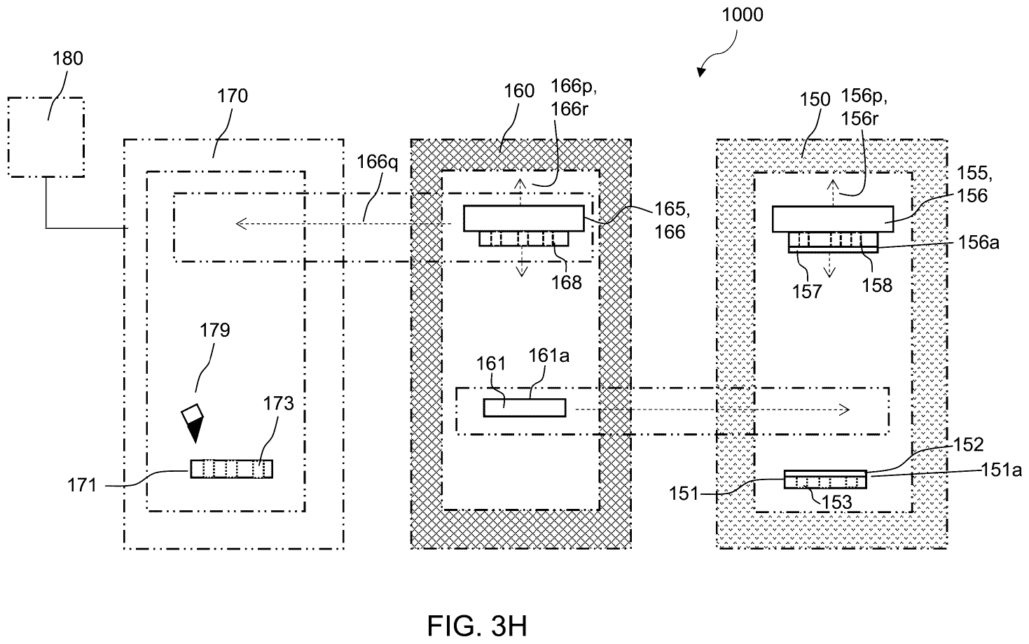

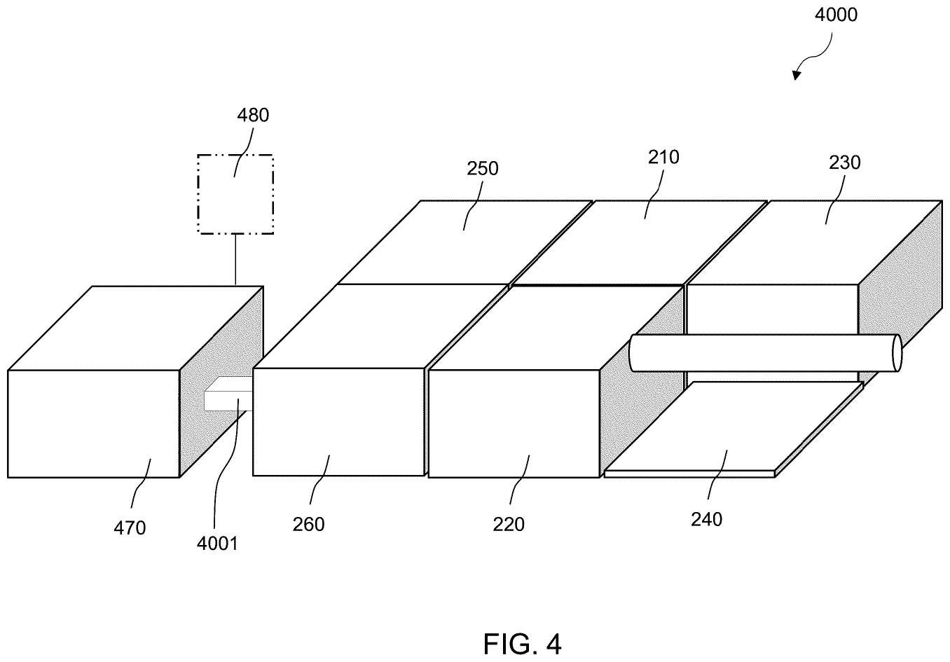

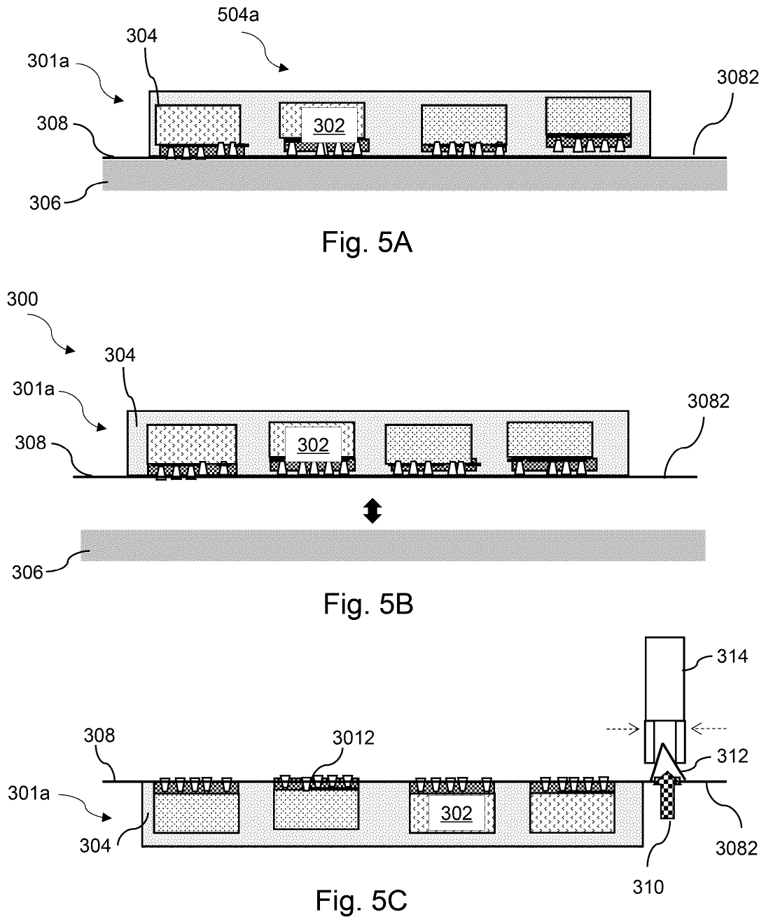

FIG. 1Q shows schematically the processing system having a pre-heating workstation linked to the release workstation, according to various embodiments;

FIG. 1R shows schematically the feeder workstation and the pre-heating workstation, linked to each other, with the feeder workstation having an alignment unit, according to various embodiments;

FIG. 2A shows a schematic perspective diagram of a processing system, according to various embodiments;

FIG. 2B and FIG. 2C show other example configurations of the processing system, according to various embodiments;

FIG. 3A shows schematically a control unit coupled to the release workstation, according to various embodiments;

FIG. 3B shows schematically a cutter workstation for the processing system, according to various embodiments;

FIG. 3C shows schematically an intermediate panel-carrier assembly with its peripheral edge portion cut by the cutter workstation, according to various embodiments;

FIG. 3D shows schematically an intermediate panel-carrier assembly with its peripheral edge portion and individual unit regions cut by the cutter workstation, according to various embodiments;

FIG. 3E shows schematically a plan view of a release-head, having a multi-zone vacuum retention arrangement, according to various embodiments;

FIG. 3F shows schematically an example of the cutter workstation within the processing system, according to various embodiments;

FIG. 3G shows schematically a first example of the cutter workstation linked to the feeder workstation, according to various embodiments;

FIG. 3H shows schematically a second example of the cutter workstation linked to the feeder workstation, according to various embodiments;

FIG. 4 shows a schematic perspective diagram of a processing system, according to various embodiments;

FIG. 5A to FIG. 5F show schematic diagrams of a first releasing process and a second releasing process, according to various embodiments.

### DETAILED DESCRIPTION OF THE INVENTION

Embodiments described below in the context of the apparatus are analogously valid for the respective methods, and vice versa. Furthermore, it will be understood that the embodiments described below may be combined, for example, a part of one embodiment may be combined with a part of another embodiment.

It should be understood that the terms “on”, “over”, “top”, “bottom”, “down”, “side”, “back”, “left”, “right”, “front”, “lateral”, “side”, “up”, “down” etc., when used in the following description are used for convenience and to aid understanding of relative positions or directions, and not intended to limit the orientation of any device, or structure or any part of any device or structure. In addition, the singular terms “a”, “an”, and “the” include plural references unless context clearly indicates otherwise. Similarly, the word “or” is intended to include “and” unless the context clearly indicates otherwise.

Various embodiments generally relate to a processing system (or processing line or automation system or automation line) (e.g. a panel release system) for processing a molded panel. According to various embodiments, processing the molded panel may include releasing the molded panel which may be attached, via thermal release adhesive, to a carrier. In particular, various embodiments generally relate to a processing system (e.g. panel release system) for releasing the molded panel. According to various embodiments, the processing system may include an automated production line or an automated assembly line or an automated process line or an automated machine which may include a series of workstations which may be linked, for example, by a transport or conveying system or arrangement to perform a pre-defined sequence of steps in a production or manufacturing or assembly or packaging process. In various embodiments, the processing system may be configured for a pre-defined sequence of steps in a panel-level packaging process for a panel-based semiconductor assembly. The panel-level packaging process may be the technology of packaging integrated circuits whereby a plurality of electronic elements, such as die, wafer, passive component and metallic component may be packaged simultaneously as a molded panel rather than the conventional technologies of individual electronic elements packaging. Accordingly, a plurality of electronic elements, such as die, wafer, passive component and metallic component, may be molded into a panel form on the carrier. According to various embodiments, there is provided a system or a processing system (e.g. panel release system) or a method of releasing a molded panel from a carrier. In various embodiments, the carrier be made, for example, of steel or steel alloy material. In various embodiments, the carrier may include a carrier panel or a carrier substrate.

Various embodiments seek to provide a processing system (e.g. panel release system) or method developed to use low cost material, such as low-cost steel alloy material, which is much robust and survives all process conditions and handling, together with the use of thermal or heat release adhesive, so as to provide the most economic and efficient solution for large panel manufacturing. Various embodiments seek to gradually heat up the panel assembly to a release temperature. Various embodiments seek to handle the molded panel with precise and controlled motion such that the molded panel may be gently released from the carrier. Various embodiments seek to ensure the molded panel is not stressed, or minimize stress, by gradual heating and gradual cooling of the panel assembly.

FIG. 1A and FIG. 1B shows schematically a release workstation 110 of a processing system (e.g. a panel release system) 1000, according to various embodiments.

According to various embodiments, processing a molded panel 101 may include release of the molded panel 101—which may (e.g. may initially) be attached, via a thermal release adhesive tape or film or membrane (which may be referred to as heat release tape, film or membrane) 102, to a carrier 103. According to various embodiments, the thermal release adhesive tape 102 may be disposed or sandwiched between the molded panel 101 and the carrier 103, thereby attaching the molded panel 101 to the carrier 103 to form an “intermediate panel-carrier assembly” 104. As an example, according to various embodiments, the molded panel 101 may encapsulate a plurality of electronic components or elements, such as one or more wafer(s), die(s), passive component(s) (e.g. capacitor(s), resistor(s), etc.), chip(s), and/or metallic component(s), etc. The carrier 103 may be a support substrate (e.g. a temporary or reusable substrate) which may facilitate handling, transport, and/or processing, etc., of the molded panel 101 prior to its release from the carrier 103. According to various embodiments, the carrier 103 may be a flat or a substantially flat and/or structured body which may be formed of a material or material composite, such as a metal or metallic alloy (e.g, particularly steel alloy 46). According to various embodiments, the material or material composite of the carrier 103 may include at least one or more of the following properties: high heat resistance, mechanical robustness, high thermal stability, dimensional stability under thermal cycling, hard, tough, durable, high thermal conductivity, good heat or thermal conduction characteristics, and/or compatibility with the thermal release adhesive tape 102 (e.g. non-reactivity with the thermal release adhesive tape 102), etc. In various embodiments, the use of a durable material (e.g. steel alloy) may enable the carrier 103 to withstand process conditions and handling (e.g. mechanical handling), thereby supporting efficient and scalable panel-level manufacturing.

According to various embodiments, heating of (or application of heat to) the thermal release adhesive tape 102 of the intermediate panel-carrier assembly 104, to a predetermined or a specific temperature (or temperature range)—which may be referred to as a “heat release temperature”—(e.g. for a predetermined duration) may result in or cause the thermal release adhesive tape 102 to lose its adhesivity or adhesiveness to a predetermined (e.g. a required or desired) extent towards the molded panel 101 (or at its side which is facing or directed towards the molded panel 101). To illustrate, with reference to a cross-sectional view of FIG. 1S, the thermal release adhesive tape 102 may include a heat-sensitive layer 102a and a pressure-sensitive layer 102b opposite or opposing to each other, and a base layer 102c sandwiched therebetween. In other words, the heat-sensitive layer 102a and the pressure-sensitive layer 102b of the thermal release adhesive tape 102 may be on opposite sides of the base layer 102c of the thermal release adhesive tape 102. According to various embodiments, within the intermediate panel-carrier assembly 104, the heat-sensitive layer 102a may be directly facing and/or adhered to the molded panel 101, while the pressure-sensitive layer 102b may be directly facing and/or adhered to the carrier 103. According to various embodiments, the heat-sensitive layer 102a may lose its adhesivity or adhesiveness (towards the molded panel 101) at (or when the heat-sensitive layer 102a is heated to) the heat release temperature, while the pressure-sensitive layer 102b may still retain its adhesivity or adhesiveness on or to the carrier 103 at (or when the pressure-sensitive layer 102b is heated to) the heat release temperature. According to various embodiments, the base layer 102c may provide mechanical support to the heat-sensitive layer 102a and the pressure-sensitive layer 102b, respectively. As a non-limiting example, according to various embodiments, the heat release temperature may be approximately 210° C.

According to various embodiments, with reference to FIG. 1A, the processing system 1000 (e.g. panel release system) may include the release workstation 110. According to various embodiments, the release workstation 110 may be configured to process the intermediate panel-carrier assembly 104 such that the molded panel 101 may be separable and/or separated (e.g. detached) from the carrier 103.

To illustrate, according to various embodiments, the release workstation 110 may include a carrier-support deck 111 (e.g. a respective or discrete deck, table, platform, stage, etc.) which may include a deck surface 111a (e.g. an upper or upward-facing surface) which may support the intermediate panel-carrier assembly 104 thereon. In particular, the deck surface 111a of the carrier-support deck 111 may be capable of supporting the intermediate panel-carrier assembly 104 thereon, with the intermediate panel-carrier assembly 104 in an orientation with the molded panel 101 at a top or topside of the intermediate panel-carrier assembly 104. Accordingly, according to various embodiments, when the intermediate panel-carrier assembly 104 is disposed or supported on the deck surface 111a of the carrier-support deck 111, the carrier 103 may be interposed or situated between the carrier-support deck 111 and the molded panel 101.

According to various embodiments, the intermediate panel-carrier assembly 104 may be delivered or transported into the release workstation 110 with the molded panel 101 at the topside of the intermediate panel-carrier assembly 104. For instance, according to various embodiments, the release workstation 110 may be linked to a preceding workstation, and the intermediate panel-carrier assembly 104 may be delivered or transported from the preceding workstation to the release workstation 110 (e.g. via a transporting or conveying mechanism, such as one or more movable decks and/or actuation members of the processing system 1000). It is also envisaged that, in various other embodiments, the release workstation 110 may be a first workstation of the processing system 1000. Accordingly, in such embodiments, the intermediate panel-carrier assembly 104 may be fed into the release workstation 110 via a feeder mechanism or via manual feeding. Accordingly, according to various embodiments, the release workstation 110 may be configured to receive the intermediate panel-carrier assembly 104 based on the overall setup and how the processing system 1000 may fit into an entire production or manufacturing or assembly or packaging process.

According to various embodiments, the carrier-support deck 111 may include (e.g. further include) a heater or release-deck-heater 112 (or a heating mechanism) for heating the intermediate panel-carrier assembly 104, when the intermediate panel-carrier assembly 104 is positioned or supported on the carrier-support deck 111 and/or with the carrier-support deck 111 positioned within the release workstation 110. In various embodiments, the heater 112 may also be referred to as a “release-deck-heater” 112. According to various embodiments, the heater 112 may be associated with the deck surface 111a of the carrier-support deck 111, such that the heater 112 may be operable to heat the intermediate panel-carrier assembly 104, when the deck surface 111a of the carrier-support deck 111 is engaged with the intermediate panel-carrier assembly 104. For instance, the heater 112 may be disposed or situated at the deck surface 111a of the carrier-support deck 111 such that it may be in direct or indirect thermal communication or thermal coupling with the intermediate panel-carrier assembly 104 that may be supported on the deck surface 111a of the carrier-support deck 111. In other words, the heater 112 may be directly or indirectly thermally coupled to the intermediate panel-carrier assembly 104 when the intermediate panel-carrier assembly 104 is supported on the deck surface 111a of the carrier-support deck 111. As an example, according to various embodiments, the heater 112 may be arranged (e.g. along the deck surface 111a of the carrier-support deck 111) so as to be in direct contact with the intermediate panel-carrier assembly 104 when it is supported on the deck surface 111a of the carrier-support deck 111. As some other examples, according to various embodiments, the heater 112 may be embedded within the deck surface 111a (or embedded within an upper portion of the carrier-support deck 111 having the deck surface 111a), or may be coupled to the deck surface 111a (e.g. while being positioned underneath the deck surface 111a), in a manner so as to be capable of heating the deck surface 111a (e.g. by conducting heat or thermal energy to the deck surface 111a). Accordingly, in various embodiments, the deck surface 111a may be capable of conducting heat from the heater 112 to the intermediate panel-carrier assembly 104. Thus, in various embodiments, the deck surface 111a may include or may be composed of a heat-conducting or thermally-conductive material (e.g. which may differ from a material of the carrier 103). In various embodiments, a layer of thermal interface material may be disposed on the deck surface 111a (e.g. between the deck surface 111a and the intermediate panel-carrier assembly 104). Accordingly, according to various embodiments, the carrier 103 of the intermediate panel-carrier assembly 104 may be in direct contact (e.g. direct thermal contact) with, or in indirect thermal contact with, the deck surface 111a and/or the heater 112 of the carrier-support deck 111. As a non-limiting example, according to various embodiments, the heater 112 of the carrier-support deck 111 may include or may be a heating plate. In various embodiments, this heating plate may form or may serve as the deck surface 111a of the carrier-support deck 111. In various other embodiments, this heating plate may be discrete from the deck surface 111a of the carrier-support deck 111. For instance, the discrete heating plate may be positioned underneath the deck surface 111a and may be thermally coupled to the deck surface 111a. Nevertheless, it is also envisaged that, in various other embodiments, the heater 112 of the carrier-support deck 111 may be implemented in any other suitable form and/or manner, including but not limited to solid-state heating elements, radiative heating arrangements (e.g. coupled, directly or indirectly, to the carrier-support deck 111), or any other suitable configuration capable of delivering the desired thermal effect. According to various embodiments, the heater 112 of the carrier-support deck 111 may provide heating based on a heating-control signal. According to various embodiments, this heating-control signal may be transmitted or provided to the heater 112 of the carrier-support deck 111 once or after the intermediate panel-carrier assembly 104 is positioned on the carrier-support deck 111 (e.g. within the release workstation 110). Thus, for instance, in various embodiments, the processing system 1000 (e.g. the carrier-support deck 111) may include a sensor configured to detect engagement between the carrier-support deck 111 and the intermediate panel-carrier assembly 104 (e.g. for triggering the heating-control signal).

According to various embodiments, when or with the intermediate panel-carrier assembly 104 supported on the deck surface 111a of the carrier-support deck 111, the heater 112 may be configured and/or operable to heat the intermediate panel-carrier assembly 104 to the heat release temperature of the thermal release adhesive tape 102 of the intermediate panel-carrier assembly 104 (e.g. for the predetermined duration), until the adhesive strength of the thermal release adhesive tape 102 between the carrier 103 and the molded panel 101 (particularly, between the thermal release adhesive tape 102 and the molded panel 101) may be weakened or reduced, thereby enabling the molded panel 101 to be separable from the carrier 103. According to various embodiments, the heat release temperature may be lower than a melting point of the carrier 103 of the intermediate panel-carrier assembly 104.

According to various embodiments, the release workstation 110 may include (e.g. further include) a release unit 115. According to various embodiments, the release unit 115 may include a release-head 116. According to various embodiments, the release-head 116 may be an actuation member (e.g. a respective or discrete actuation member or actuatable head). According to various embodiments, the release-head 116 may be positioned opposite and/or above the carrier-support deck 111, within the release workstation 110 (or when the carrier-support deck 111 is within the release workstation 110). For instance, within the release workstation 110, the carrier-support deck 111 may be within a lower region while the release-head 116 may be within an upper region thereof.

According to various embodiments, the release-head 116 may be configured and/or operable to be movable along a movement plane (herein may be referred to as “release-head-movement plane” 116p) within the release workstation 110. In various embodiments, the release-head-movement plane 116p may be a substantially flat plane which may be substantially vertically-oriented (e.g. relative to a base of the processing system 1000, and/or when the processing system 1000 is disposed and/or oriented upright on an external floor or ground). In particular, in various embodiments, the release-head-movement plane 116p may be aligned with (e.g. may intersect) the carrier-support deck 111 (e.g. its deck surface 111a), when the carrier-support deck 111 is positioned within the release workstation 110. According to various embodiments, the release unit 115 may be operable in a manner corresponding to (e.g. resembling) a press unit or a top press, with the release-head 116 being movable in upward and downward directions (e.g. opposite linear directions), within or along the release-head-movement plane 116p, so as to be capable of engaging the intermediate panel-carrier assembly 104 when the intermediate panel-carrier assembly 104 is aligned with and/or positioned underneath the release-head 116 and/or capable of lifting at least the molded panel 101 of the intermediate panel-carrier assembly 104 (e.g. away from the carrier-support deck 111). Accordingly, according to various embodiments, when the carrier-support deck 111 is positioned within the release workstation 110 and/or is aligned with the release-head 116 (e.g. within the release workstation 110), the release-head 116 may be configured and/or operable to be movable or moved towards the deck surface 111a of the carrier-support deck 111 to engage the molded panel 101 of the intermediate panel-carrier assembly 104 which may be supported on the deck surface 111a of the carrier-support deck 111. According to various embodiments, movement of the release-head 116 along the release-head-movement plane 116p may be based on a movement signal. In various embodiments, this movement signal may be transmitted or provided to the release-head 116 or to an actuator coupled thereto (e.g. to instruct movement of the release-head 116).

According to various embodiments, the release-head 116 may include a (or at least one) release-head-retaining member 118. According to various embodiments, the release-head-retaining member 118 may be a retaining member configured to releasably retain (e.g. releasably hold or secure) at least the molded panel 101 of the intermediate panel-carrier assembly 104 to an engagement surface 116a (e.g. a downward-facing surface) of the release-head 116 (e.g. when the release-head 116 is engaged with the separated molded panel 101). According to various embodiments, the release-head-retaining member 118 may be associated with (e.g. at or proximal to) the engagement surface 116a of the release-head 116. As some examples, according to various embodiments, the release-head-retaining member 118 may include a vacuum suction mechanism (e.g. vacuum plate, vacuum suction holes, vacuum cups, etc.), a gripping mechanism (e.g. grippers or clamps), electrostatic chuck, end effector, etc. According to various embodiments, operation of the release-head-retaining member 118 may be based on a retaining-control signal. In various embodiments, this retaining-control signal may be transmitted or provided to the release-head-retaining member 118 (e.g. to instruct operation of the release-head-retaining member 118).

Accordingly, according to various embodiments, after the heater 112 of the carrier-support deck 111 heats or has heated the intermediate panel-carrier assembly 104 to the heat release temperature (e.g. for the predetermined duration, until the heat-sensitive layer 102a of the thermal release adhesive tape 102 losses its adhesivity or adhesiveness towards the molded panel 101)—with the release-head-retaining member 118 securing (e.g. releasably retaining) the molded panel 101 to the engagement surface 116a of the release-head 116—the release-head 116 may further be configured and/or operable to be movable or moved (e.g. in an opposite, upward direction) away from the deck surface 111a of the carrier-support deck 111, thereby separating (or detaching) the molded panel 101 from the carrier 103. In particular, in various embodiments, once the adhesive strength between the molded panel 101 and the thermal release adhesive tape 102 of the intermediate panel-carrier assembly 104 is weakened or reduced to the required extent, mere lifting of the molded panel 101 by the release-head 116 may be sufficient to separate (or detach) the molded panel 101 from the underlying carrier 103. As a result, the carrier 103 (e.g. together with the thermal release adhesive tape 102) may remain on the deck surface 111a of the carrier-support deck 111, when the molded panel 101 is lifted away (i.e. separated) from the carrier 103.

According to various embodiments, the release-head 116 may include (e.g. optionally and/or further include) a heater or release-heater 117 (e.g. a respective or a further heater or heating plate) which may be associated with the engagement surface 116a of the release-head 116. In various embodiments, the heater 117 may also be referred to as a “release-head-heater” 117. For instance, the heater 117 may be which may be disposed at the engagement surface 116a of the release-head 116. According to various embodiments, the heater 117 of the release-head 116 may be configured and/or operable to cooperatively heat the intermediate panel-carrier assembly 104 together with the heater 112 of the carrier-support deck 111—when the intermediate panel-carrier assembly 104 is between (e.g. interposed or sandwiched between) the carrier-support deck 111 and the release-head 116 (in other words, when the intermediate panel-carrier assembly 104 is supported on the deck surface 111a of the carrier-support deck 111 and when the engagement surface 116a of the release-head 116 is engaged with the intermediate panel-carrier assembly 104—to and/or at the heat release temperature (i.e. to weaken or reduce the adhesive strength of the thermal release adhesive tape 102), before the release-head 116 lifts and separates the molded panel 101 from the carrier 103. In other words, according to various embodiments, heat may (e.g. optionally) be applied at both sides of the intermediate panel-carrier assembly 104 by the processing system 1000 to weaken the adhesive strength of the thermal release adhesive tape 102. According to various embodiments, the heater 117 of the release-head 116 may provide heating based on a heating-control signal. According to various embodiments, this heating-control signal may be transmitted or provided to the heater 117 of the release-head 116 when the release-head 116 is engaged with the molded panel 101 and when the carrier-support deck 111 is engaged with the carrier 103, so as to perform the cooperative heating of the intermediate panel-carrier assembly 104 together with the heater 112 of the carrier-support deck 111. In various embodiments, the processing system 1000 (e.g. the release-head 116) may also include a sensor configured to detect engagement between the release-head 116 and the intermediate panel-carrier assembly 104 (e.g. for triggering this heating-control signal).

According to various embodiments, the carrier-support deck 111 may include (e.g. optionally and/or further include) a (or at least one) carrier-support-deck-retaining member 113. According to various embodiments, the carrier-support-deck-retaining member 113 may be a retaining member (e.g. another respective of discrete retaining member) configured to releasably retain (e.g. releasably hold or secure) at least the carrier 103 of the intermediate panel-carrier assembly 104 to the deck surface 111a (e.g. upward-facing surface) of the carrier-support deck 111 (i.e. when the carrier-support deck 111 is engaged with the carrier 103). According to various embodiments, the carrier-support-deck-retaining member 113 may be associated with (e.g. at or proximal to) the deck surface 111a of the carrier-support deck 111. As some examples, according to various embodiments, the carrier-support-deck-retaining member 113 may include a vacuum suction mechanism (e.g. vacuum plate, vacuum suction holes, vacuum cups, etc.), a gripping mechanism (e.g. grippers or clamps), electrostatic chuck, end effector, etc. According to various embodiments, to facilitate separation of the molded panel 101 from the carrier 103, the carrier-support-deck-retaining member 113 may retain (e.g. releasably retain) the carrier 103 to the deck surface 111a of the carrier-support deck 111, as or while the release-head 116 releasably retains the molded panel 101 to the engagement surface 116a of the release-head 116 and lifts the molded panel 101 away from the carrier 103. According to various embodiments, operation of the carrier-support-deck-retaining member 113 may be based on a retaining-control signal. In various embodiments, this retaining-control signal may be transmitted or provided to the carrier-support-deck-retaining member 113 (e.g. to instruct operation of the carrier-support-deck-retaining member 113).

FIG. 1C and FIG. 1D show schematically the processing system 1000 having the release workstation 110 of FIG. 1A, optionally and as a matter of choice together with a panel-handling workstation 120 and a carrier-handling workstation 130, according to various embodiments.

According to various embodiments, the processing system 1000 may include (e.g. optionally further include) one or more other workstations which may be linked to the release workstation 110. In various embodiments, these workstations may be linked to each other, for instance, via a transporting or conveying mechanism, such as one or more movable decks and/or actuation members of the processing system 1000.

For instance, with reference to FIG. 1C and FIG. 1D, according to various embodiments, the processing system 1000 may include (e.g. optionally further include) the panel-handling workstation 120 and/or the carrier-handling workstation 130, respectively linked to the release workstation 110.

According to various embodiments, the panel-handling workstation 120 may be capable of receiving, or may be configured to receive, the separated molded panel 101 from the release workstation 110. In other words, in various embodiments, the separated molded panel 101 may be conveyed or moved from the release workstation 110 to the panel-handling workstation 120.

For instance, according to various embodiments, the panel-handling workstation 120 may include a panel-support deck 121 (e.g. a respective or discrete deck, table, platform, stage, etc.) which may be configured and/or operable to be movable between the panel-handling workstation 120 and the release workstation 110 for conveying the separated molded panel 101 from the release workstation 110 to the panel-handling workstation 120. In particular, in various embodiments, the panel-support deck 121 may be movable at least from the release workstation 110 to the panel-handling workstation 120 to convey the separated molded panel 101 from the release workstation 110 to the panel-handling workstation 120. Thus, the panel-support deck 121 may correspond to (e.g. may be or may resemble) a discrete transfer (or shuttle or sliding or movable) table (or platform). According to various embodiments, the panel-support deck 121 may be movable along a movement plane (herein may be referred to as “panel-support-deck-movement plane” 121p) which may extend between the panel-handling workstation 120 and the release workstation 110. In various embodiments, the panel-support-deck-movement plane 121p may be a substantially flat plane which may be substantially horizontally-oriented (e.g. relative to the base of the processing system 1000, and/or when the processing system 1000 is disposed and/or oriented upright on the external floor or ground). According to various embodiments, the panel-support-deck-movement plane 121p may be non-parallel (e.g. perpendicular or substantially perpendicular) to the release-head-movement plane 116p. As a non-limiting example, according to various embodiments, the processing system 1000 may include a respective (e.g. a respective or discrete) rail, track or slide (e.g. linear rail, track or slide, in other words, a guide element) which may extend between the panel-handling workstation 120 and the release workstation 110, for the panel-support deck 121 to be movable (e.g. slidable) and/or guided therealong. Thus, in various embodiments, the panel-support deck 121 may be capable and/or operable to be movable, in lateral or sideways directions (e.g. opposite linear directions), within or along the panel-support-deck-movement plane 121p—out of the panel-handling workstation 120 and into the release workstation 110, and out of the release workstation 110 and into the panel-handling workstation 120. According to various embodiments, movement of the panel-support deck 121 along the panel-support-deck-movement plane 121p may be based on a movement signal. In various embodiments, this movement signal may be transmitted or provided to the panel-support deck 121 or to an actuator coupled thereto (e.g. to instruct movement of the panel-support deck 121).

According to various embodiments, after the molded panel 101 has been separated from the carrier 103 (i.e. at the release workstation 110), the panel-support deck 121 (e.g. without the molded panel 101 thereon) may be configured and/or operable to be movable or moved into the release workstation 110, to align with the release-head 116 (e.g. which may be releasably retaining the separated molded panel 101), within the release workstation 110, so as to be capable of receiving (or so as to receive) the separated molded panel 101 from the release-head 116.

In particular, according to various embodiments, when or with the panel-support deck 121 positioned within the release workstation 110 to align with the release-head 116, the release-head 116 may be operable to release the separated molded panel 101 onto the panel-support deck 121 (i.e. within the release workstation 110). According to various embodiments, when or with the separated molded panel 101 on the panel-support deck 121 (in other words, after the panel-support deck 121 receives the separated molded panel 101 from the release-head 116 at the release workstation 110), the panel-support deck 121 may be operable to be moved out of the release workstation 110 and into the panel-handling workstation 120, thereby conveying the separated molded panel 101 from the release workstation 110 to the panel-handling workstation 120.

As an illustration, according to various embodiments, the panel-support-deck-movement plane 121p of the panel-support deck 121 may be spatially separated from and/or parallel to and/or above a carrier-support-deck-movement plane 111p (see FIG. 1D) (described later) of the carrier-support deck 111. As such, in this example, according to various embodiments, when the panel-support deck 121 is moved into the release workstation 110, the panel-support deck 121 may be above the carrier-support deck 111 (or above the carrier-support-deck-movement plane 111p), to align with the release-head 116 and/or the separated molded panel 101 which may be releasably retained to the release-head 116 (e.g. without any intervening physical obstruction between the separated molded panel 101 and the panel-support deck 121 underneath it). It is also envisaged that, in various other embodiments, the panel-support-deck-movement plane 121p may be below the carrier-support-deck-movement plane 111p. Accordingly, according to various embodiments, the carrier-support deck 111 may be movable along the carrier-support-deck-movement plane 111p, and the panel-support deck 121 may be movable along the panel-support-deck movement plane 121p which may be parallel and/or spaced apart from the carrier-support-deck-movement plane 111p.

As another illustration, according to various embodiments, the carrier-support deck 111 may be configured and/or operable to be movable into and out of the release workstation 110, synchronously with the movement of the panel-support deck 121. Thus, in various embodiments, the carrier-support deck 111 may be moved out of the release workstation 110, to facilitate and/or enable movement of the panel-support deck 121 into the release workstation 110 and/or alignment with the release-head 116 within the release workstation 110. It is envisaged that, in this example, the carrier-support deck 111 and the panel-support deck 121 may be movable along a same plane, or they may respectively be movable along different and spatially separated planes (e.g. one above the other).

According to various embodiments, upon (or with) alignment of the panel-support deck 121 and the release-head 116 (i.e. releasably retaining the separated molded panel 101 thereto), the release-head 116 may be configured and/or operable to be movable or moved (i.e. together with the separated molded panel 101) towards the panel-support deck 121 to release and dispose the separated molded panel 101 onto the panel-support deck 121. In particular, according to various embodiments, the release-head 116 may be lowered along the release-head-movement plane 116p until the separated molded panel 101 is proximal or engages a deck surface 121a (e.g. upper surface) of the panel-support deck 121, and thereafter release the separated molded panel 101 onto the panel-support deck 121. According to various embodiments, after the separated molded panel 101 is placed onto the panel-support deck 121 by the release-head 116, the release-head 116 may be operable to be movable or moved in an opposite direction, away from the panel-support deck 121, to facilitate movement of the panel-support deck 121 (i.e. with the separated molded panel 101 thereon) out of the release workstation 110 and into the panel-handling workstation 120. Accordingly, in various embodiments, after the release-head 116 has released or deposited the separated molded panel 101 onto the panel-support deck 121, the panel-support deck 121 may transport or convey the separated molded panel 101 from the release workstation 110 to the panel-handling workstation 120.

According to various embodiments, the panel-handling workstation 120 may include a panel-handling unit 125. According to various embodiments, the panel-handling unit 125 may include a panel-handling head 126. According to various embodiments, the panel-handling head 126 may be an actuation member (e.g. a respective or discrete actuation member or actuatable head). According to various embodiments, the panel-handling head 126 may be positioned opposite and/or above the panel-support deck 121, within the panel-handling workstation 120 (or when they are both within the panel-handling workstation 120). For instance, within the panel-handling workstation 120, the panel-support deck 121 may be within a lower region while the panel-handling head 126 may be within an upper region thereof.

According to various embodiments, the panel-handling head 126 may be configured and/or operable to be movable along a movement plane (herein may be referred to as “panel-handling-head-movement plane” 126p), at least within the panel-handling workstation 120. According to various embodiments, the panel-handling-head-movement plane 126p may be a substantially flat plane which may be substantially vertically-oriented (e.g. relative to the base of the processing system 1000, and/or when the processing system 1000 is disposed and/or oriented upright on the external floor or ground). According to various embodiments, the panel-handling-head-movement plane 126p at the panel-handling workstation 120 may be parallel or substantially parallel with the release-head-movement plane 116p at the release workstation 110. Further, the panel-handling-head-movement plane 126p may be non-parallel (e.g. perpendicular or substantially perpendicular) to the panel-support-deck-movement plane 121p. According to various embodiments, the panel-handling-head-movement plane 126p may be aligned with (e.g. may intersect) the panel-support deck 121 (e.g. its deck surface 121a) when the panel-support deck 121 is positioned within the panel-handling workstation 120, together with the panel-handling head 126. According to various embodiments, the panel-handling unit 125 may be operable in a manner corresponding to (e.g. resembling) a press unit or a top press, with the panel-handling head 126 being movable in upward and downward directions (e.g. opposite linear directions), within or along the panel-handling-head-movement plane 126p, so as to be capable of engaging the separated molded panel 101 when the separated molded panel 101 is aligned with and/or positioned underneath the panel-handling head 126 and/or capable of lifting the separated molded panel 101 from (e.g. away from) the panel-support deck 121. Accordingly, according to various embodiments, when the panel-support deck 121 is positioned within the panel-handling workstation 120 and/or is aligned with the panel-handling head 126, the panel-handling head 126 may be configured and/or operable to be movable (e.g. in a downward direction) towards the deck surface 121a of the panel-support deck 121 to engage the separated molded panel 101 on the deck surface 121a of the panel-support deck 121 (e.g. for transferring the separated molded panel 101 from the panel-support deck 121 to the panel-handling head 126). According to various embodiments, movement of the panel-handling head 126 along the panel-handling-head-movement plane 126p may be based on a movement signal. In various embodiments, this movement signal may be transmitted or provided to the panel-handling head 126 (e.g. to instruct movement of the panel-handling head 126).

According to various embodiments, the panel-handling head 126 may include a (or at least one) panel-handling-head-retaining member 128. According to various embodiments, the panel-handling-head-retaining member 128 may be a retaining member configured to releasably retain (e.g. releasably hold or secure) the separated molded panel 101 to an engagement surface 126a (e.g. a downward-facing surface) of the panel-handling head 126 (e.g. when the panel-handling head 126 is engaged with the separated molded panel 101). According to various embodiments, the panel-handling-head-retaining member 128 may be associated with (e.g. at or proximal to) the engagement surface 126a of the panel-handling head 126. As some examples, according to various embodiments, the panel-handling-head-retaining member 128 may include a vacuum suction mechanism (e.g. vacuum plate, vacuum suction holes, vacuum cups, etc.), a gripping mechanism (e.g. grippers or clamps), electrostatic chuck, end effector, etc. According to various embodiments, operation of the panel-handling-head-retaining member 128 may be based on a retaining-control signal. In various embodiments, this retaining-control signal may be transmitted or provided to the panel-handling-head-retaining member 128 (e.g. to instruct operation of the panel-handling-head-retaining member 128).

According to various embodiments, the panel-handling head 126 may further include a temperature-regulating heater 127 (or temperature-regulating element or arrangement) for regulating a temperature of the separated molded panel 101 (e.g. to a temperature lower than the heat release temperature).

According to various embodiments, this temperature-regulating heater 127 may be associated with the engagement surface 126a of the panel-handling head 126, such that the temperature-regulating heater 127 may be operable to regulate a temperature of the separated molded panel 101 when the engagement surface 126a of the panel-handling head 126 is engaged with the separated molded panel 101. For instance, the temperature-regulating heater 127 may be disposed at the engagement surface 126a of the panel-handling head 126 so as to be in thermal communication or thermal coupling with the separated molded panel 101 that may be releasably retained on the engagement surface 126a of the panel-handling head 126. As an example, according to various embodiments, the temperature-regulating heater 127 may be arranged (e.g. along the engagement surface 126a of the panel-handling head 126) so as to be in direct contact with the separated molded panel 101 that may be releasably retained onto the engagement surface 126a of the panel-handling head 126. As some other examples, according to various embodiments, the temperature-regulating heater 127 may be embedded within the engagement surface 126a (or embedded within a lower portion of the panel-handling head 126 having the engagement surface 126a), or may be coupled to the engagement surface 126a (e.g. while being positioned behind or rearward of the engagement surface 126a), in a manner so as to be capable of heating or regulating a temperature of the engagement surface 126a (e.g. by conducting heat or thermal energy, for instance, in a controlled manner, to the engagement surface 126a). Accordingly, in various embodiments, the engagement surface 126a may be capable of conducting or transferring heat or thermal energy between the temperature-regulating heater 127 and the separated molded panel 101 (e.g. from the separated molded panel 101 to the temperature-regulating heater 127). Thus, in various embodiments, the engagement surface 126a may include or may be composed of a heat-conducting or thermally-conductive material. In various embodiments, a layer of thermal interface material may be disposed on the engagement surface 126a (e.g. between the engagement surface 126a and the separated molded panel 101). Accordingly, according to various embodiments, the separated molded panel 101 may be in direct contact (e.g. direct thermal contact) with, or in indirect thermal contact with, the engagement surface 126a and/or the temperature-regulating heater 127 of the panel-handling head 126. As a non-limiting example, according to various embodiments, the temperature-regulating heater 127 of the panel-handling head 126 may include or may be a heating plate. In various embodiments, this heating plate may form or may serve as the engagement surface 126a of the panel-handling head 126. In various other embodiments, this heating plate may be discrete from the engagement surface 126a of the panel-handling head 126. For instance, the discrete heating plate may be positioned adjacent (e.g. rearwards of) the engagement surface 126a and may be thermally coupled to the engagement surface 126a. Nevertheless, it is also envisaged that, in various other embodiments, the temperature-regulating heater 127 of the panel-handling head 126 may be implemented in any other suitable form and/or manner, including but not limited to solid-state heating elements, radiative heating arrangements (e.g. coupled, directly or indirectly, to the engagement surface 126a of the panel-handling head 126), or any other suitable configuration capable of delivering the desired thermal effect. According to various embodiments, the temperature-regulating heater 127 of the panel-handling head 126 may provide temperature-regulation based on a temperature-regulation-control signal. According to various embodiments, this temperature-regulation-control signal may be transmitted or provided to the temperature-regulating heater 127 of the panel-handling head 126, particularly, after the release operation has been performed on the intermediate panel-carrier assembly 104 and once or after the panel-handling head 126 engages the separated molded panel 101. Thus, for instance, in various embodiments, the processing system 1000 (e.g. the panel-handling head 126) may include a sensor configured to detect engagement between the panel-handling head 126 and the separated molded panel 101 (e.g. for triggering this temperature-regulation-control signal).

In particular, according to various embodiments, the temperature-regulating heater 127 of the panel-handling head 126 may be operable to regulate a temperature of the panel-handling head 126 (e.g. its engagement surface 126a) and, in turn, the separated molded panel 101 to a level between the heat release temperature and an ambient temperature (i.e. which may be lower than the heat release temperature). According to various embodiments, when the separated molded panel 101 is conveyed (or delivered or transported) (e.g. via the panel-support deck 121) from the release workstation 110 to the panel-handling workstation 120, the separated molded panel 101 may be at a temperature at, substantially at, or close to the heat release temperature. On the other hand, the temperature of the temperature-regulating heater 127 of the panel-handling head 126 (and/or the engagement surface 126a of the panel-handling head 126) may be configured (e.g. controlled or regulated, via the temperature-regulating heater 127) to be between the ambient temperature and the heat release temperature or, more particularly, higher than the ambient temperature but lower than the heat release temperature and/or lower than the temperature of the separated molded panel 101. In this manner, according to various embodiments, the panel-handling head 126 (i.e. in engagement with the separated molded panel 101 via the panel-handling-head-retaining member 128, while the temperature-regulating heater 127 is in operation) may serve as a thermal buffer, whereby heat may be transferred from the molded panel 101 to the panel-handling head 126, thereby initiating a controlled and/or gradual cooling process of the molded panel 101. In various embodiments, as the temperature differential between the panel-handling head 126 and the molded panel 101 may be less than that between the molded panel 101 and the ambient temperature (or ambient air), the cooling rate of the molded panel 101 (i.e. that is releasably retained to the panel-handling head 126 and/or in thermal communication or thermal coupling with its temperature-regulating heater 127) may accordingly be moderated or regulated. In various embodiments, such a gradual cooling process or gradual temperature drop may minimize thermal stress and reduce or eliminate any potential risk of panel warpage or distortion.

Additionally, according to various embodiments, the panel-support deck 121 may be configured to serve or function as another (e.g. an auxiliary) thermal buffer (e.g. similar to the panel-handling head 126). For instance, according to various embodiments, the panel-support deck 121 may include a temperature-regulating heater 122 (e.g. a respective heater, which may function as an auxiliary temperature-regulating heater or temperature-regulating element or arrangement) which may be configured to maintain the separated molded panel 101 at a temperature between the heat release temperature and the ambient temperature and/or which may be configured to regulate the temperature of the separated molded panel 101 (e.g. to a temperature lower than the heat release temperature)—when the separated molded panel 101 is supported on the deck surface 121a of the panel-support deck 121.

According to various embodiments, the temperature-regulating heater 122 of the panel-support deck 121 may be associated with the deck surface 121a of the panel-support deck 121, such that the temperature-regulating heater 122 may be operable to maintain the separated molded panel 101 at a temperature between the heat release temperature and the ambient temperature when the deck surface 121a of the panel-support deck 121 is engaged with the separated molded panel 101. For instance, the temperature-regulating heater 122 may be disposed at the deck surface 121a of the panel-support deck 121 so as to be in thermal communication or thermal coupling with the separated molded panel 101 that may be placed or transferred thereon from the release-head 116. As an example, according to various embodiments, the temperature-regulating heater 122 may be arranged (e.g. along the deck surface 121a of the panel-support deck 121) so as to be capable of being in direct contact with the separated molded panel 101. As some other examples, according to various embodiments, the temperature-regulating heater 122 may be embedded within the deck surface 121a (or embedded within an upper portion of the panel-support deck 121 having the deck surface 121a), or may be coupled to the deck surface 121a (e.g. while being positioned underneath the deck surface 121a), in a manner so as to be capable of heating or regulating a temperature of the deck surface 121a (e.g. by conducting heat or thermal energy, for example, in a controlled manner, to the deck surface 121a). Accordingly, in various embodiments, the deck surface 121a may be capable of conducting or transferring heat or thermal energy between the temperature-regulating heater 122 and the separated molded panel 101 (e.g. from the separated molded panel 101 to the temperature-regulating heater 122). Thus, in various embodiments, the deck surface 121a may include or may be composed of a heat-conducting or thermally-conductive material. In various embodiments, a layer of thermal interface material may be disposed on the deck surface 121a (e.g. between the deck surface 121a and the separated molded panel 101). Accordingly, according to various embodiments, the separated molded panel 101 may be in direct contact (e.g. direct thermal contact) with, or in indirect thermal contact with, the deck surface 121a and/or the temperature-regulating heater 122 of the panel-support deck 121. As a non-limiting example, according to various embodiments, the temperature-regulating heater 122 of the panel-support deck 121 may include or may be a heating plate. In various embodiments, this heating plate may form or may serve as the deck surface 121a of the panel-support deck 121. In various other embodiments, this heating plate may be discrete from the deck surface 121a of the panel-support deck 121. For instance, the discrete heating plate may be positioned underneath the deck surface 121a and may be thermally coupled to the deck surface 121a. Nevertheless, it is also envisaged that, in various other embodiments, the temperature-regulating heater 122 of the panel-support deck 121 may be implemented in any other suitable form and/or manner, including but not limited to solid-state heating elements, radiative heating arrangements (e.g. coupled, directly or indirectly, to the deck surface 121a of the panel-support deck 121), or any other suitable configuration capable of delivering the desired thermal effect. According to various embodiments, the temperature-regulating heater 122 of the panel-support deck 121 may provide temperature-regulation based on a temperature-regulation-control signal. According to various embodiments, this temperature-regulation-control signal may be transmitted or provided to the temperature-regulating heater 122 of the panel-support deck 121 after the release operation has been performed on the intermediate panel-carrier assembly 104 and once or after the panel-support deck 121 engages the separated molded panel 101. Thus, for instance, in various embodiments, the processing system 1000 (e.g. the panel-support deck 121) may include a sensor configured to detect engagement between the panel-support deck 121 and the separated molded panel 101 (e.g. for triggering this temperature-regulation-control signal).

According to various embodiments, the temperature-regulating heater 122 of the panel-support deck 121 may be operable to regulate a temperature of the panel-support deck 121 (e.g. its deck surface 121a) and, in turn, the separated molded panel 101 to a level between the heat release temperature and the ambient temperature (i.e. which may be lower than the heat release temperature). In particular, the temperature of the temperature-regulating heater 122 of the panel-support deck 121 (and/or the deck surface 121a of the panel-support deck 121) may be configured (e.g. controlled or regulated, via the temperature-regulating heater 122) to be between the heat release temperature and the ambient temperature or, more particularly, higher than the ambient temperature but lower than the heat release temperature and/or lower than the temperature of the separated molded panel 101. In this manner, according to various embodiments, the panel-support deck 121 (i.e. in engagement with the separated molded panel 101, while the temperature-regulating heater 122 is in operation) may serve as a thermal buffer, whereby heat may be transferred from the molded panel 101 to the panel-support deck 121, thereby initiating a controlled and/or gradual cooling process of the molded panel 101 on the panel-support deck 121.

In various embodiments, when both the panel-support deck 121 and the panel-handling head 126 include respective temperature-regulating heaters 122, 127, the separated molded panel 101 may be gradually cooled to a first temperature (e.g. lower than the heat release temperature but higher than the ambient temperature) by the panel-support deck 121 (i.e. via its respective temperature-regulating heater 122), and further gradually cooled to a second temperature (e.g. lower than the first temperature) by the panel-handling head 126 (i.e. via its respective temperature-regulating heater 127). Thus, in such embodiments, the temperature-regulating heater 122 of the panel-support deck 121 may be operable to regulate a temperature of the panel-support deck 121 (e.g. its deck surface 121a) and, in turn, the separated molded panel 101 engaged therewith to a level between the heat release temperature and the first temperature, while the temperature-regulating heater 127 of the panel-handling head 126 may be operable to regulate a temperature of the panel-handling head 126 (e.g. its engagement surface 126a) and, in turn, the separated molded panel 101 engaged therewith to another level between the first temperature and the second temperature (and/or the ambient temperature).

According to various embodiments, the panel-support deck 121 may include (e.g. optionally and/or further include) a (or at least one) panel-support-deck-retaining member 123. According to various embodiments, the panel-support-deck-retaining member 123 may be a retaining member (e.g. another respective of discrete retaining member) configured to releasably retain (e.g. releasably hold or secure) the separated molded panel 101 to the deck surface 121a (e.g. upward-facing surface) of the panel-support deck 121 (e.g. when the panel-support deck 121 is engaged with the separated molded panel 101 and/or as the separated molded panel 101 is conveyed by the panel-support deck 121 from the release workstation 110 to the panel-handling workstation 120). According to various embodiments, the panel-support-deck-retaining member 123 may be associated with (e.g. at or proximal to) the deck surface 121a of the panel-support deck 121. As some examples, according to various embodiments, the panel-support-deck-retaining member 123 may include a vacuum suction mechanism (e.g. vacuum plate, vacuum suction holes, vacuum cups, etc.), a gripping mechanism (e.g. grippers or clamps), electrostatic chuck, end effector, etc. According to various embodiments, operation of the panel-support-deck-retaining member 123 may be based on a retaining-control signal. In various embodiments, this retaining-control signal may be transmitted or provided to the panel-support-deck-retaining member 123 (e.g. to instruct operation of the panel-support-deck-retaining member 123).

Thus, as an illustration, according to various embodiments, the panel-handling head 126 may initially be at a position (e.g. at an upper region within the panel-handling workstation 120) to facilitate movement of the panel-support deck 121 from the release workstation 110 (e.g. to receive the molded panel 101) and into the panel-handling workstation 120, underneath the panel-handling head 126. When the panel-support deck 121 (i.e. supporting the separated molded panel 101 thereon) is aligned with (e.g. positioned underneath) the panel-handling head 126, the panel-handling head 126 may be moved towards the separated molded panel 101 to engage the separated molded panel 101 and releasably retain the separated molded panel 101 to its engagement surface 126a (e.g. via the panel-handling-head-retaining member 128). Thereafter, according to various embodiments, the panel-handling head 126 (i.e. having the separated molded panel 101 retained thereto) may move or lift the separated molded panel 101 away from the panel-support deck 121 (e.g. for transferring the separated molded panel 101 to another location or out of the processing system 1000). In various embodiments, the panel-support deck 121 may thereafter return to the release workstation 110 to receive another separated molded panel 101 from another intermediate panel-carrier assembly 104 which may be fed into the processing system 1000.

Additionally, according to various embodiments, the panel-handling head 126 (or the entire panel-handling unit 125) may be configured to be movable laterally along a “lateral-panel-handling-head-movement plane” 226q (see FIG. 2A) which may be non-parallel (e.g. perpendicular or substantially perpendicular) to the panel-handling-head-movement plane 126p. In various embodiments, the lateral-panel-handling-head-movement plane 226q may be a substantially flat plane which may be substantially horizontally-oriented (e.g. relative to the base of the processing system 1000, and/or when the processing system 1000 is disposed and/or oriented upright on the external floor or ground). Accordingly, in various embodiments, the panel-handling head 126 (or the panel-handling unit 125) may be capable and/or operable to be movable in lateral or sideways directions (e.g. opposite linear directions), within or along the lateral-panel-handling-head-movement plane 226q. According to various embodiments, the lateral or sideways directions of movements of the panel-handling head 126 (or the panel-handling unit 125) along the lateral-panel-handling-head-movement plane 226q may be, but is not limited to being, non-parallel (e.g. perpendicular or substantially perpendicular) to the lateral or sideways directions of movements of the panel-support deck 121 along the panel-support-deck-movement plane 121p (i.e. between the panel-handling workstation 120 and the release workstation 110). According to various embodiments, such a setup of the panel-handling head 126 (or the panel-handling unit 125) may allow or enable the separated molded panel 101 that is held by the panel-handling head 126 to be conveyed or transported by the panel-handling head 126 (e.g. to another workstation or location for further processing or handling, or for transferring the separated molded panel 101 out of the processing system 1000). As a non-limiting example, according to various embodiments, the processing system 1000 may include a respective rail, track or slide (e.g. linear rail, track or slide) for enabling and/or guiding such lateral movement of the panel-handling head 126 along the lateral-panel-handling-head-movement plane 226q. According to various embodiments, movement of the panel-handling head 126 along the lateral-panel-handling-head-movement plane 226q may be based on a movement signal. In various embodiments, this movement signal may be transmitted or provided to the panel-handling head 126 (e.g. to instruct movement of the panel-handling head 126).

With reference to FIG. 1C and FIG. 1D, according to various embodiments, the carrier-handling workstation 130 may be capable of receiving, or may be configured to receive, the separated carrier 103 from the release workstation 110. In other words, in various embodiments, the separated carrier 103 may be conveyed or moved from the release workstation 110 to the carrier-handling workstation 130.

For instance, according to various embodiments, the carrier-support deck 111 may be configured and/or operable to be movable between the release workstation 110 and the carrier-handling workstation 130 for conveying the separated carrier 103 from the release workstation 110 to the carrier-handling workstation 130. In particular, in various embodiments, the carrier-support deck 111 may be movable at least from the release workstation 110 to the carrier-handling workstation 130 to convey the separated carrier 103 from the release workstation 110 to the carrier-handling workstation 130. Accordingly, according to various embodiments, the carrier-support deck 111 may correspond to (e.g. may be or may resemble) a discrete transfer (or shuttle or sliding or movable) table (or platform). According to various embodiments, the carrier-support deck 111 may be movable along a movement plane (herein may be referred to as “carrier-support-deck-movement plane” 111p) (see FIG. 1D) which may extend between the release workstation 110 and the carrier-handling workstation 130. In various embodiments, the carrier-support-deck-movement plane 111p may be a substantially flat plane which may be substantially horizontally-oriented (e.g. relative to the base of the processing system 1000, and/or when the processing system 1000 is disposed and/or oriented upright on the external floor or ground). Accordingly, in various embodiments, the carrier-support deck 111 may be capable and/or operable to be movable in lateral or sideways directions (e.g. opposite linear directions), within or along the carrier-support-deck-movement plane 111p, between the release workstation 110 and the carrier-handling workstation 130. According to various embodiments, the lateral or sideways directions of movements of the carrier-support deck 111 along the carrier-support-deck-movement plane 111p, between the release workstation 110 and the carrier-handling workstation 130, may be, but is not limited to being, non-parallel (e.g. perpendicular or substantially perpendicular) to the lateral or sideways directions of movements of the panel-support deck 121 along the panel-support-deck-movement plane 121p (i.e. between the panel-handling workstation 120 and the release workstation 110). According to various embodiments, movement of the carrier-support deck 111 along the carrier-support-deck-movement plane 111p may be based on a movement signal. In various embodiments, this movement signal may be transmitted or provided to the carrier-support deck 111 or to an actuator coupled thereto (e.g. to instruct movement of the carrier-support deck 111).

According to various embodiments, the carrier-support-deck-movement plane 111p may be non-parallel (e.g. perpendicular or substantially perpendicular) to the release-head-movement plane 116p.

According to various embodiments, the lateral-panel-handling-head-movement plane 226q may be, but is not limited to being, parallel to the carrier-support-deck-movement plane 111p. However, according to various embodiments, the lateral-panel-handling-head-movement plane 226q may be spatially separated from the carrier-support-deck-movement plane 111p. In other words, in various embodiments, the panel-handling head 126 and the carrier-support deck 111 may be movable at different heights within the processing system 1000 (e.g. when the processing system 1000 is disposed and/or oriented upright on the external floor or ground). Thus, for instance, in various embodiments, the panel-handling head 126 and the carrier-support deck 111 may be movable along separate and/or parallel rails, tracks or slides, at different heights, within the processing system 1000.

According to various embodiments, both the carrier-support-deck-movement plane 111p and the panel-support-deck-movement plane 121p may be parallel to each other. Thus, in various embodiments, both the carrier-support-deck-movement plane 111p and the panel-support-deck-movement plane 121p may be horizontal or substantially horizontally-oriented. However, according to various embodiments, the directions of movements of the carrier-support deck 111 along the carrier-support-deck-movement plane 111p may be non-parallel (e.g. perpendicular or substantially perpendicular) to the directions of movements of the panel-support deck 121 along the panel-support-deck-movement plane 121p. Thus, with reference to FIG. 1D, according to various embodiments, the carrier-support deck 111 and the panel-support deck 121 may be movable along different and/or non-parallel (e.g. perpendicular) directions from each other. According to various embodiments, this may enable or allow the carrier-support deck 111 and the panel-support deck 121 to be movable in a synchronous and/or coordinated and/or concurrent and/or simultaneous manner, along the carrier-support-deck-movement plane 111p and the panel-support-deck-movement plane 121p, respectively (e.g. without coinciding with each other and/or other workstations). In particular, in various embodiments, both the carrier-support deck 111 and the panel-support deck 121 may be configured and/or operable to be movable concurrently and/or simultaneously—(i) with the carrier-support deck 111 moving out of the release workstation 110 and/or towards (or into) the carrier-handling workstation 130 (e.g. to transport the carrier 103 (with the thermal release adhesive tape 102 adhered thereto), separated from the molded panel 101, to the carrier-handling workstation 130) and (ii) with the panel-support deck 121 moving out of the panel-handling workstation 120 and/or towards (or into) the release workstation 110 (e.g. to receive the separated molded panel 101). In various embodiments, movements of both the carrier-support deck 111 and the panel-support deck 121 may be coordinated such that the carrier-support deck 111 may leave the release workstation 110 before the panel-support deck 121 enters the release workstation 110, or they may both leave the panel-handling workstation 120 and the carrier-handling workstation 130, respectively, at the same time. As a further illustration, according to various embodiments, both the panel-support deck 121 and the carrier-support deck 111 may be operable to leave the release workstation 110 at the same time (e.g. to convey the separated molded panel 101 and the separated carrier 103 to the panel-handling workstation 120 and the carrier-handling workstation 130, respectively, in a synchronous manner). For instance, the panel-support deck 121 may be movable along the panel-support-deck-movement plane 121p which may be above or over the carrier-support-deck-movement plane 111p of the carrier-support deck 111. Thus, in various embodiments, after the molded panel 101 has been separated from the carrier 103, the carrier 103 may remain on the carrier-support deck 111 while the panel-support deck 121 may be positioned or moved to a position above or over both the carrier-support deck 111 and the separated carrier 103 on the carrier-support deck 111 to receive the separated molded panel 101 from the release-head 116. Thereafter, the panel-support deck 121 (i.e. with the separated molded panel 101 thereon) and the carrier-support deck 111 (i.e. with the separated carrier 103 thereon) may move out of the release workstation 110 in a coordinated and/or synchronous manner (e.g. concurrently or simultaneously). Accordingly, according to various embodiments, the panel-support-deck-movement plane 121p of the panel-support deck 121 may be spatially separated from and/or parallel to and/or above the carrier-support-deck-movement plane 111p of the carrier-support deck 111. It is also envisaged that, in various other embodiments, the panel-support-deck-movement plane 121p may be below the carrier-support-deck-movement plane 111p. According to various embodiments, such a setup may further facilitate the coordinated and/or concurrent movements of the carrier-support deck 111 and the panel-support deck 121.

According to various embodiments, each of the panel-handling workstation 120 and the carrier-handling workstation 130 may respectively be linked (e.g. directly linked) to and/or positioned downstream (e.g. immediately downstream) of the release workstation 110.

For instance, according to various embodiments, the processing system 1000 may further include a respective (e.g. another discrete) rail, track or slide (e.g. linear rail, track or slide) which may extend between (e.g. between at least) the release workstation 110 and the carrier-handling workstation 130, for the carrier-support deck 111 to be movable (e.g. slidable) and/or guided between the release workstation 110 and the carrier-handling workstation 130. In this manner, according to various embodiments, the panel-handling workstation 120 and the carrier-handling workstation 130 may be linked to the release workstation 110 via respective rails, tracks or slides.

According to various embodiments, the carrier-handling workstation 130 may include a carrier-handling unit 135. According to various embodiments, the carrier-handling unit 135 may include a carrier-handling head 136. According to various embodiments, the carrier-handling head 136 may be an actuation member (e.g. a respective or discrete actuation member or actuatable head). According to various embodiments, the carrier-handling head 136 may be positioned opposite and/or above the carrier-support deck 111, within the carrier-handling workstation 130 (e.g. when the carrier-support deck 111 is moved into the carrier-handling workstation 130). For instance, within the carrier-handling workstation 130, the carrier-support deck 111 may be within a lower region while the carrier-handling head 136 may be within an upper region thereof.

According to various embodiments, the carrier-handling head 136 may be configured and/or operable to be movable along a movement plane (herein may be referred to as “carrier-handling-head-movement plane” 136p) within the carrier-handling workstation 130. According to various embodiments, the carrier-handling-head-movement plane 136p may be a substantially flat plane which may be substantially vertically-oriented (e.g. relative to the base of the processing system 1000, and/or when the processing system 1000 is disposed and/or oriented upright on the external floor or ground). According to various embodiments, the carrier-handling-head-movement plane 136p at the carrier-handling workstation 130 may be parallel or substantially parallel with the release-head-movement plane 116p at the release workstation 110 and/or with the panel-handling-head-movement plane 126p at the panel-handling workstation 120. Further, the carrier-handling-head-movement plane 136p may be non-parallel (e.g. perpendicular or substantially perpendicular) to the carrier-support-deck-movement plane 111p. According to various embodiments, the carrier-handling-head-movement plane 136p may be aligned with (e.g. may intersect) the carrier-support deck 111 (e.g. its deck surface 121a) when the carrier-support deck 111 is positioned within (e.g. moved into) the carrier-handling workstation 130. According to various embodiments, the carrier-handling unit 135 may be operable in a manner corresponding to (e.g. resembling) a press unit or a top press, with the carrier-handling head 136 being movable in upward and downward directions (e.g. opposite linear directions), within or along the carrier-handling-head-movement plane 136p, so as to be capable of engaging the separated carrier 103 when the separated carrier 103 is aligned with and/or positioned underneath the carrier-handling head 136 and/or capable of lifting the separated carrier 103 from (e.g. away from) the carrier-support deck 111. Accordingly, according to various embodiments, when the carrier-support deck 111 is positioned within the carrier-handling workstation 130 and/or is aligned with the carrier-handling head 136, the carrier-handling head 136 may be configured and/or operable to be movable or moved towards the deck surface 111a of the carrier-support deck 111 to engage the separated carrier 103 on the deck surface 111a of the carrier-support deck 111. According to various embodiments, movement of the carrier-handling head 136 along the carrier-handling-head-movement plane 136p may be based on a movement signal. In various embodiments, this movement signal may be transmitted or provided to the carrier-handling head 136 (e.g. to instruct movement of the carrier-handling head 136 or actuatable head).

According to various embodiments, the carrier-handling head 136 may include a (or at least one) carrier-handling-head-retaining member 138. According to various embodiments, the carrier-handling-head-retaining member 138 may be a retaining member configured to releasably retain (e.g. releasably hold or secure) the separated carrier 103 to an engagement surface 136a (e.g. a downward-facing surface) of the carrier-handling head 136 (e.g. when the carrier-handling head 136 is engaged with the separated carrier 103). According to various embodiments, the carrier-handling-head-retaining member 138 may be associated with (e.g. at or proximal to) the engagement surface 136a of the carrier-handling head 136. As some examples, according to various embodiments, the carrier-handling-head-retaining member 138 may include a vacuum suction mechanism (e.g. vacuum plate, vacuum suction holes, vacuum cups, etc.), a gripping mechanism (e.g. grippers or clamps), electrostatic chuck, end effector, etc. According to various embodiments, operation of the carrier-handling-head-retaining member 138 may be based on a retaining-control signal. In various embodiments, this retaining-control signal may be transmitted or provided to the carrier-handling-head-retaining member 138 (e.g. to instruct operation of the carrier-handling-head-retaining member 138).

Accordingly, according to various embodiments, the carrier-handling head 136 may initially be at a position (e.g. at an upper region within the carrier-handling workstation 130) to facilitate movement of the carrier-support deck 111 (i.e. supporting the separated carrier 103) into the carrier-handling workstation 130. Thereafter, when or with the carrier-support deck 111 (i.e. supporting the separated carrier 103 thereon) aligned with the carrier-handling head 136 (e.g. its carrier-handling-head-movement plane 136p), the carrier-handling head 136 may be moved towards the separated carrier 103 to engage the separated carrier 103 and releasably retain the separated carrier 103 to its engagement surface 136a (e.g. via the carrier-handling-head-retaining member 138). Subsequently, according to various embodiments, the carrier-handling head 136 may move or lift the separated carrier 103 away from the carrier-support deck 111, thereby allowing the carrier-support deck 111 to be movable out of the carrier-handling workstation 130 (e.g. to return to the release workstation 110).

FIG. 1E shows schematically the processing system 1000 having an offload workstation 140 linked to the carrier-handling workstation 130 of FIG. 1C and FIG. 1D, according to various embodiments.

According to various embodiments, the processing system 1000 may include (e.g. optionally further include) the offload workstation 140 which may be linked (e.g. directly linked) to the carrier-handling workstation 130. In particular, the offload workstation 140 may be downstream (e.g. immediately downstream) of the carrier-handling workstation 130.

According to various embodiments, the offload workstation 140 may be capable of receiving, or may be configured to receive, the separated carrier 103 from the carrier-handling workstation 130.

For instance, according to various embodiments, the offload workstation 140 may include a respective deck or an offload tray 141 which may be configured and/or operable to be movable between the offload workstation 140 and the carrier-handling workstation 130 for conveying the separated carrier 103 from the carrier-handling workstation 130 to the offload workstation 140. In particular, in various embodiments, the offload tray 141 may be movable at least from the carrier-handling workstation 130 to the offload workstation 140 to convey the separated carrier 103 from the carrier-handling workstation 130 to the offload workstation 140. Thus, the offload tray 141 may correspond to (e.g. may be or may resemble) a discrete transfer (or shuttle or sliding or movable) table (or platform). According to various embodiments, the offload tray 141 may be movable along a movement plane (herein may be referred to as “offload-tray-movement plane” 141p) which may extend between the offload workstation 140 and the carrier-handling workstation 130. In various embodiments, the offload-tray-movement plane 141p may be a flat plane which may be substantially horizontally-oriented (e.g. relative to the base of the processing system 1000, and/or when the processing system 1000 is disposed and/or oriented upright on the external floor or ground). According to various embodiments, the offload-tray-movement plane 141p may be non-parallel (e.g. perpendicular or substantially perpendicular) to the carrier-handling-head-movement plane 136p. Accordingly, in various embodiments, the offload tray 141 may be capable and/or operable to be movable in lateral or sideways directions (e.g. opposite linear directions), within or along the offload-tray-movement plane 141p, between the offload workstation 140 and the carrier-handling workstation 130. In various embodiments, the lateral or sideways directions of movements of the offload tray 141 along the offload-tray-movement plane 141p, between the offload workstation 140 and the carrier-handling workstation 130, may be, but is not limited to being, parallel with the lateral or sideways directions of movements of the panel-support deck 121 along the panel-support-deck-movement plane 121p (i.e. between the panel-handling workstation 120 and the release workstation 110). As a non-limiting example, according to various embodiments, the processing system 1000 may include a respective rail, track or slide (e.g. linear rail, track or slide) which may extend between the offload workstation 140 and the carrier-handling workstation 130, for the offload tray 141 to be movable (e.g. slidable) and/or guided therealong. Thus, in various embodiments, the offload tray 141 may be capable and/or operable to be movable out of the offload workstation 140 and into the carrier-handling workstation 130, and out of the carrier-handling workstation 130 and into the offload workstation 140. According to various embodiments, movement of the offload tray 141 along the offload-tray-movement plane 141p may be based on a movement signal. In various embodiments, this movement signal may be transmitted or provided to the offload tray 141 or to an actuator coupled thereto (e.g. to instruct movement of the offload tray 141).

Additionally, in various embodiments, an upper side or surface of the offload tray 141 (i.e. capable of supporting the separated carrier 103 thereon) may include rollers or roller conveyors, or a movable conveyor or roller belt, etc., for the separated carrier 103 to move or be further conveyed thereby.

Accordingly, according to various embodiments, after the carrier-handling head 136 has lifted the separated carrier 103 away from the carrier-support deck 111 (i.e. at the carrier-handling workstation 130), the offload tray 141 may be configured and/or operable to be movable or moved into the carrier-handling workstation 130, to align with the carrier-handling head 136 (i.e. which may be releasably retaining the separated carrier 103 thereto) so as to receive the separated carrier 103 from the carrier-handling head 136 (e.g. on an upper side or surface of the offload tray 141).

In particular, according to various embodiments, when or with the offload tray 141 positioned within the carrier-handling workstation 130 to align with the carrier-handling head 136 (i.e. within the carrier-handling workstation 130), the carrier-handling head 136 may be operable to release the separated carrier 103 onto the offload tray 141. According to various embodiments, when or with the separated carrier 103 on the offload tray 141 (in other words, after the offload tray 141 receives the carrier 103 from the carrier-handling head 136 at the carrier-handling workstation 130), the offload tray 141 may be operable to be moved out of the carrier-handling workstation 130 and into the offload workstation 140, thereby conveying the separated carrier 103 from the carrier-handling workstation 130 to the offload workstation 140 (e.g. for transferring the carrier 103 out of the processing system 1000).

As an illustration, according to various embodiments, the offload-tray-movement plane 141p of the offload tray 141 may be spatially separated from and/or parallel to and/or above the carrier-support-deck-movement plane 111p of the carrier-support deck 111. As such, in this example, according to various embodiments, when the offload tray 141 is moved into the carrier-handling workstation 130, the offload tray 141 may be above the carrier-support deck 111 (or above the carrier-support-deck-movement plane 111p), to align with the carrier-handling head 136 and/or the separated carrier 103 which may be releasably retained to the carrier-handling head 136 (e.g. without any intervening physical obstruction between the separated carrier 103 and the offload tray 141). It is also envisaged that, in various other embodiments, the offload-tray-movement plane 141p may be below the carrier-support-deck-movement plane 111p.

As another illustration, according to various embodiments, the carrier-support deck 111 may be configured and/or operable to be movable into and out of the carrier-handling workstation 130, synchronously with the movement of the offload tray 141. Thus, in various embodiments, the carrier-support deck 111 may be moved out of the carrier-handling workstation 130, to facilitate and/or enable movement of the offload tray 141 into the carrier-handling workstation 130. It is envisaged that, in this example, the carrier-support deck 111 and the offload tray 141 may be movable along a same plane, or they may respectively be movable along different and spatially separated planes (e.g. one above the other).

According to various embodiments, upon (or with) alignment of the offload tray 141 and the carrier-handling head 136 (i.e. releasably retaining the separated carrier 103), the carrier-handling head 136 may be configured and/or operable to be moved (i.e. together with the releasably retained separated carrier 103) towards the offload tray 141 to release and dispose or place the separated carrier 103 onto the offload tray 141. In particular, according to various embodiments, the carrier-handling head 136 may be lowered along the carrier-handling-head-movement plane 136p until the separated carrier 103 engages an upper side or surface of the offload tray 141, before releasing the separated carrier 103 onto the offload tray 141. Thereafter, in various embodiments, the carrier-handling head 136 may be moved in an opposite direction, away from the offload tray 141, to facilitate movement of the offload tray 141 (i.e. with the separated carrier 103 supported thereon) out of the carrier-handling workstation 130 and into the offload workstation 140. Accordingly, in various embodiments, after the carrier-handling head 136 has released or deposited the separated carrier 103 onto the offload tray 141, the offload tray 141 may transport or convey the separated carrier 103 to the offload workstation 140 (e.g. for unloading of the carrier 103 from the processing system 1000).

According to various embodiments, with reference to a top view of FIG. 1T, the carrier 103 may include an orientation feature 103a (e.g. a chamfer or a chamfered corner or edge, marking, notch, or other physical identifier) that may be utilized to indicate an orientation of the carrier 103 within the system 1000. In various embodiments, the orientation identification of the carrier 103 may be required to ensure proper alignment and handling of the carrier 103 (and/or the molded panel 101 which may be attached thereto) within the system 1000. As an illustration, according to various embodiments, when the orientation feature 103a includes the chamfered corner, it may be formed by cutting a corner of an otherwise square or squarish carrier 103.

According to various embodiments, the lateral or sideways directions of movements of the offload tray 141 along the offload-tray-movement plane 141p may be non-parallel (e.g. perpendicular or substantially perpendicular) to the lateral or sideways directions of movements of the carrier-support deck 111 along the carrier-support-deck-movement plane 111p. In other words, according to various embodiments, the carrier-support deck 111 and the offload tray 141 may be movable along different and/or non-parallel (e.g. perpendicular) and/or different directions from each other. According to various embodiments, in such a setup, the carrier-handling head 136 may further be configured and/or operable to rotate the separated carrier 103—before the carrier-handling head 136 releases the separated carrier 103 onto the offload tray 141, and while the carrier-handling-head-retaining member 138 still releasably retains the separated carrier 103 to the engagement surface 136a of the carrier-handling head 136—by an angle (e.g. a right angle or substantially 90°) (e.g. clockwise, when viewing the processing system 1000 from a top or plan view) substantially equal to an angle (e.g. a right angle) formed between the directions (e.g. linear directions) of movements of the offload tray 141 along the offload-tray-movement plane 141p and the directions (e.g. linear directions) of movements of the carrier-support deck 111 along the carrier-support-deck-movement plane 111p (e.g. to facilitate alignment of the separated carrier 103 within the processing system 1000). In particular, the carrier-handling head 136 (or at least a lower portion thereof with the engagement surface 136a) may be configured to be rotatable about a “carrier-handling-unit-rotation axis” 136r (see FIG. 1C) which may be a vertical or substantially vertical axis (e.g. relative to the base of the processing system 1000, and/or when the processing system 1000 is disposed and/or oriented upright on the external floor or ground) and/or which may extend through the carrier-handling head 136 (e.g. through a central axis thereof) and/or which may be aligned (e.g. parallel and/or coincident) with the carrier-handling-head-movement plane 136p.

In various embodiments, the angle of rotation of the carrier 103 about the carrier-handling-unit-rotation axis 136r may be selected not solely based on the relative directions of movement of the offload tray 141 and the carrier-support deck 111, but may alternatively or additionally be based on alignment requirements which may be imposed by the offload workstation 140 and/or the carrier-handling workstation 130 and/or other factor(s). According to various embodiments, the rotation of the carrier 103 about the carrier-handling-unit-rotation axis 136r may be determined by any one or a combination of factors, including but not limited to, layout of the workstations (e.g. offload workstation 140 and/or the carrier-handling workstation 130), positional requirements of upstream and/or downstream processes or automation, etc., within the processing system 1000.

According to various embodiments, rotational movement of the carrier-handling head 136 about the carrier-handling-unit-rotation axis 136r may be based on a movement signal. In various embodiments, this movement signal may be transmitted or provided to the carrier-handling head 136 (e.g. to instruct rotational movement of the carrier-handling head 136).

FIG. 1F shows schematically the processing system 1000 having the offload workstation 140 linked directly to the release workstation 110, according to various other embodiments.

It is also envisaged that, in various other embodiments, the offload workstation 140 may be linked directly to the release workstation 110 as shown, for example, in FIG. 1F. In other words, in various other embodiments, the offload workstation 140 may be immediately downstream of the release workstation 110.

Accordingly, as an example, with reference to FIG. 1F, in various other embodiments, the carrier-support deck 111 may be configured and/or operable to be movable between the release workstation 110 and the offload workstation 140 (i.e. which may be immediately downstream of the release workstation 110) for conveying the separated carrier 103 from the release workstation 110 directly to the offload workstation 140 (e.g. without any carrier-handling workstation 130 between the release workstation 110 and the offload workstation 140, or without any carrier-handling workstation 130 within the processing system 1000).

FIG. 1G to FIG. 1J show schematically an adhesive-removal tool 131 in operation, according to various embodiments.

With reference to FIG. 1G to FIG. 1J, according to various embodiments, the processing system 1000 may include the adhesive-removal tool 131 which may be configured to remove the thermal release adhesive tape 102 from the carrier 103. In various embodiments, the thermal release adhesive tape 102 may still remain adhered on the separated carrier 103 after the molded panel 101 has been released and separated from the carrier 103 at the release workstation 110 as the press-sensitive layer 102a of the thermal release adhesive tape 102 may still retain its adhesivity even after being heated to the heat release temperature and/or even after the release operation has been performed.

To illustrate, referring to FIG. 1G to FIG. 1J, the adhesive-removal tool 131 may be configured to remove the thermal release adhesive tape 102 (e.g. remaining on the carrier 103 after the molded panel 101 is separated from the carrier 103), when the carrier-support deck 111 supporting the carrier 103 and the remaining thermal release adhesive tape 102 is positioned relative to or aligned with the adhesive-removal tool 131. For instance, according to various embodiments, the adhesive-removal tool 131 may be configured to initially detach a peripheral portion 1022 of the thermal release adhesive tape 102 away from (e.g. above or upward of) the carrier 103. Subsequently, the adhesive-removal tool 131 may be configured to engage (e.g. hold) the peripheral portion 1022 of the thermal release adhesive tape 102, while another remaining portion 1024 of the thermal release adhesive tape 102 is still adhered to the carrier 103. Consequently, the adhesive-removal tool 131 may be configured to remove the remaining portion 1024 of the thermal release adhesive tape 102 from the carrier 103. According to various embodiments, the adhesive-removal tool 131 may be movable between a first edge portion 102d of the carrier 103 and an opposite second edge portion 102e of the carrier 103, while the adhesive-removal tool 131 holds the thermal release adhesive tape 102, thereby removing the thermal release adhesive tape 102 across the carrier 103 from the first edge portion 102d to the second edge portion 102e.

As an illustration, according to various embodiments, the adhesive-removal tool 131 may include an attachment mechanism configured to hold the peripheral portion 1022 (which may include a raised segment 1026, described below) of the thermal release adhesive tape 102. In various embodiments, the attachment mechanism may include a clamping mechanism 137 (e.g. gripper, clamp, jaw, or fingers) to grip the peripheral portion 1022 of the thermal release adhesive tape 102. As shown in FIG. 1G, the clamping mechanism 137 may include a first clamp finger 1372 and a second clamp finger 1374 opposing to each other. Further, as shown in FIG. 1H, the first clamp finger 1372 and the second clamp finger 1374 move towards to each other (as shown by the opposing dashed arrows in FIG. 1H) to apply a clamping force to retain (or pinch) the raised segment 1026 of the peripheral portion 1022 of the thermal release adhesive tape 102 therebetween. Alternatively, according to various other embodiments, the attachment mechanism may include a vacuum-based mechanism (e.g. suction cup) (not shown) to pick up the peripheral portion 1022 of the thermal release adhesive tape 102. The attachment mechanism may be operable based on corresponding control signals to engage the peripheral portion 1022 of the thermal release adhesive tape 102. According to various embodiments, the adhesive-removal tool 131 may be actuated to move across the carrier 103 (e.g. from the first edge portion 102d to the opposite second edge portion 102e) while holding onto the thermal release adhesive tape 102, so as to peel or pull the remaining portion 1024 of the thermal release adhesive tape 102 from the carrier 103 (as shown in FIG. 11) so as to remove the thermal release adhesive tape 102 completely from the carrier 103 (as shown in FIG. 1H). The adhesive-removal tool 131 may also be configured to follow a predetermined path or motion profile (e.g. linear, arcuate, or multi-segment) to facilitate complete detachment of the thermal release adhesive tape 102 from the carrier 103.

In various embodiments, to facilitate engagement with the thermal release adhesive tape 102 and to initiate the adhesive removal process, the adhesive-removal tool 131 may further include or employ a (mechanical) separation-facilitating tool 132. For example, the separation-facilitating tool 132 may include a plough element 133 (e.g. at least one blade) which may be configured to move laterally or parallel to (or plough) the peripheral portion 1022 of the thermal release adhesive tape 102 to snag or catch onto the thermal release adhesive tape 102 and induce the formation of the raised segment 1026 (e.g. as shown in FIG. 1H resembling a “wave” along the peripheral portion 1022 of the thermal release adhesive tape 102). The raised segment 1026 may then be more readily gripped, peeled, or pulled by the adhesive-removal tool 131. In various embodiments, this initial separation step may be performed prior to, or in coordination with, the actuation of the adhesive-removal tool 131, thereby enabling a continuous and reliable removal of the thermal release adhesive tape 102 across the carrier 103 surface.

As an example, according to various embodiments, the separation-facilitating tool 132 may be positioned and/or oriented to be along a same plane as the thermal release adhesive tape 102 and then pushed against a lateral side or edge of the thermal release adhesive tape 102 to create the raised segment 1026 of the thermal release adhesive tape 102. The raised segment 1026 may then be directly grasped by the opposing first and second clamp fingers 1372, 1374 of the clamping mechanism 137 to initiate the peeling or removal of the thermal release adhesive tape 102.

FIG. 1K to FIG. 1N show schematically another mode of operation of the adhesive-removal tool 131, according to various other embodiments.

As another example, according to various other embodiments, the separation-facilitating tool 132 may include the plough element 133 which may restricted from lateral or sideways movement (in other words, may be immovable in lateral directions) but may be configured to be movable in upward and downward directions along a “plough-element-movement plane” 133p which may be parallel or substantially parallel to the release-head-movement plane 116p. Specifically, the plough element 133 may be configured to be movable away from or towards the thermal release adhesive tape 102 on the carrier 103, when the thermal release adhesive tape 102 (i.e. on the carrier 103) and the plough element 133 are aligned with each other (e.g. along the plough-element-movement plane 133p).

In various embodiments, the plough element 133 may initially be in a raised position to facilitate movement of the carrier-support deck 111 (i.e. supporting the carrier 103 with the thermal release adhesive tape 102), until the peripheral portion 1022 of the thermal release adhesive tape 102 is aligned with (e.g. positioned underneath) the plough element 133. Thereafter, the plough element 133 may be lowered towards the peripheral portion 1022 of the thermal release adhesive tape 102 to engage the peripheral portion 1022 of the thermal release adhesive tape 102 (as shown in 1L). Thereafter, the carrier-support deck 111 (i.e. supporting the carrier 103 having the thermal release adhesive tape 102) may then be moved laterally or sideways (e.g. along the carrier-support-deck-movement plane 111p), relative to the plough element 133 (i.e. which may be stationary at this juncture and engaged with the peripheral portion 1022 of the thermal release adhesive tape 102) (as shown in FIG. 1M), thereby causing the peripheral portion 1022 of the thermal release adhesive tape 102 to snag or catch against the plough element 133 and induce formation of the raised segment 1026 (as shown in FIG. 1N) as the thermal release adhesive tape 102 is moved against the plough element 133. Once the raised segment 1026 is formed, it may be more readily gripped, peeled, or pulled by the adhesive-removal tool 131. After this process is completed, the plough element 133 may be raised or moved away from the carrier-support deck 111 to facilitate movement of the carrier-support deck 111 away from the plough element 133 (e.g. to another workstation or location of the processing system 1000).

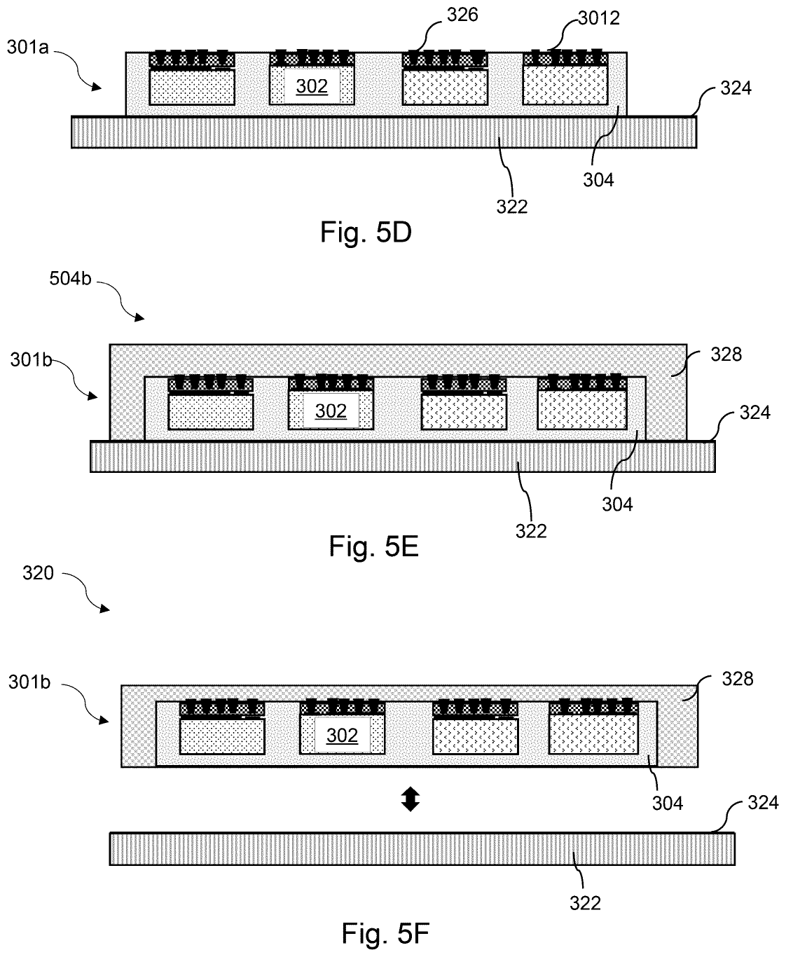

FIG. 10 and FIG. 1P show schematically a mechanism for operating the adhesive-removal tool 131 according to the mode described with reference to FIG. 1K to FIG. 1N, according to various embodiments. In particular, FIG. 10 schematically show a cross-sectional view, taken along line A-A of FIG. 1K, according to various embodiments.

As an example, according to various embodiments, with reference to FIG. 10 and FIG. 1P, the separation-facilitating tool 132 may include one or more blades 134a for engaging a first peripheral portion 1022a of the thermal release adhesive tape 102, one or more blades 134b for engaging a second (opposite) peripheral portion 1022b of the thermal release adhesive tape 102, and one or more blades 134c for engaging an central peripheral portion 1022c of the thermal release adhesive tape 102 (e.g. between the first peripheral portion 1022a and the second peripheral portion 1022b of the thermal release adhesive tape 102).

According to various embodiments, the plurality of blades 134 may be mounted to a blade-support head 139 of the separation-facilitating tool 132. For instance, according to various embodiments, the blades 134 may be fixedly attached to the blade-support head 139. Alternatively, according to various other embodiments, the blades 134 may be coupled to the blade-support head 139 via a damping mechanism (e.g. a spring-based mechanism, or elastomeric interface) (not shown) (e.g. for controlled engagement of the blades 134 with the thermal release adhesive tape 102, for example, to ensure sufficient contact between the blades 134 and the thermal release tape 102, while also preventing excessive force from being applied by the blades 134 onto the thermal release adhesive tape 102). In various embodiments, the plurality of blades 134 may be arranged along a straight or substantially straight line or axis (i.e. forming a linear or substantially linear array or arrangement of blades 134). In various embodiments, such an arrangement of the blades 134 may facilitate engagement of the blades 134 with the thermal release adhesive tape 102 in a linear or substantially linear manner (i.e. across a width of the thermal release adhesive tape 102).

In various embodiments, a density of the blades 134a, 134b (e.g. number of blades 134 per unit length or area, thickness of the blades 134, etc.) may be greater at the peripheral portions 1022a, 1022b of the thermal release adhesive tape 102 compared to the central peripheral portion 1022c. According to various embodiments, this may help facilitate more effective raised segment 1026 formation, as the thermal release adhesive tape 102 at the peripheral portions 1022a, 1022b may exhibit stronger resistance, which may make it more difficult to initiate peeling. However, it is also envisaged that, in various other embodiments, the density of the blades 134a, 134b at each of the peripheral portions 1022a, 1022b of the thermal release adhesive tape 102 may be equal to the density of blades 134c at the central peripheral portion 1022c of the thermal release adhesive tape 102.

As an example, according to various embodiments, with reference to FIG. 10, the plough element 133 may include a first pair of blades 134a attached to a first peripheral portion 139a of the blade-support head 139 (e.g. in a linear single-file arrangement, or in a lateral side-by-side arrangement) for engaging the first peripheral portion 1022a of the thermal release adhesive tape 102. Similarly, the plough element 133 may further include another pair of blades 134b attached to a second (opposite) peripheral portion 139b of the blade-support head 139 for engaging the second peripheral portion 1022b of the thermal release adhesive tape 102. Further, in various embodiments, the plough element 133 may include a single blade 134c attached to an inner portion 139c of the blade-support head 139, between the first peripheral portion 139a and the second peripheral portion 139b of the blade-support head 139. In various other embodiments, the plough element 133 may include a pair of blades 134c attached to the inner portion 139c of the blade-support head 139.

According to various embodiments, the blade-support head 139 may be operatively coupled to an actuator 80 (e.g. a pneumatic driver, linear actuator, etc.) of the processing system 1000 which may be configured and/or operable to move the blade-support head 139 together with the blades 134, along the plough-element-movement plane 133p and relative to the thermal release adhesive tape 102 on the carrier 103.

According to various embodiments, a plurality of clamp fingers 1372 of the clamping mechanism 137 may cooperate with a corresponding plurality of opposing clamp fingers 1374 of the clamping mechanism 137 (shown in FIG. 1G to FIG. 1N) to grip or pinch the raised segment 1026 of the thermal release adhesive tape 102 after it has been formed, to initiate the peeling or removal of the thermal release adhesive tape 102.

In various embodiments, movement of the blades 134 along the plough-element-movement plane 133p (see FIG. 1K) may be independent of movement of the attachment mechanism (e.g. clamp fingers 1372, 1374 of the clamping mechanism 137). In other words, in various embodiments, the blades 134 may be movable relative to the attachment mechanism. However, it is also envisaged that, in various other embodiments, the blades 134 and the attachment mechanism (e.g. clamp fingers 1372, 1374) may be configured to be movable in tandem or synchronously as a single unit, in the directions along the plough-element-movement plane 133p (as required).

In various embodiments, the plough element 133, or the plurality of blades 134 of the plough element 133, may be positioned between (e.g. directly between) the opposing clamp fingers 1372 and 1374 of the clamping mechanism 137. In other words, in various embodiments, the plough element 133, or the plurality of blades 134 of the plough element 133, may be positioned along a central axis of the attachment mechanism.

According to various embodiments, the adhesive-removal tool 131 may be, or may be part of, an independent de-taping or adhesive-removal module within the processing system 1000. Alternatively, in various other embodiments, this de-taping or adhesive-removal module may be integrated with any suitable location of the processing system 1000, for instance, at or within the release workstation 110 or any workstation downstream of the release workstation 110 such as at or within the carrier-handling workstation 130.

Alternatively, it is also envisaged that, according to various other embodiments, the removal of the thermal release adhesive tape 102 may not be performed within the processing system 1000. Instead, in various other embodiments, the carrier 103—along with the thermal release adhesive tape 102 still attached thereto—may (e.g. optionally) be offloaded from the processing system 1000 (e.g. without undergoing adhesive removal). In such other embodiments, subsequent removal of the thermal release adhesive tape 102 may then be carried out in a separate downstream process or handled externally from the processing system 1000.

FIG. 1Q shows schematically the processing system 1000 having a pre-heating workstation 150 linked to the release workstation 110, according to various embodiments.

According to various embodiments, the processing system 1000 may include (e.g. optionally further include) the pre-heating workstation 150 which may be linked (e.g. directly linked) to the release workstation 110. In particular, the pre-heating workstation 150 may be upstream (e.g. immediately upstream) of the release workstation 110.

According to various embodiments, the pre-heating workstation 150 may be capable of receiving, or may be configured to receive, the intermediate panel-carrier assembly 104, before it reaches or is subsequently conveyed to the release workstation 110.

In various embodiments, the pre-heating workstation 150 may be configured to receive the intermediate panel-carrier assembly 104 based on the overall setup and how the processing system 1000 may fit into an entire production or manufacturing or assembly or packaging process. Thus, for instance, the intermediate panel-carrier assembly 104 may be fed into the pre-heating workstation 150 with the molded panel 101 at the topside of the intermediate panel-carrier assembly 104, via manual feeding or via a feeder workstation 160 (described in FIG. 1Q below).

According to various embodiments, the pre-heating workstation 150 may include a pre-heating deck 151 (e.g. a respective or discrete deck, table, platform, stage, etc.) which may include a deck surface 151a (e.g. an upper or upward-facing surface) which may receive and/or support the intermediate panel-carrier assembly 104 thereon. In particular, the deck surface 151a of the pre-heating deck 151 may be capable of supporting the intermediate panel-carrier assembly 104 thereon, with the intermediate panel-carrier assembly 104 in an orientation with the molded panel 101 at the topside of the intermediate panel-carrier assembly 104. In other words, according to various embodiments, with the intermediate panel-carrier assembly 104 disposed on the deck surface 151a of the pre-heating deck 151, the carrier 103 of the intermediate panel-carrier assembly 104 may be between the molded panel 101 of the intermediate panel-carrier assembly 104 and the deck surface 151a of the pre-heating deck 151.

According to various embodiments, the pre-heating deck 151 may further include a pre-heating heater 152 configured to heat (e.g. pre-heat) the intermediate panel-carrier assembly 104 (e.g. to an intermediate temperature below the heat release temperature, or between an ambient temperature and the heat release temperature), when the intermediate panel-carrier assembly 104 is supported on the deck surface 151a of the pre-heating deck 151. As a non-limiting example, according to various embodiments, the intermediate temperature may be approximately 120° C. To illustrate, according to various embodiments, the pre-heating heater 152 may be associated with the deck surface 151a of the pre-heating deck 151, such that the pre-heating deck 151 may be operable to pre-heat the intermediate panel-carrier assembly 104 when the deck surface 151a of the pre-heating deck 151 is engaged with the intermediate panel-carrier assembly 104. For instance, the pre-heating heater 152 may be disposed at the deck surface 151a of the pre-heating deck 151 so as to be in thermal communication or thermal coupling with the intermediate panel-carrier assembly 104 when it is supported on the deck surface 151a of the pre-heating deck 151. As an example, according to various embodiments, the pre-heating heater 152 may be arranged (e.g. along the deck surface 151a of the pre-heating deck 151) so as to be in direct contact with the intermediate panel-carrier assembly 104 when it is supported on the deck surface 151a of the pre-heating deck 151. As some other examples, according to various embodiments, the pre-heating heater 152 may be embedded within the deck surface 151a (or embedded within an upper portion of the pre-heating deck 151 having the deck surface 151a), or may be coupled to the deck surface 151a (e.g. while being positioned underneath the deck surface 151a), in a manner so as to be capable of heating the deck surface 151a (e.g. by conducting heat or thermal energy to the deck surface 151a). Accordingly, in various embodiments, the deck surface 151a may be capable of conducting heat from the pre-heating heater 152 to the intermediate panel-carrier assembly 104. Thus, in various embodiments, the deck surface 151a may include or may be composed of a heat-conducting or thermally-conductive material. In various embodiments, a layer of thermal interface material may be disposed on the deck surface 151a (e.g. between the deck surface 151a and the intermediate panel-carrier assembly 104). Accordingly, according to various embodiments, the carrier 103 of the intermediate panel-carrier assembly 104 may be in direct contact (e.g. direct thermal contact) with, or in indirect thermal contact with, the deck surface 151a and/or the pre-heating heater 152 of the pre-heating deck 151. As a non-limiting example, according to various embodiments, the pre-heating heater 152 of the pre-heating deck 151 may include or may be a heating plate. In various embodiments, this heating plate may form or may serve as the deck surface 151a of the pre-heating deck 151. In various other embodiments, this heating plate may be discrete from the deck surface 151a of the pre-heating deck 151. For instance, the discrete heating plate may be positioned underneath the deck surface 151a and may be thermally coupled to the deck surface 151a. Nevertheless, it is also envisaged that, in various other embodiments, the pre-heating heater 152 of the pre-heating deck 151 may be implemented in any other suitable form and/or manner, including but not limited to solid-state heating elements, radiative heating arrangements (e.g. coupled, directly or indirectly, to the pre-heating deck 151), or any other suitable configuration capable of delivering the desired thermal effect. According to various embodiments, the pre-heating heater 152 of the pre-heating deck 151 may provide pre-heating based on a pre-heating-control signal. According to various embodiments, this pre-heating-control signal may be transmitted or provided to the pre-heating heater 152 of the pre-heating deck 151 once or after the intermediate panel-carrier assembly 104 is positioned on the pre-heating deck 151 within the pre-heating workstation 150 and/or before a release operation is performed on the intermediate panel-carrier assembly 104 at the release workstation 110. Thus, for instance, in various embodiments, the processing system 1000 (e.g. the pre-heating deck 151) may include a sensor configured to detect engagement between the pre-heating deck 151 and the intermediate panel-carrier assembly 104 (e.g. for triggering the pre-heating-control signal).

According to various embodiments, the pre-heating deck 151 may include (e.g. optionally and/or further include) a (or at least one) pre-heating-deck-retaining member 153. According to various embodiments, the pre-heating-deck-retaining member 153 may be a retaining member (e.g. another respective of discrete retaining member) configured to releasably retain (e.g. releasably hold or secure) the intermediate panel-carrier assembly 104 to the deck surface 151a (e.g. upward-facing surface) of the pre-heating deck 151 (e.g. when the pre-heating deck 151 is engaged with the intermediate panel-carrier assembly 104). According to various embodiments, the pre-heating-deck-retaining member 153 may be associated with (e.g. at or proximal to) the deck surface 151a of the pre-heating deck 151. As some examples, according to various embodiments, the pre-heating-deck-retaining member 153 may include a vacuum suction mechanism (e.g. vacuum plate, vacuum suction holes, vacuum cups, etc.), a gripping mechanism (e.g. grippers or clamps), electrostatic chuck, end effector, etc. According to various embodiments, operation of the pre-heating-deck-retaining member 153 may be based on a retaining-control signal. In various embodiments, this retaining-control signal may be transmitted or provided to the pre-heating-deck-retaining member 153 (e.g. to instruct operation of the pre-heating-deck-retaining member 153).

According to various embodiments, the pre-heating workstation 150 (e.g. the pre-heating heater 152 thereof) may be configured to gradually heat the intermediate panel-carrier assembly 104 to the intermediate temperature, thereby causing a temperature of the intermediate panel-carrier assembly 104 to gradually increase to the intermediate temperature and then stay or remain at or around the intermediate temperature over a pre-determined period of time.

According to various embodiments, the pre-heating workstation 150 may include (e.g. further include) a pre-heating unit 155. According to various embodiments, the pre-heating unit 155 may include a pre-heating head 156. According to various embodiments, the pre-heating head 156 may be an actuation member (e.g. a respective or discrete actuation member or actuatable head). According to various embodiments, the pre-heating head 156 may be positioned opposite and/or above the pre-heating deck 151, within the pre-heating workstation 150 (or when they are both within the pre-heating workstation 150). For instance, within the pre-heating workstation 150, the pre-heating deck 151 may be within a lower region while the pre-heating head 156 may be within an upper region thereof.

According to various embodiments, the pre-heating head 156 may be configured and/or operable to be movable along a movement plane (herein may be referred to as “pre-heating-head-movement plane” 156p) within the pre-heating workstation 150. According to various embodiments, the pre-heating-head-movement plane 156p may be a substantially flat plane which may be substantially vertically-oriented (e.g. relative to the base of the processing system 1000, and/or when the processing system 1000 is disposed and/or oriented upright on the external floor or ground). According to various embodiments, the pre-heating-head-movement plane 156p at the pre-heating workstation 150 may be parallel or substantially parallel with the release-head-movement plane 116p at the release workstation 110. According to various embodiments, the pre-heating-head-movement plane 156p may be aligned with (e.g. may intersect) the pre-heating deck 151 (e.g. its deck surface 151a) when the pre-heating deck 151 is positioned within the pre-heating workstation 150. According to various embodiments, the pre-heating unit 155 may be operable in a manner corresponding to (e.g. resembling) a press unit or a top press, with the pre-heating head 156 being movable in upward and downward directions (e.g. opposite linear directions), within or along the pre-heating-head-movement plane 156p, so as to be capable of engaging the intermediate panel-carrier assembly 104 when the intermediate panel-carrier assembly 104 is aligned with and/or positioned underneath the pre-heating head 156 and/or capable of lifting at the intermediate panel-carrier assembly 104 (e.g. as required, relative to the pre-heating deck 151). Accordingly, according to various embodiments, when the pre-heating deck 151 is positioned within the pre-heating workstation 150 and/or is aligned with the pre-heating head 156, the pre-heating head 156 may be configured and/or operable to be movable or moved towards the deck surface 151a of the pre-heating deck 151 to engage the molded panel 101 at the topside of the intermediate panel-carrier assembly 104 (i.e. supported on the deck surface 151a of the pre-heating deck 151). According to various embodiments, movement of the pre-heating head 156 along the pre-heating-head-movement plane 156p may be based on a movement signal. In various embodiments, this movement signal may be transmitted or provided to the pre-heating head 156 (e.g. to instruct movement of the pre-heating head 156).

According to various embodiments, the pre-heating head 156 may include a (or at least one) pre-heating-head-retaining member 158. According to various embodiments, the pre-heating-head-retaining member 158 may be a retaining member configured to releasably retain (e.g. releasably hold or secure) the intermediate panel-carrier assembly 104 to an engagement surface 156a (e.g. a downward-facing surface) of the pre-heating head 156 (e.g. when the pre-heating head 156 is engaged with the intermediate panel-carrier assembly 104). According to various embodiments, the pre-heating-head-retaining member 158 may be associated with (e.g. at or proximal to) the engagement surface 156a of the pre-heating head 156. As some examples, according to various embodiments, the pre-heating-head-retaining member 158 may include a vacuum suction mechanism (e.g. vacuum plate, vacuum suction holes, vacuum cups, etc.), a gripping mechanism (e.g. grippers or clamps), electrostatic chuck, end effector, etc. According to various embodiments, operation of the pre-heating-head-retaining member 158 may be based on a retaining-control signal. In various embodiments, this retaining-control signal may be transmitted or provided to the pre-heating-head-retaining member 158 (e.g. to instruct operation of the pre-heating-head-retaining member 158).

According to various embodiments, the pre-heating head 156 may include (e.g. optionally and/or further include) a pre-heating heater 157 (e.g. a respective or a further pre-heating heater) which may be associated with the engagement surface 156a of the pre-heating head 156, such that the pre-heating heater 157 may be operable to pre-heat the intermediate panel-carrier assembly 104 when the engagement surface 156a of the pre-heating head 156 is engaged with the intermediate panel-carrier assembly 104. For instance, the pre-heating heater 157 may be disposed at the engagement surface 156a of the pre-heating head 156. According to various embodiments, this pre-heating heater 157 of the pre-heating head 156 may be configured and/or operable to cooperatively pre-heat the intermediate panel-carrier assembly 104, together with the pre-heating heater 152 of the pre-heating deck 151 (e.g. to the intermediate temperature)—when the intermediate panel-carrier assembly 104 is between (e.g. interposed or sandwiched between) the pre-heating deck 151 and the pre-heating head 156 (in other words, when the intermediate panel-carrier assembly 104 is supported on the deck surface 151a of the pre-heating deck 151 and when the engagement surface 156a of the pre-heating head 156 is engaged with the intermediate panel-carrier assembly 104). According to various embodiments, the pre-heating heater 157 of the pre-heating head 156 may provide pre-heating based on a pre-heating-control signal. According to various embodiments, this pre-heating-control signal may be transmitted or provided to the pre-heating heater 157 of the pre-heating head 156 when the pre-heating head 156 is engaged with the intermediate panel-carrier assembly 104 and when the pre-heating deck 151 is also engaged with the intermediate panel-carrier assembly 104, to cooperatively pre-heat the intermediate panel-carrier assembly 104. In various embodiments, the processing system 1000 (e.g. the pre-heating head 156) may further include a sensor configured to detect engagement between the pre-heating head 156 and the intermediate panel-carrier assembly 104 (e.g. for triggering this pre-heating-control signal).

According to various embodiments, the pre-heating deck 151 may be configured and/or operable to be movable between the pre-heating workstation 150 and the release workstation 110. In particular, the pre-heating deck 151 may be movable at least from the pre-heating workstation 150 to the release workstation 110 to convey the intermediate panel-carrier assembly 104 from the pre-heating workstation 150 to the release workstation 110. Thus, the pre-heating deck 151 may correspond to (e.g. may be or may resemble) a discrete transfer (or shuttle or sliding or movable) table (or platform). According to various embodiments, the pre-heating deck 151 may be movable along a movement plane (herein may be referred to as “pre-heating-deck-movement plane” 151p) which may extend between the pre-heating workstation 150 and the release workstation 110. In various embodiments, the pre-heating-deck-movement plane 151p may be a substantially flat plane which may be substantially horizontally-oriented (e.g. relative to the base of the processing system 1000, and/or when the processing system 1000 is disposed and/or oriented upright on the external floor or ground). According to various embodiments, the pre-heating-deck-movement plane 151p may be non-parallel (e.g. perpendicular or substantially perpendicular) to the pre-heating-head-movement plane 156p. Accordingly, in various embodiments, the pre-heating deck 151 may be capable and/or operable to be movable in lateral or sideways directions (e.g. opposite linear directions), within or along the pre-heating-deck-movement plane 151p, between the pre-heating workstation 150 and the release workstation 110. In various embodiments, the lateral or sideways directions of movements of the pre-heating deck 151 along the pre-heating-deck-movement plane 151p, between the pre-heating workstation 150 and the release workstation 110, may be, but is not limited to being, non-parallel (e.g. perpendicular or substantially perpendicular) to the lateral or sideways directions of movements of the panel-support deck 121 along the panel-support-deck-movement plane 121p (i.e. between the panel-handling workstation 120 and the release workstation 110). As a non-limiting example, according to various embodiments, the processing system 1000 may include a rail, track or slide (e.g. linear rail, track or slide) which may extend between the pre-heating workstation 150 and the release workstation 110, for the pre-heating deck 151 to be movable (e.g. slidable) and/or guided therealong. According to various embodiments, movement of the pre-heating deck 151 along the pre-heating-deck-movement plane 151p may be based on a movement signal. In various embodiments, this movement signal may be transmitted or provided to the pre-heating deck 151 or to an actuator coupled thereto (e.g. to instruct movement of the pre-heating deck 151).

As an illustration, according to various embodiments, the pre-heating-deck-movement plane 151p may be parallel with the carrier-support-deck-movement plane 111p.

As an illustration, according to various embodiments, the pre-heating-deck-movement plane 151p of the pre-heating deck 151 may be spatially separated from and/or parallel to and/or above the carrier-support-deck-movement plane 111p of the carrier-support deck 111. As such, in this example, according to various embodiments, when the pre-heating deck 151 is moved into the release workstation 110, the pre-heating deck 151 may be above the carrier-support deck 111 (or above the carrier-support-deck-movement plane 111p), to align with the release-head 116 (e.g. without any intervening physical obstruction between the release-head 116 and the intermediate panel-carrier assembly 104 on the pre-heating deck 151)—so that the intermediate panel-carrier assembly 104 may be lifted from the pre-heating deck 151 by the release-head 116 (e.g. for subsequent processing of the intermediate panel-carrier assembly 104, such as performing the release operation, within the release workstation 110). It is also envisaged that, in various other embodiments, the pre-heating-deck-movement plane 151p may be below the carrier-support-deck-movement plane 111p. As an illustration, according to various embodiments, after the intermediate panel-carrier assembly 104 is lifted from the pre-heating deck 151 by the release-head 116, the pre-heating deck 151 may be moved out of the release workstation 110 (e.g. back into the pre-heating workstation 150), and the carrier-support deck 111 may be positioned within (e.g. moved into) the release workstation 110 so as to align with the release-head 116. Subsequently, the release-head 116 may release and/or dispose or place the intermediate panel-carrier assembly 104 onto the carrier-support deck 111 to firstly or initially pre-heat or increase a temperature of the intermediate panel-carrier assembly 104 to the heat release temperature and then initiate the release operation for separating the molded panel 101 from the carrier 103. Thus, according to various embodiments, when the pre-heating deck 151 with the intermediate panel-carrier assembly 104 thereon is moved into the release workstation 110, to align with the release-head 116, the release-head 116 may be movable or moved towards the pre-heating deck 151 to engage the intermediate panel-carrier assembly 104, releasably retain the intermediate panel-carrier assembly 104 to the engagement surface 116a of the release-head 116, and move the intermediate panel-carrier assembly 104 away from the pre-heating deck 151 for the release-head 116 to subsequently release the intermediate panel-carrier assembly 104 on the carrier-support deck 111 when the carrier-support deck is aligned (or positioned or moved into alignment) with the release-head 116 (e.g. within the release workstation 110). Accordingly, according to various embodiments, the carrier-support deck 111 may be movable along the carrier-support-deck-movement plane 111p, and the pre-heating deck 151 may be movable along the pre-heating-deck-movement plane 151p which may be parallel and/or spaced apart from the carrier-support-deck-movement plane 111p of the carrier-support deck 111 and/or the panel-support-deck-movement plane 121p of the panel-support deck 121.

As another illustration, according to various embodiments, the pre-heating-deck-movement plane 151p and the carrier-support-deck-movement plane 111p may be parallel and aligned (e.g. coincident) with each other. For instance, the processing system 1000 may include a single, continuous track, rail or slide for the pre-heating deck 151 and the carrier-support deck 111 to be movable therealong. Accordingly, in this example, the carrier-support deck 111 may be first moved out of the release workstation 110, to facilitate and/or enable movement of the pre-heating deck 151 into the release workstation 110.

According to various embodiments, with reference to FIG. 1Q, the processing system 1000 may include (e.g. optionally further include) the feeder workstation 160 which may be linked (e.g. directly linked) to the pre-heating workstation 150. In particular, the feeder workstation 160 may be upstream (e.g. immediately upstream) of the pre-heating workstation 150.

It is also envisaged that, in various other embodiments, other configurations of the feeder workstation 160 may be implemented. For instance, in various other embodiments (not shown), the feeder workstation 160 may be linked (e.g. directly linked) to the release workstation 110, and may be upstream (e.g. immediately upstream) of the release workstation 110 (e.g. for conveying an intermediate panel-carrier assembly 104 directly from the feeder workstation 160 to the release workstation 110), depending on an overall setup of the processing system 1000.

Referring back to FIG. 1Q, according to various embodiments, the feeder workstation 160 may be configured to receive the intermediate panel-carrier assembly 104, and to deliver or convey the intermediate panel-carrier assembly 104 to a corresponding workstation (e.g. the pre-heating workstation 150) that the feeder workstation 160 may be linked with. In other words, according to various embodiments, when the feeder workstation 160 is linked with the pre-heating workstation 150, it may be capable of delivering, or configured to deliver, the intermediate panel-carrier assembly 104 to the pre-heating workstation 150.

For instance, according to various embodiments, the feeder workstation 160 may include a feeding mechanism 161 (e.g. a respective conveying mechanism, deck or a feeder tray) which may be configured to initially receive the intermediate panel-carrier assembly 104. In various embodiments, the intermediate panel-carrier assembly 104 may be disposed onto an upper side or surface 161a of the feeding mechanism 161, for instance, via a robotic arm, pick-and-place system, automated guided vehicle or tool, a conveying belt, or by any other suitable means or mechanism.

In various embodiments, the upper side or surface 161a of the feeding mechanism 161 may be configured to support the intermediate panel-carrier assembly 104 thereon, and may further be configured to be capable of aligning (e.g. moving and/or to datum and/or referencing) the intermediate panel-carrier assembly 104 relative to an alignment structure 154 (e.g. a stopper, end stopper, or limiter, cylinder stopper, etc.). According to various embodiments, the alignment structure 154 may be, but is not limited to being, a physical structure at or within the pre-heating workstation 150. As some examples, according to various embodiments, the upper side or surface 161a of the feeding mechanism 161 may include rollers, roller conveyors, roller belt, etc., or any other rolling mechanism or any suitable movable conveyor, for aligning (e.g. moving) the intermediate panel-carrier assembly 104 relative to the alignment structure 154 at the pre-heating workstation 150, while the intermediate panel-carrier assembly 104 is on the upper side or surface 161a of the feeding mechanism 161 (i.e. having the rolling mechanism). For ease of description, such an upper side or surface 161a of the feeding mechanism 161 may also be referred to as a “conveyance surface” of the feeding mechanism 161.

According to various embodiments, the alignment structure 154 (e.g. stopper) at the pre-heating workstation 150 may ensure alignment of the intermediate panel-carrier assembly 104 relative to the pre-heating head 156 within the preheating workstation 150 by preventing unintended movement of the intermediate panel-carrier assembly 104 beyond a predetermined point or edge within the preheating workstation 150.

As an illustration, according to various embodiments, the alignment structure 154 (e.g. stopper), at the pre-heating workstation 150, may be configured and/or operable to be movable upward and downward, in directions parallel or substantially parallel to the pre-heating-head-movement plane 156p. Accordingly, in various embodiments, the alignment structure 154 may be moved upward to engage an edge of the intermediate panel-carrier assembly 104 (i.e. while the intermediate panel-carrier assembly 104 is on the conveyance surface of the feeding mechanism 161, within the pre-heating workstation 150), thereby aligning the intermediate panel-carrier assembly 104 with the pre-heating head 156 of the pre-heating workstation 150. Once alignment is completed and the intermediate panel-carrier assembly 104 is subsequently picked up by the pre-heating head 156, the alignment structure 154 may be moved downward to facilitate or allow movement of the pre-heating deck 151 into alignment with the pre-heating head 156 and the intermediate panel-carrier assembly 104 releasably retaining thereto.

According to various embodiments, the feeding mechanism 161 may be configured and/or operable to be movable between the feeder workstation 160 and the pre-heating workstation 150. In particular, the feeding mechanism 161 may be movable at least from the feeder workstation 160 to the pre-heating workstation 150 to convey the intermediate panel-carrier assembly 104 from the feeder workstation 160 to the pre-heating workstation 150. Thus, the feeding mechanism 161 may correspond to (e.g. may be or may resemble) a discrete transfer (or shuttle or sliding or movable) table (or platform). According to various embodiments, the feeding mechanism 161 may be movable along a movement plane (herein may be referred to as “feeding-mechanism-movement plane” 161p) which may extend between the feeder workstation 160 and the pre-heating workstation 150. In various embodiments, the feeding-mechanism-movement plane 161p may be a substantially flat plane which may be substantially horizontally-oriented (e.g. relative to the base of the processing system 1000, and/or when the processing system 1000 is disposed and/or oriented upright on the external floor or ground). According to various embodiments, the feeding-mechanism-movement plane 161p may be non-parallel (e.g. perpendicular or substantially perpendicular) to the pre-heating-head-movement plane 156p and/or to the release-head-movement plane 116p. In various embodiments, the feeding-mechanism-movement plane 161p may be, but is not limited to being, parallel to the panel-support-deck-movement plane 121p and/or to the offload-tray-movement plane 141p. Accordingly, in various embodiments, the feeding mechanism 161 may be capable and/or operable to be movable in lateral or sideways directions (e.g. opposite linear directions), within or along the feeding-mechanism-movement plane 161p, between the feeder workstation 160 and the pre-heating workstation 150. In various embodiments, the lateral or sideways directions of movements of the feeding mechanism 161 along the feeding-mechanism-movement plane 161p, between the feeder workstation 160 and the pre-heating workstation 150, may be, but is not limited to being, parallel with the lateral or sideways directions of movements of the panel-support deck 121 along the panel-support-deck-movement plane 121p (i.e. between the panel-handling workstation 120 and the release workstation 110). As a non-limiting example, according to various embodiments, the processing system 1000 may include a respective rail, track or slide (e.g. linear rail, track or slide) which may extend between the feeder workstation 160 and the pre-heating workstation 150, for the feeding mechanism 161 to be movable (e.g. slidable) and/or guided therealong. Thus, in various embodiments, the feeding mechanism 161 may be capable and/or operable to be movable out of the feeder workstation 160 and into the pre-heating workstation 150, and out of the pre-heating workstation 150 and into the feeder workstation 160. According to various embodiments, movement of the feeding mechanism 161 along the feeding-mechanism-movement plane 161p may be based on a movement signal. In various embodiments, this movement signal may be transmitted or provided to the feeding mechanism 161 or to an actuator coupled thereto (e.g. to instruct movement of the feeding mechanism 161).

Accordingly, according to various embodiments, when or with the pre-heating head 156 initially positioned at (or moved to) an upper region of the pre-heating workstation 150, the feeding mechanism 161 may be configured and/or operable to be movable into the pre-heating workstation 150, to align with the pre-heating head 156 (e.g. beneath the pre-heating head 156). Additionally, in various embodiments, while the feeding mechanism 161 is within the pre-heating workstation 150, the conveyance surface of the feeding mechanism 161 may align the intermediate panel-carrier assembly 104 relative to the alignment structure 154 at the pre-heating workstation 150 and, in turn, with the pre-heating head 156 of the pre-heating workstation 150.

In particular, according to various embodiments, when the feeding mechanism 161 with the intermediate panel-carrier assembly 104 thereon is moved into the pre-heating workstation 150, to align with the pre-heating head 156, the pre-heating head 156 may be movable or moved towards the feeding mechanism 161 to engage the intermediate panel-carrier assembly 104, releasably retain the intermediate panel-carrier assembly 104 to the engagement surface 156a of the pre-heating head 156, and move the intermediate panel-carrier assembly 104 away from the feeding mechanism 161 for the pre-heating head 156 to subsequently release or place the intermediate panel-carrier assembly 104 on the pre-heating deck 151 when the pre-heating deck is aligned (or positioned or moved into alignment) with the pre-heating head 156 (e.g. within the pre-heating workstation 150)—for pre-heating of the intermediate panel-carrier assembly 104 to the intermediate temperature.

As an illustration, according to various embodiments, the feeding-mechanism-movement plane 161p of the feeding mechanism 161 may be spatially separated from and/or parallel to and/or above the pre-heating-deck-movement plane 151p of the pre-heating deck 151. As such, in this example, according to various embodiments, when the feeding mechanism 161 is moved into the pre-heating workstation 150, the feeding mechanism 161 may be above the pre-heating deck 151 (or above the pre-heating-deck-movement plane 151p), to align with the pre-heating head 156 (e.g. without any intervening physical obstruction between the intermediate panel-carrier assembly 104 on the feeding mechanism 161 and the pre-heating head 156). It is also envisaged that, in various other embodiments, the feeding-mechanism-movement plane 161p may be below the pre-heating-deck-movement plane 151p.

As another illustration, according to various embodiments, the pre-heating deck 151 may be configured and/or operable to be movable into and out of the pre-heating workstation 150, synchronously with the movement of the feeding mechanism 161. Thus, in various embodiments, the pre-heating deck 151 may be moved out of the pre-heating workstation 150 (e.g. to the release workstation 110, or to an intermediate position between the pre-heating workstation 150 and the release workstation 110), to facilitate and/or enable movement of the feeding mechanism 161 into the pre-heating workstation 150 and/or alignment with the pre-heating head 156 within the pre-heating workstation 150. It is envisaged that, in this example, the pre-heating deck 151 and the feeding mechanism 161 may be movable along a same plane, or they may respectively be movable along different and spatially separated planes (e.g. one above the other).

According to various embodiments, upon (or with) alignment of the feeding mechanism 161 and the pre-heating head 156 (e.g. within the pre-heating unit 155), the pre-heating head 156 may be configured and/or operable to be movable or moved towards the feeding mechanism 161 to releasably retain and lift the intermediate panel-carrier assembly 104 away from the feeding mechanism 161 (e.g. using the pre-heating-head-retaining member 158). Accordingly, according to various embodiments, when the pre-heating head 156 (i.e. releasably retaining the intermediate panel-carrier assembly 104 thereto) is moved away from the feeding mechanism 161, it may facilitate movement of the feeding mechanism 161 (i.e. without any intermediate panel-carrier assembly 104 thereon) out of the pre-heating workstation 150 and back into the feeder workstation 160 (e.g. for receiving another intermediate panel-carrier assembly 104). According to various embodiments, the pre-heating head 156 may subsequently release and/or place the intermediate panel-carrier assembly 104 onto the pre-heating deck 151 (e.g. when the pre-heating deck 151 is in alignment with the pre-heating head 156).

According to various embodiments, each of the feeding-mechanism-movement plane 161p and the pre-heating-deck-movement plane 151p may be a horizontal or substantially horizontal plane (e.g. relative to the base of the processing system 1000, and/or when the processing system 1000 is disposed and/or oriented upright on the external floor or ground). However, in various embodiments, the lateral or sideways directions of movements of the feeding mechanism 161 along the feeding-mechanism-movement plane 161p (i.e. between the feeder workstation 160 and the pre-heating workstation 150) plane may be non-parallel (e.g. perpendicular or substantially perpendicular) to the lateral or sideways directions of movements of the pre-heating deck 151 along the pre-heating-deck-movement plane 151p. In other words, according to various embodiments, the feeding mechanism 161 and the pre-heating deck 151 may be movable along different and/or non-parallel (e.g. perpendicular) and/or different directions from each other. According to various embodiments, in such a setup, the pre-heating head 156 may further be configured and/or operable to rotate the intermediate panel-carrier assembly 104 about a “pre-heating-head-rotation axis” 156r which may be oriented vertically (e.g. relative to the base of the processing system 1000, and/or when the processing system 1000 is disposed and/or oriented upright on the external floor or ground) and/or extending through the pre-heating head 156 (e.g. through a central axis thereof) and/or which may be aligned (e.g. parallel and/or coincident) with the pre-heating-head-movement plane 156p—before the pre-heating head 156 releases the intermediate panel-carrier assembly 104 onto the pre-heating deck 151, and while the pre-heating head 156 still releasably retains the intermediate panel-carrier assembly 104 to the engagement surface 156a of the pre-heating head 156—by an angle (e.g. a right angle) (e.g. clockwise, when viewing the processing system 1000 from a top or plan view) substantially equal to an angle (e.g. a right angle) formed between the directions (e.g. linear directions) of movements of the feeding mechanism 161 along the feeding-mechanism-movement plane 161p and the directions (e.g. linear directions) of movements of the pre-heating deck 151 along the pre-heating-deck-movement plane 151p (e.g. to align the intermediate panel-carrier assembly 104 relative to the pre-heating workstation 150).

In various embodiments, the angle of rotation of the intermediate panel-carrier assembly 104 about the pre-heating-head-rotation axis 156r may be selected not solely based on the relative directions of movement of the feeding mechanism 161 and the pre-heating deck 151, but may alternatively or additionally be based on alignment requirements which may be imposed by the feeding workstation 160 and/or the pre-heating workstation 150 and/or other factor(s). According to various embodiments, the rotation of the intermediate panel-carrier assembly 104 about the pre-heating-head-rotation axis 156r may be determined by any one or a combination of factors, including but not limited to, layout of the workstations (e.g. feeding workstation 160 and/or the pre-heating workstation 150), positional requirements of upstream and/or downstream processes or automation, etc., within the system 1000.

According to various embodiments, rotational movement of the pre-heating head 156 about the pre-heating-head-rotation axis 156r may be based on a movement signal. In various embodiments, this movement signal may be transmitted or provided to the pre-heating head 156 (e.g. to instruct rotational movement of the pre-heating head 156).

FIG. 1R shows schematically the feeder workstation 160 and the pre-heating workstation 150, linked to each other, with the feeder workstation 160 having an alignment unit 165, according to various embodiments.

As another example, according to various embodiments, the feeder workstation 160 may include the alignment unit 165 for rotating the intermediate panel-carrier assembly 104 by the angle (e.g. in a clockwise direction, when viewing the processing system 1000 from a top or plan view) which may be substantially equal to the angle which may be formed between the directions (e.g. linear directions) of movements of the feeding mechanism 161 along the feeding-mechanism-movement plane 161p and the directions (e.g. linear directions) of movements of the pre-heating deck 151 along the pre-heating-deck-movement plane 151p.

For instance, according to various embodiments, the feeder workstation 160 may include (e.g. further include) the alignment unit 165. According to various embodiments, the alignment unit 165 may include an alignment-head 166. According to various embodiments, the alignment-head 166 may be an actuation member (e.g. a respective or discrete actuation member or actuatable head). According to various embodiments, the alignment-head 166 may be positioned opposite and/or above the feeding mechanism 161, within the feeder workstation 160 (e.g. when they are both within the feeder workstation 160). Accordingly, within the feeder workstation 160, the feeding mechanism 161 may be within a lower region while the alignment-head 166 may be within an upper region thereof.

According to various embodiments, the alignment-head 166 may be configured and/or operable to be movable along a movement plane (herein may be referred to as “alignment-unit-actuation-member-movement plane” 166p), at least within the feeder workstation 160. According to various embodiments, the alignment-unit-actuation-member-movement plane 166p may be a substantially flat plane which may be substantially vertically-oriented (e.g. relative to the base of the processing system 1000, and/or when the processing system 1000 is disposed and/or oriented upright on the external floor or ground). According to various embodiments, the alignment-unit-actuation-member-movement plane 166p (e.g. at the feeder workstation 160) may be parallel or substantially parallel with the release-head-movement plane 116p at the release workstation 110. Further, according to various embodiments, the alignment-unit-actuation-member-movement plane 166p may be non-parallel (e.g. perpendicular or substantially perpendicular) to the feeding-mechanism-movement plane 161p. According to various embodiments, the alignment-unit-actuation-member-movement plane 166p may be aligned with (e.g. may intersect) the feeding mechanism 161 (e.g. its upper side or surface) when the feeding mechanism 161 is positioned within the feeder workstation 160. According to various embodiments, the alignment unit 165 may be operable in a manner corresponding to (e.g. resembling) a press unit or a top press, with the alignment-head 166 being movable in upward and downward directions (e.g. opposite linear directions), within or along the alignment-unit-actuation-member-movement plane 166p, so as to be capable of engaging the intermediate panel-carrier assembly 104 when the intermediate panel-carrier assembly 104 is aligned with and/or positioned underneath the alignment-head 166 and/or capable of lifting the intermediate panel-carrier assembly 104 from (e.g. away from) the feeding mechanism 161. Accordingly, according to various embodiments, when the feeding mechanism 161 (i.e. with the intermediate panel-carrier assembly 104 thereon) is positioned within the feeder workstation 160 and/or is aligned with the alignment-head 166, the alignment-head 166 may be configured and/or operable to be movable or moved towards the upper side or surface 161a of the feeding mechanism 161 to engage the intermediate panel-carrier assembly 104 on the feeding mechanism 161. According to various embodiments, movement of the alignment-head 166 along the alignment-unit-actuation-member-movement plane 166p may be based on a movement signal. In various embodiments, this movement signal may be transmitted or provided to the alignment-head 166 (e.g. to instruct movement of the alignment-head 166).

According to various embodiments, the alignment-head 166 may include a (or at least one) alignment-head-retaining member 168. According to various embodiments, the alignment-head-retaining member 168 may be a retaining member configured to releasably retain (e.g. releasably hold or secure) the intermediate panel-carrier assembly 104 to an engagement surface 166a (e.g. a downward-facing surface) of the alignment-head 166 (e.g. when the alignment-head 166 is engaged with the intermediate panel-carrier assembly 104). According to various embodiments, the alignment-head-retaining member 168 may be associated with (e.g. at or proximal to) the engagement surface 166a of the alignment-head 166. As some examples, according to various embodiments, the alignment-head-retaining member 168 may include a vacuum suction mechanism (e.g. vacuum plate, vacuum suction holes, vacuum cups, etc.), a gripping mechanism (e.g. grippers or clamps), electrostatic chuck, end effector, etc. According to various embodiments, operation of the alignment-head-retaining member 168 may be based on a retaining-control signal. In various embodiments, this retaining-control signal may be transmitted or provided to the alignment-head-retaining member 168 (e.g. to instruct operation of the alignment-head-retaining member 168).

According to various embodiments, the alignment-head 166 (e.g. at least a lower portion thereof) may further be configured and/or operable to be rotatable about an “alignment-unit-rotation axis” 166r which may be oriented vertically (e.g. relative to the base of the processing system 1000, and/or when the processing system 1000 is disposed and/or oriented upright on the external floor or ground) and/or extending through the alignment-head 166 (e.g. through a central axis thereof) and/or which may be aligned (e.g. parallel and/or coincident) with the alignment-unit-actuation-member-movement plane 166p.

In particular, according to various embodiments, the alignment-head 166 may be configured to rotate the intermediate panel-carrier assembly 104—while the alignment-head 166 releasably retains the intermediate panel-carrier assembly 104 to the engagement surface 166a of the alignment-head 166, but before the alignment-head 166 releases the intermediate panel-carrier assembly 104 onto the feeding mechanism 161 for subsequent conveyance to the pre-heating workstation 150—about the alignment-unit-rotation axis 166r, by an angle (e.g. a right angle) substantially equal to an angle (e.g. a right angle) which may be formed between the directions (e.g. linear directions) of movements of the feeding mechanism 161 along the feeding-mechanism-movement plane 161p and the directions (e.g. linear directions) of movements of the pre-heating deck 151 along the pre-heating-deck-movement plane 151p.

In various embodiments, the angle of rotation of the intermediate panel-carrier assembly 104 about the alignment-unit-rotation axis 166r may be selected not solely based on the relative directions of movement of the feeding mechanism 161 and the pre-heating deck 151, but may alternatively or additionally be based on alignment requirements which may be imposed by the feeding workstation 160 and/or the pre-heating workstation 150 and/or other factor(s). According to various embodiments, the rotation of the intermediate panel-carrier assembly 104 about the alignment-unit-rotation axis 166r may be determined by any one or a combination of factors, including but not limited to, layout of the workstations (e.g. feeding workstation 160 and/or the pre-heating workstation 150), positional requirements of upstream and/or downstream processes or automation, etc.

According to various embodiments, rotational movement of the alignment-head 166 about the alignment-unit-rotation axis 166r may be based on a movement signal. In various embodiments, this movement signal may be transmitted or provided to the alignment-head 166 (e.g. to instruct rotational movement of the alignment-head 166).

FIG. 2A shows a schematic perspective diagram of a processing system 2000, according to various embodiments.

According to various embodiments, there may be provided the processing system (or, particularly, a panel release system) 2000. According to various embodiments, the processing system 2000 may include any one or more or all features of the processing system 1000, and vice versa.

According to various embodiments, the processing system 2000 may include a feeder workstation 260 (or feeder station), which may include any one or more or all features of the feeder workstation 160.

According to various embodiments, the processing system 2000 may include a pre-heating workstation 250 (or pre-heating or pre-heat station), which may include any one or more or all features of the pre-heating workstation 150. The pre-heating workstation 250 may be linked (e.g. directly or indirectly linked) with the feeder workstation 260 (e.g. via a transporting or conveying mechanism, such as one or more movable decks and/or actuation members of the processing system 2000) and may be downstream (e.g. immediately downstream) of the feeder workstation 260.

According to various embodiments, the processing system 2000 may include a release workstation 210 (or release station), which may include any one or more or all features of the release workstation 110. The release workstation 210 may be linked (e.g. directly or indirectly linked) with the pre-heating workstation 250 (e.g. via one or more movable decks and/or actuation members of the processing system 2000) and may be downstream (e.g. immediately downstream) of the pre-heating workstation 250.

According to various embodiments, the processing system 2000 may include a panel-handling workstation 220 (or panel-handling station), which may include any one or more or all features of the panel-handling workstation 120. The panel-handling workstation 220 may be linked (e.g. directly or indirectly linked) with the release workstation 210 (e.g. via one or more movable decks and/or actuation members of the processing system 2000) and may be downstream (e.g. immediately downstream) of the release workstation 210.

According to various embodiments, the processing system 2000 may include a carrier-handling workstation 230 (or carrier-handling station), which may include any one or more or all features of the carrier-handling workstation 130. The carrier-handling workstation 230 may be linked (e.g. directly or indirectly linked) with the release workstation 210 (e.g. via one or more movable decks and/or actuation members of the processing system 2000) and may be downstream (e.g. immediately downstream) of the release workstation 210.

In various embodiments, when the processing system 2000 includes both the panel-handling workstation 220 and the carrier-handling workstation 230, both the panel-handling workstation 220 and the carrier-handling workstation 230 may be linked to the release workstation 210 (e.g. via different/orthogonal faces or sides of the release workstation 210) and may both be immediately downstream of the release workstation 210 (e.g. from the different/orthogonal faces or sides of the release workstation 210).

According to various embodiments, the processing system 2000 may include an offload workstation 240 (or offload station), which may include any one or more or all features of the offload workstation 140. The offload workstation 240 may be linked (e.g. directly or indirectly linked) with the carrier-handling workstation 230 (e.g. via one or more movable decks and/or actuation members of the processing system 2000) and may be downstream (e.g. immediately downstream) of the carrier-handling workstation 230.

According to various embodiments, within the processing system 2000, the lateral-panel-handling-head-movement plane 226q of a panel-handling head of the panel-handling workstation 220 (e.g. similar or identical to the panel-handling head 126) may be parallel to and/or spatially separated from (e.g. above) an offload-tray-movement plane 241p. However, in various embodiments, directions of movements (as shown by a dashed arrow 222) of the panel-handling head of the panel-handling workstation 220 along the lateral-panel-handling-head-movement plane 226q may be perpendicular or substantially perpendicular to direction of movements (as shown by a solid arrow 242) of an offload tray of the offload workstation 240 (e.g. similar or identical to the offload tray 141) along the offload-tray-movement plane 241p. Accordingly, in various embodiments, after an intermediate panel-carrier assembly 104 has been processed by the processing system 2000, such that the molded panel 101 is separated from the carrier 103, the separated molded panel 101 and the separated carrier 103 may respectively be output from the processing system 2000 in substantially horizontally-oriented but mutually perpendicular or orthogonal directions (such as shown by the dashed arrow 222 and the solid arrow 242) from each other. Additionally, each of the separated molded panel 101 and the separated carrier 103 may be output at different heights within the processing system 2000. As an illustration, according to various embodiments, the panel-handling workstation 220 may include a panel-handling guide 229 (such as rail, track or slide) for guiding movement of a panel-handling head of the panel-handling workstation 220 (e.g. similar or identical to the panel-handling head 126) in the directions 222 along the lateral-panel-handling-head-movement plane 226q. In addition, according to various embodiments, the panel-handling guide 229 may further include an actuator (such as an electric actuator) which may be operable to actuate or cause the panel-handling head of the panel-handling workstation 220 to move (e.g. in the manner as described herein), based on the movement signal which may be transmitted or provided to the panel-handling head of the panel-handling workstation 220.

According to various embodiments, the processing system 2000 (and/or its constituent workstation(s), such as the release workstation 210, the panel-handling workstation 220, the carrier-handling workstation 230, the offload workstation 240, the pre-heating workstation 250, and/or the feeder workstation 260) may be implemented in a modular architecture. For instance, any one or more suitable workstations may be omitted, repositioned, or substituted, etc., as required.

FIG. 2B and FIG. 2C show other example configurations of the processing system 2000, according to various embodiments.

According to various embodiments, the spatial arrangement (or positioning) of any one or more workstations within the processing system 2000 may vary. For example, as shown in FIG. 2B, the feeding workstation 260, the pre-heating workstation 250 and the release workstation 210 may be arranged linearly or aligned along a linear axis (in other words, arranged in a linear layout). Thus, in this example, shown in FIG. 2B, according to various embodiments, the feeding workstation 260 and the release workstation 210 may be on opposite sides of the pre-heating workstation 250 (i.e. instead of being at orthogonal sides of the pre-heating workstation 250, or in a non-linear layout, as shown in FIG. 2A). Accordingly, in this example, according to various embodiments, the intermediate panel-carrier assembly 104 which may be fed into the feeding workstation 260 may be transferred along a linear or substantially linear path or route from the feeding workstation 260 to the pre-heating workstation 250 and, subsequently, to the release-workstation 210.

According to various embodiments, such modularity of the processing system 2000 may allow the processing system 2000 to be flexibly adapted to different manufacturing footprints, process or automation flows, and/or integration with other equipment, etc.

As another example, with reference to FIG. 2C, according to various embodiments, the release workstation 210 of the processing system 2000 may be configured or operable to output the separated carrier 103 directly (e.g. without routing the separated carrier 103 through the carrier-handling workstation 230 and/or the offload workstation 240). In other words, as an example, with reference to FIG. 2C, according to various embodiments, the carrier-handling workstation 230 and/or the offload workstation 240 may be omitted from the processing system 2000. That is, in various embodiments, any one or more workstations may selectively be omitted from the processing system 2000.

FIG. 3A shows schematically a control unit 180 which may be integrated into the processing system 1000, according to various embodiments. According to various embodiments, the control unit 180 may be integrated or coupled to any one or more components and/or workstations of the processing system 100, such as the release workstation 110, and/or a cutter workstation 170 (described later in FIG. 3B).

According to various embodiments, the control unit 180 (e.g. a control module, a processor, a controller or microcontroller, etc.) may be configured to control (e.g. either directly or indirectly) performance of a mechanical action, or to cause a mechanical action to be performed, on the intermediate panel-carrier assembly 104 to disturb or weaken the adhesive strength or adhesive bond between the molded panel 101 and the carrier 103 of the intermediate panel-carrier assembly 104, before the intermediate panel-carrier assembly 104 is heated to the release temperature (e.g. by the heater 112 of the carrier-support deck 111 and/or the heater 117 of the release-head 116) and/or before the molded panel 101 is separated (e.g. entirely separated and/or detached) from the carrier 103.

In other words, according to various embodiments, the processing system 1000 may include (e.g. further include) a pre-release (or “release-initiation”) arrangement (or operation, process, or mechanism) which may be configured to perform one or more mechanical actions on the intermediate panel-carrier assembly 104 to disturb or weaken the adhesive bond between the molded panel 101 and the carrier 103 of the intermediate panel-carrier assembly 104, before the molded panel 101 is separated (e.g. entirely separated and/or detached) from the carrier 103. According to various embodiments, the pre-release arrangement may be controlled by the control unit 180 to operate one or more components (e.g. the carrier-support deck 111 and/or a material-removal tool (e.g. a cutter 179) as described later in FIG. 3B) of the processing system 1000 to perform the mechanical action on the intermediate panel-carrier assembly 104 to disturb or weaken the adhesive strength or adhesive bond between the molded panel 101 and the carrier 103 of the intermediate panel-carrier assembly 104.

Specifically, according to various embodiments, the pre-release arrangement may be configured to apply one or more forces (e.g. a mechanical force, for instance, a shearing force or lateral forces by the carrier-support deck 111, or a cutting force by the material-removal tool (e.g. the cutter 179)) to the thermal release adhesive tape 102 to weaken the adhesive bond between the carrier 103 and the molded panel 101 of the intermediate panel-carrier assembly 104, before the molded panel 101 is completely or entirely separated or detached from the carrier 103.

As an illustration, with reference to FIG. 3A, according to various embodiments, the control unit 180 may be coupled (e.g. electrically and/or communicatively coupled, either directly or indirectly) to the release workstation 110. According to various embodiments, the control unit 180 may control or operate (e.g. operate at least) any one or more components of the processing system 1000 (e.g. within the release workstation 110).

In particular, according to various embodiments, the control unit 180 may be configured to control or instruct the carrier-support deck 111 to move (e.g. laterally, thereby resembling a shearing motion, along the carrier-support-deck-movement plane 111p) by a predetermined distance (e.g. predetermined short distance) relative to the release-head 116 (e.g. which may be at the heat release temperature), while the carrier-support deck 111 and the release-head 116 cooperatively retain the intermediate panel-carrier assembly 104 in such a manner that the carrier-support deck 111 and the release-head 116 may be in contact or engagement with the carrier 103 and the molded panel 101 of the intermediate panel-carrier assembly 104, respectively. According to various embodiments, the pre-release arrangement may be performed before the molded panel 101 is entirely or completely separated and/or detached or moved away from the carrier 103 (in other words, before the release operation is performed). According to various embodiments, the relative lateral movement between the carrier-support deck 111 and the release-head 116 during their cooperative retaining of the intermediate panel-carrier assembly 104 may mechanically agitate and/or disturb an adhesive interface between the molded panel 101 and the heat-sensitive layer 102a of the thermal release adhesive tape 102, thereby disturbing or weakening the adhesive bond (e.g. at the heat release temperature), weaken adhesive forces of the thermal release adhesive tape 102, and/or promote partial detachment of the molded panel 101 from the carrier 103 prior to full separation of the molded panel 101 and the carrier 103 from each other at the release workstation 110. According to various embodiments, this may facilitate or enhance an overall efficiency of the separation/release process which may be subsequently performed on the intermediate panel-carrier assembly 104 at the release workstation 110. As an example, according to various embodiments, the control unit 180 may be configured to control the carrier-support deck 111 to move (e.g. laterally) relative to the release-head 116 by the pre-determined short distance which may create the shearing motion which may be sufficient to induce mechanical stress, agitation, or displacement at the adhesive interface between the molded panel 101 and the heat-sensitive layer 102a of the thermal release adhesive tape 102, thereby initiating or assisting in the subsequent separation of the molded panel 101 from the thermal release adhesive tape 102. As a non-limiting example, the pre-determined short distance that the carrier-support deck 111 may be controlled (i.e. by the control unit 180) to move may be in a range between 0.5 to 3.5 mm, or particularly in a range between 1.5 to 2.5 mm, or more particularly by approximately or around 2 mm. In various embodiments, the carrier-support deck 111 may be controlled to move unidirectionally or bidirectionally (e.g. approximately 2 mm to the right and/or 2 mm to the left). In other words, the control unit 180 may be configured to control the carrier-support deck 111 to move relative to the release-head 116—while the release-head-retaining member 118 releasably retains the molded panel 101 of the intermediate panel-carrier assembly 104 to the engagement surface 116a of the release-head 116 and while the carrier-support-deck-retaining member 113 releasably retains the carrier 103 of the intermediate panel-carrier assembly 104 to the deck surface 111a of the carrier-support deck 111—by the pre-determined short distance, with the molded panel 101 and the carrier 103 still overlapping each other within the release workstation 110. Thus, in various embodiments, the carrier-support deck 111 may be controlled to move along the carrier-support-deck-movement plane 111p, within or while remaining in the release workstation 110 (i.e. with the carrier-support deck 111 and the release-head 116 respectively retaining the carrier 103 and the molded panel 101), before the molded panel 101 is subsequently and completely separated and/or detached from the carrier 103.

According to various embodiments, the processing system 1000 may include an actuator (e.g. motor) operably coupled to the carrier-support deck 111 and configured to drive its movement along the carrier-support-deck-movement plane 111p. Thus, according to various embodiments, the control unit 180 may be coupled (e.g. communicatively coupled) with the actuator so as to control its operation and, in turn, movement of the carrier-support deck 111. Accordingly, according to various embodiments, the control unit 180 may be configured to initiate, regulate, and/or synchronize the movement of the carrier-support deck 111 relative to the release-head 116, by controlling an operation of said actuator (e.g. motor), to achieve the desired mechanical effect (e.g. agitation, shearing, or displacement, etc.) at the interface between the molded panel 101 and the thermal release adhesive tape 102.

According to various embodiments, each of the carrier-support deck 111 and the release-head 116 may include corresponding alignment elements 182a, 182b (e.g. fiducial markers), which may be disposed at corresponding locations on the carrier-support deck 111 and the release-head 116, respectively. According to various embodiments, these alignment elements 182a, 182b may be configured to enable visual or sensor-based monitoring of relative lateral displacement between the carrier-support deck 111 and the release-head 116 when performing the abovesaid pre-release arrangement. For instance, according to various embodiments, the alignment elements 182a, 182b may be initially aligned with each other during cooperative heating (i.e. using the carrier-support deck 111 and the release-head 116) of the thermal release adhesive tape 102 of the intermediate panel-carrier assembly 104 to the heat release temperature, but before release (i.e. separation and detachment) of the molded panel 101 from the carrier 103. Subsequently, the alignment elements 182a, 182b of the carrier-support deck 111 and the release-head 116 may be misaligned with each other as a result of controlled relative lateral movement (e.g. shearing motion) of the carrier-support deck 111 relative to the stationary release-head 116 to agitate the adhesive interface between the molded panel 101 and the heat-sensitive layer 102a of the thermal release adhesive tape 102. According to various embodiments, the degree of misalignment between the alignment elements 182a, 182b may serve as a visual, optical, or sensor-detectable indicator that the pre-determined short-distance shearing motion has been performed. In various embodiments, the misalignment between the alignment elements 182a, 182b may be used to verify, measure, or calibrate the displacement induced by the actuator (e.g. motor for controlling movement of the carrier-support deck 111) under control of the control unit 180, ensuring that the agitation at the adhesive interface between the molded panel 101 and the thermal release adhesive tape 102 has occurred as intended. For example, in various embodiments, a sensor (e.g. an optical sensor, camera-based image recognition module, etc.) of the processing system 1000 may be positioned (e.g. within the release workstation 110) to detect relative alignment or misalignment of the alignment elements 182a, 182b. According to various embodiments, the sensor may be communicatively linked to the control unit 180, such that the control unit 180 may receive verification signals or measurement data confirming that the pre-determined short-distance displacement has been achieved. In various embodiments, the control unit 180 may use this information to validate, calibrate, or regulate the shearing operation and/or provide feedback for closed-loop control of the actuator (e.g. motor) responsible for moving the carrier-support deck 111 relative to the release-head 116 to perform the pre-release arrangement. As some examples, according to various embodiments, the alignment elements 182a, 182b may be (matching or complementary) textured or patterned formations on outer surfaces (e.g. outer side surfaces) of the carrier-support deck 111 and the release-head 116, or any other suitable type of fiducial markers (e.g. ink or paint-based markers).

Accordingly, in various embodiments, the pre-release arrangement of the processing system 1000 may include the carrier-support deck 111 (e.g. serving as a first mechanical component of the pre-release arrangement), the release-head 116 (e.g. serving as a second mechanical component of the pre-release arrangement), with the carrier-support deck 111 configured and/or operable to move in a direction along the carrier-support-deck-movement plane 111p (or in a direction non-parallel to the release-head-movement plane 116p), while the release-head-retaining member 118 releasably retains the molded panel 101 of the intermediate panel-carrier assembly 104 to the engagement surface 116a of the release-head 116 and while the carrier-support-deck-retaining member 113 releasably retains the carrier 103 of the intermediate panel-carrier assembly 104 to the deck surface 111a of the carrier-support deck 111. In various embodiments, the control unit 180 and/or the motor for actuating or moving the carrier-support deck 111 and/or the sensor (not shown) may also serve as component(s) for the pre-release arrangement.

FIG. 3B shows schematically the cutter workstation 170 for the processing system 1000, according to various embodiments.

As another example, according to various embodiments, the processing system 1000 may include (e.g. further include) the cutter (or cutting) workstation 170 for performing the pre-release arrangement. According to various embodiments, the cutter workstation 170 may be positioned upstream (e.g. either directly or indirectly) of the release workstation 110 (e.g. immediately upstream, or upstream with one or more intervening workstations or stages therebetween). According to various embodiments, the cutter workstation 170 may be linked (e.g. either directly, or indirectly, for instance, via the feeder workstation) to the release workstation 110 (e.g. via a transporting or conveying mechanism or arrangement of the processing system 1000, such as one or more movable decks and/or actuation members of the processing system 1000).

According to various embodiments, the cutter workstation 170 may include the material-removal tool, for instance, the cutter 179 (or cutting tool, cutting mechanism, etc.) configured to cut (e.g. separate or remove) at least a portion of the intermediate panel-carrier assembly 104 (e.g. at least a portion of molding materials of the molded panel 101), before the molded panel 101 is separated from the carrier 103 at the release workstation 110. It is also envisaged that, in various other embodiments, the cutter 179 may be configured to cut (e.g. separate or remove) at least a portion of molding materials of the molded panel 101 after the molded panel 101 is separated from the carrier 103 at the release workstation 110.

It is also envisaged that, in various other embodiments, the cutter 179 or the material-removal tool may be implemented within another workstation for the same purpose, for instance, at the feeder workstation 160, the release workstation 110, or the panel-handling workstation 120. Accordingly, in such other embodiments, the processing system 1000 may not include a discrete cutter workstation 170.

According to various embodiments, the cutter 179 may be operated relative to the molded panel 101 (e.g. within the cutter workstation 170 or another corresponding workstation) to cut at least the portion of molding materials of the molded panel 101, before the molded panel 101 is separated and/or detached from the carrier 103 by the release operation performed at the release workstation 110. In particular, in various embodiments, the cutter 179 may be operable to cut through a full thickness of the molded panel 101.

In various embodiments, the cutter 179 may serve as a respective mechanical component of the pre-release arrangement of the processing system 1000.

It is also envisaged that, in various other embodiments, the cutter 179 may be configured to cut at least the portion of molding materials of the molded panel 101 (e.g. into “Q-panels”, described later with reference to FIG. 3D), either before or after the molded panel 101 has been separated and detached from the carrier 103 by the release operation. In other words, in various other embodiments, the cutter 170 may operate on the molded panel 101 either before or after it has been completely released as a whole from the carrier 103.

FIG. 3C shows schematically the molded panel 101 (e.g. either adhered on the carrier 103 (as shown by the dashed square) before being released therefrom or existing independently after being released from the carrier 103) with a peripheral edge portion 101a cut by the cutter 179 either at the cutter workstation 170 or at another workstation as described above, according to various embodiments.

According to various embodiments, the cutter 179 may be configured and/or operable to cut (or remove) the peripheral edge portion 101a of the molded panel 101. In other words, in various embodiments, the control unit 180 may control or instruct the cutter 179 to cut entirely through or almost through the peripheral edge portion 101a of the molded panel 101.

According to various embodiments, the peripheral edge portion 101a may be a continuous and/or unbroken loop-shaped portion of the molded panel 101, which may surround or encircle an inner (or central) portion 101b thereof. However, it is also envisaged that, in various other embodiments, the peripheral edge portion 101a may refer to one or more discrete edge portion(s) of the molded panel 101. According to various embodiments, cutting of the peripheral edge portion 101a of the molded panel 101 may facilitate subsequent release of the molded panel 101 from the thermal release adhesive tape 102 since, in various embodiments, the peripheral edge portion 101a of the molded panel 101 may be more strongly adhered to the thermal release adhesive tape 102 than the inner portion 101b of the molded panel 101.

In various embodiments, the peripheral edge portion 101a of the molded panel 101 may correspond to (e.g. may be, or may be designated as) an inactive or a non-functional zone of the molded panel 101 (e.g. without any primary and/or functional and/or electronic elements, such as circuits, dies, etc.). In particular, in various embodiments, the peripheral edge portion 101a may include only or exclusively include molding materials without any dies, chips, etc., and/or other active or inactive circuitry components. On the other hand, the inner portion 101b of the molded panel 101 may correspond to an active or functional zone of the molded panel 101 (e.g. where primary and/or functional and/or electronic elements, such as circuits, dies, etc., may be located or disposed at).

As some non-limiting examples, according to various embodiments, the cutter 179 may include a laser cutter, a mechanical cutter (e.g. blade, saw, tool bit, router bit, etc.), or any other suitable cutter.

As an illustration, according to various embodiments, when the cutter 179 is or includes a laser cutter, it may be operable to direct a focused laser beam onto the molded panel 101 to selectively ablate, melt, or vaporize the molding material along predetermined cut paths (e.g. to separate the peripheral edge portion 101a from the inner portion 101b). In various embodiments, the laser cutter may be configured to follow a programmed cutting profile that may define a boundary of the peripheral edge portion 101a. As an example, according to various embodiments, the laser beam from the laser cutter may ablate, melt, or vaporize through the full height or thickness of the molded panel 101 along the boundary of the peripheral edge portion 101a. Accordingly, in various embodiments, the laser beam may cut the peripheral edge portion 101a of the molded panel 101 of the intermediate panel-carrier assembly 104. According to various embodiments, the laser cutter may be operated or controlled by the control unit 180 (e.g. based on a cutter-control signal).

As another illustration, according to various other embodiments, when the cutter 179 is or includes a mechanical cutter, it may be movable relative to the molded panel 101 to mechanically engage and/or separate (or remove) the molding material along designated cut lines. In various embodiments, the mechanical cutter may be mounted on a movable member (e.g. a movable head). In various embodiments, the movable member may be driven by an actuator (e.g. motor) which may be operated or controlled by the control unit 180 (e.g. based on a cutter-control signal).

According to various embodiments, the molded panel 101 may have a panel size slightly smaller than a carrier size of the carrier 103 (as shown by the dashed square, e.g. in a square shape, for instance, 700 mm×700 mm). Further, the peripheral edge portion 101a may be varied in width in order to adjust an inner size of the inner portion 101b to adapt the inner portion 101b to subsequent processes. Accordingly, in various embodiments, removal of the peripheral edge portion 101a of the molded panel 101 may help to define a cleaner boundary of the inner portion 101b of the molded panel 101 for subsequent handling or processing.

FIG. 3D shows schematically the molded panel 101 (e.g. either adhered on the carrier 103 before being released therefrom or existing independently after being released from the carrier 103) with individual unit regions 101c cut by the cutter 179 either at the cutter workstation 170 or at another workstation as described above, according to various embodiments.

According to various embodiments, with reference to FIG. 3D, the cutter 179 may be configured and/or operable to singulate or cut out a plurality of individual unit regions 101c from the molded panel 101. In other words, in various embodiments, the cutter 179 may cut the molded panel 101 into one or more portions of smaller dimensions (which may be referred to as “Q-panels”).

In various embodiments, after the molded panel 101 has been cut, but before the molded panel 101 is released from the carrier 103, the intermediate panel-carrier assembly 104 may remain intact (or held together), as the Q-panels may still be adhered to the carrier 103 by the thermal release adhesive tape 102.

In various other embodiments, the cutter 179 may be configured and/or operable to cut or singulate the inner portion 101b, in addition to or instead of cutting the peripheral edge portion 101a of the molded panel 101.

In various embodiments, the unit regions 101c may be delineated by predefined singulation lines or cut paths formed within the inner portion 101b of the molded panel 101. According to various embodiments, the cutter 179 may follow a cutting profile that may correspond to the intended outline of each unit region 101c, such that each unit region 101c may be separated (e.g. either individually, or all at once as a group or as a whole) from a remainder of the molded panel 101 upon completion of the cutting operation. As an example, according to various embodiments, the cutting operation may be performed fully through the thickness of the molded panel 101 to enable the individual separation. However, it is also envisaged that, according to various other embodiments, the cutter 179 may be configured to cut partially through the molded panel 101 (e.g. as may be required).

As some non-limiting examples, according to various embodiments, each unit region 101c may correspond to (e.g. correspond to at least a shape or outer border of) one (e.g. for Single-Chip Module or SCM) or more (e.g. for Multi-Chip Module or MCM) dies, chips, device packages, integrated circuits, package units, functional units, and/or any suitable electronic, microelectronic, or optoelectronic units or sub-units or devices, etc.

According to various embodiments, the shape and dimensions of the plurality of unit regions 101c may be identical to each other, or they may differ (e.g. based on varying specifications).

As a non-limiting example, according to various embodiments, the cutter 179 at the cutter workstation 170 or at another workstation as described above may be configured to singulate or cut out a plurality of unit regions 101c (e.g. nine unit regions 101c in a “3×3” array or layout) from the molded panel 101. In various embodiments, the unit regions 101c may be, but are not limited to being, evenly spaced apart from one another across the molded panel 101. In various other embodiments, the layout of the plurality of unit regions 101c may follow a regular grid pattern, staggered layout, or any other predefined or suitable configuration.

FIG. 3F shows schematically an example of the cutter workstation 170 integrated within the processing system 1000, according to various embodiments.

FIG. 3G shows schematically a first example of the cutter workstation 170 linked to the feeder workstation 160, according to various embodiments.

As an illustration, according to various embodiments, with reference to FIG. 3F and FIG. 3G, an intermediate panel-carrier assembly 104 (e.g. a “pre-cut” or uncut intermediate panel-carrier assembly 104) may be initially fed to the feeder workstation 160, where it is disposed on a feeding mechanism 161 with the molded panel 101 facing upward (i.e. at the topside of the intermediate panel-carrier assembly 104). The feeding mechanism 161 may then be configured and/or operable to be movable or moved from the feeder workstation 160 to the cutter workstation 170. For instance, in various embodiments, the feeding mechanism 161 may be configured and/or operable to be movable along the feeding-mechanism-movement plane 161p in lateral or sideways directions between the feeder workstation 160 and the cutter workstation 170. According to various embodiments, movement of the feeding mechanism 161 along the feeding-mechanism-movement plane 161p, between the feeder workstation 160 and the cutter workstation 170, may be based on a movement signal. In various embodiments, this movement signal may be transmitted or provided to the feeding mechanism 161 or to an actuator coupled thereto (e.g. to instruct movement of the feeding mechanism 161).

In various embodiments, at the cutter workstation 170, the cutter 179 may be configured and/or operable to cut the molded panel 101 adhered to the carrier 103 (e.g. while the molded panel 101 of the intermediate panel-carrier assembly 104 is supported on the feeding mechanism 161).

In various other embodiments, the intermediate panel-carrier assembly 104 may be temporarily transferred from the feeding mechanism 161 to a cutting platform 171 (e.g. a cutting deck or stage) (as described below in FIG. 3H) within the cutter workstation 170 for the cutting operation, before being returned to the feeding mechanism 161.

Once the cutting operation is completed, the feeding mechanism 161, carrying the intermediate panel-carrier assembly 104 with the molded panel 101 (e.g. cut into the one or more Q-panels), may convey the intermediate panel-carrier assembly 104 to another workstation, such as the pre-heating workstation 150—according to a processing sequence of the processing system 1000. For example, in various embodiments, the feeding mechanism 161 may first return to or pass through the feeder workstation 160, before continuing its path downstream to the pre-heating workstation 150. As some examples, according to various embodiments, the pre-heating workstation 150 and the cutter workstation 170 may be on opposite sides of the feeder workstation 160, or they may be at orthogonal sides of the feeder workstation 160. Thus, in various embodiments, the directions of movements of the feeding mechanism 161 between the feeder workstation 160 and the cutter workstation 170 may be parallel or perpendicular to the directions of movements of the feeding mechanism 161 between the feeder workstation 160 and the pre-heating workstation 150.

FIG. 3H shows schematically a second example of the cutter workstation 170 linked to the feeder workstation 160, according to various embodiments.

As another example, with reference to FIG. 3H, according to various embodiments, the alignment-head 166 of the feeder workstation 160 may be configured and/or operable to be movable between the feeder workstation 160 and the cutter workstation 170. For instance, the alignment-head 166 may be movable laterally along a “lateral-alignment-unit-actuation-member-movement plane” 166q. In various embodiments, the lateral-alignment-unit-actuation-member-movement plane 166q may be a substantially flat plane which may be substantially horizontally-oriented (e.g. relative to the base of the processing system 1000, and/or when the processing system 1000 is disposed and/or oriented upright on the external floor or ground). According to various embodiments, the lateral-alignment-unit-actuation-member-movement plane 166q may be non-parallel (e.g. perpendicular or substantially perpendicular) to the alignment-unit-actuation-member-movement plane 166p. In various embodiments, the lateral-alignment-unit-actuation-member-movement plane 166q may be, but is not limited to being, parallel with the carrier-support-deck-movement plane 111p. Accordingly, in various embodiments, the alignment-head 166 may be capable and/or operable to be movable in lateral or sideways directions (e.g. opposite linear directions), within or along the lateral-alignment-unit-actuation-member-movement plane 166q, between the feeder workstation 160 and the cutter workstation 170. In various embodiments, the lateral or sideways directions of movements of the alignment-head 166 along the lateral-alignment-unit-actuation-member-movement plane 166q, between the feeder workstation 160 and the cutter workstation 170, may be, but is not limited to being, non-parallel (e.g. perpendicular) with the lateral or sideways directions of movements of the panel-support deck 121 along the panel-support-deck-movement plane 121p (i.e. between the panel-handling workstation 120 and the release workstation 110). As a non-limiting example, according to various embodiments, the processing system 1000 may include a respective (e.g. a respective or discrete) rail, track or slide (e.g. linear rail, track or slide, in other words, a guide element) which may extend between the feeder workstation 160 and the cutter workstation 170, for the alignment-head 166 of the feeder workstation 160 to be movable and/or guided therealong. According to various embodiments, movement of the alignment-head 166 along the lateral-alignment-unit-actuation-member-movement plane 166q may be based on a movement signal. In various embodiments, this movement signal may be transmitted or provided to the alignment-head 166 (e.g. to instruct movement of the alignment-head 166).

Accordingly, in various embodiments, after placement of a “pre-cut” or uncut intermediate panel-carrier assembly 104 onto the feeding mechanism 161 at the feeder workstation 160, the alignment-head 166 may engage with the intermediate panel-carrier assembly 104 (e.g. via the alignment-head-retaining member 168) at the feeder workstation 160, releasably retain and lift the intermediate panel-carrier assembly 104 from the feeding mechanism 161 within the feeder workstation 160, and transport the intermediate panel-carrier assembly 104 laterally from the feeder workstation 160 to the cutter workstation 170.

Further, in various embodiments, at the cutter workstation 170, the alignment-head 166 may be configured to perform alignment and placement of the intermediate panel-carrier assembly 104 relative to the cutting platform 171 (e.g. cutting deck or stage) at either the cutter workstation 170 (e.g. positioned at a lower region within the cutter workstation 170) or at another workstation as described above. In particular, after the alignment-head 166 is aligned with (e.g. directly above or overhead) the cutting platform 171 at the cutter workstation 170, the alignment-head 166 may be movable along the alignment-unit-actuation-member-movement plane 166p to place and release the intermediate panel-carrier assembly 104 having the molded panel 101 onto the cutting platform 171 of the cutter workstation 170.

In various embodiments, the cutting platform 171 of the cutter workstation 170 may include a retaining member 173 (e.g. vacuum suction mechanism, a gripping mechanism, electrostatic chuck, end effector, etc.) which may be configured to releasably secure the molded panel 101 (or, specifically, the carrier 103 and, subsequently or consequently, the molded panel 101 adhered to the carrier 103) in place during the cutting process. According to various embodiments, operation of the retaining member 173 may be based on a retaining-control signal. In various embodiments, this retaining-control signal may be transmitted or provided to the retaining member 173 (e.g. to instruct operation of the retaining member 173).

Consequently, the cutter 179 may perform cutting operations on the molded panel 101 while it is supported on the cutting platform 171.

Once the cutting operation is complete, the alignment-head 166 of the feeder workstation 160 may engage the intermediate panel-carrier assembly 104 with the cut molded panel 101 (e.g. cut into the Q-panels), then lift the intermediate panel-carrier assembly 104 with the cut molded panel 101 away from the cutting platform 171, and subsequently convey the intermediate panel-carrier assembly 104 with the cut molded panel 101 to another workstation (e.g. the pre-heating workstation 150)—according to a processing sequence of the processing system 1000. In various embodiments, the alignment-head 166 may further be configured to transport the intermediate panel-carrier assembly 104 back to the feeder workstation 160 before proceeding to the next workstation (e.g. when the feeder workstation 160 is positioned between the cutter workstation 170 and the next workstation). In other words, in various embodiments, the alignment-head 166 may pass the feeder workstation 160 as it conveys the cut intermediate panel-carrier assembly 104 (e.g. with the molded panel 101 cut into the Q-panels) from the cutter workstation 170 to the pre-heating workstation 150.

As a non-limiting example, according to various embodiments, at least or only an intended (or functional or active) cut portion (or zone) of the molded panel 101—such as the inner portion 101b and/or the individual unit regions 101c (i.e. Q-panels)—may be released from the carrier 103 at the release workstation 110. In other words, in various embodiments, the peripheral edge portion 101a (i.e. separated from the inner portion 101b during cutting), or any remaining portion of the molded panel 101 outside of the individual unit regions 101c (or outside of an intended cut region), may not be released from the carrier 103 at the release workstation 110.

Alternatively, in various other embodiments, the cutter workstation 170 may be positioned outside and/or downstream of the processing system 1000. In these other embodiments, the molded panel 101 may not be cut before it is released from the carrier 103 at the release workstation 110 and may, thus, be released as a whole from the carrier 103 at the release workstation 110. After being transferred or conveyed sequentially out of the release workstation 110 and out of the panel-handling workstation 120, the molded panel 101 (i.e. alone, without the thermal release adhesive tape 102 and the carrier 103) may be conveyed or transported to the cutter workstation 170 (e.g. downstream of the panel-handling workstation 120) and cut in a manner as described above (e.g. into the one or more Q-panels).

FIG. 3E shows schematically a plan view of the release-head 116, having a multi-zone vacuum retention arrangement 190, according to various embodiments.

According to various embodiments, with reference to FIG. 3E, the release-head 116 may include the multi-zone vacuum retention arrangement 190. For instance, with reference to FIG. 3E, the multi-zone vacuum retention arrangement 190 may include a first vacuuming zone 190a at the engagement surface 116a of the release-head 116, a second vacuuming zone 190b at the engagement surface 116a of the release-head 116 (e.g. surrounded or encircled by the first vacuuming zone 190a), and a third vacuuming zone 190c at the engagement surface 116a of the release-head 116 (e.g. surrounded or encircled the second vacuuming zone 190b). As an example, shown in FIG. 3E, each of the first vacuuming zone 190a and the second vacuuming zone 190b may be loop-shaped (e.g. an annular or annular-like shape, or a ring shape, etc., or forming a continuous and/or uninterrupted and/or closed loop). Further, the second vacuuming zone 190b may be between the first vacuuming zone 190a and the third vacuuming zone 190c. It is understood that the multi-zone vacuum retention arrangement 190 may include any other number of vacuuming zones (e.g. two, or more than three vacuuming zones), each of which may be identical or similar to the first vacuuming zone 190a, the second first vacuuming zone 190b, or the third vacuuming zone 190c.

According to various embodiments, the multi-zone vacuum retention arrangement 190 may include primary vacuum ports 191 and auxiliary vacuum ports 192 (e.g. nozzle, hole, orifice, etc.), at the engagement surface 116a of the release-head 116, for picking or retaining the molded panel 103 via vacuum suction. According to various embodiments, each primary vacuum port 191 may have a larger size compared to each auxiliary vacuum port 192. According to various embodiments, each larger-sized primary vacuum port 191 may facilitate a stronger suction force, thereby enabling a more secure retention of the molded panel 103 to the engagement surface 116a of the release-head 116.

As an example, according to various embodiments, the first vacuuming zone 190a may be configured and/or designated for the molded panel 103 (e.g. large and/or uncut or pre-cut molded panel 103, which may be either adhered to or separated from the carrier 103). In various embodiments, the first vacuuming zone 190a may also be configured to engage and/or interface with the peripheral edge portion 101a (e.g. inactive or non-functional zone) of the molded panel 103. In various embodiments, the multi-zone vacuum retention arrangement 190 may include a respective group or subset of the primary vacuum ports 191 and/or a respective group or subset of the auxiliary vacuum ports 192 within the first vacuuming zone 190a at the engagement surface 116a of the release-head 116. In various embodiments, these groups or subsets of the primary vacuum ports 191 and/or the auxiliary vacuum ports 192 may be distributed (e.g. in a spaced apart manner) along loop-shaped first vacuuming zone 190a.

As a further example, according to various embodiments, each of the second vacuuming zone 190b and the third vacuuming zone 190c may be configured and designated for the molded panel 103 having cut (or pre-cut) inner portion 101b or Q-panels. In particular, in various embodiments, each of the second vacuuming zone 190b and the third vacuuming zone 190c may be configured to releasably retain cut (or pre-cut) inner portion 101b or Q-panels of the molded panel 103 to the engagement surface 116a of the release-head 116. Accordingly, in various embodiments, the second vacuuming zone 190b and the third vacuuming zone 190c may be configured to engage and/or interface with the inner portion 101b of the molded panel 101. In various embodiments, the inner portion 101b of the molded panel 101 may have limited spacing between active components (e.g. dies), which may restrict the physical space available for larger vacuum structures. Accordingly, in various embodiments, the multi-zone vacuum retention arrangement 190 may include a respective group or subset of the auxiliary vacuum ports 192 distributed within the second vacuuming zone 190b and another respective group or subset of the auxiliary vacuum ports 192 distributed within the third vacuuming zone 190c. In various embodiments, the second and the third vacuuming zones 190b, 190c may be devoid of larger primary vacuum ports 191, allowing the auxiliary vacuum ports 192 at these zones 190b, 190c to be distributed along the engagement surface 116a of the release-head 116 in a manner which may match a confined layout of the inner portion 101b or the Q-panels of the molded panel 103.

According to various embodiments, each vacuuming zone 190a, 190b, 190c (or the ports 191 and/or 192 of each vacuuming zone 190a, 190b, 190c) may be configured to function independently. For instance, each vacuuming zone 190a, 190b, 190c (or the ports 191 and/or 192 of each vacuuming zone 190a, 190b, 190c) may be associated with its own dedicated vacuum line or conduit. Further, each vacuum line or conduit may be coupled to a dedicated vacuum source or module. For example, with reference to FIG. 3E, each vacuum line or conduit for each vacuuming zone 190a, 190b, 190c may be associated with a respective pump 193a, 193b, 193c (e.g. vacuum pump), a respective valve 194a, 194b, 194c (e.g. solenoid valve), a respective filter 195a, 195b, 195c (e.g. particulate air filter), and a respective sensor 196a, 196b, 196c (e.g. vacuum gauge)—which may cooperatively monitor and control a vacuum level delivered to the corresponding vacuuming zone 190a, 190b, 190c. In other words, in various embodiments, the three vacuuming zones 190a, 190b, 190c may be associated or equipped with their respective and independent vacuuming systems (i.e. respective pump 193a, 193b, 193c, valve 194a, 194b, 194c, filter 195a, 195b, 195c, and sensor 196a, 196b, 196c), which may help ensure operational redundancy and reliability. Accordingly, as an illustration, in various embodiments, if one or two of the three vacuuming zones 190a, 190b, 190c may fail (e.g. due to vacuum loss or mechanical malfunction), a remainder of the vacuuming zones 190a, 190b, 190c may be capable of providing suction to hold the pick or retain the molded panel 103 thereto.

As a non-limiting example, according to various embodiments, the pump 193a associated with the first vacuuming zone 190a (or the ports 191 and/or 192 of the first vacuuming zone 190a) may be configured to deliver greater suction force or higher vacuum pressure than the pumps 193b, 193c associated with the second and the third vacuuming zones 190b, 190c.

It is also envisaged that, according to various embodiments, the multi-zone vacuum retention arrangement 190 may be applicable across different and/or discrete vacuum-based handling components within the processing system 1000. For example, the multi-zone vacuum retention arrangement 190 may be respectively implemented in each of any one or more or all of the carrier-support deck 111, the panel-support deck 121, the panel-handling head 126, the pre-heating deck 151, the pre-heating head 156, the alignment-head 166, and/or the cutting platform 171, and/or any vacuum-holding module that may interface with the molded panel 101 (e.g. as a whole, its inner portion 101b which may be cut from its peripheral edge portion 101a, or its individual unit regions 101c or Q-panels) (e.g. separated from the carrier 103), or with the carrier 103 (e.g. adhered to the carrier 103).

Referring back to FIG. 3D and FIG. 3F, according to various embodiments, when the cutter workstation 170 is configured to singulate or cut out a plurality of the individual unit regions 101c from the molded panel 101, the release-head-retaining member 118 of the release-head 116 at the release workstation 110 may be configured (e.g. positioned, shaped, and/or sized, etc.) to interface with and/or releasably retain only the individual unit regions 101c of the molded panel 101 to the engagement surface 116a of the release-head 116. For instance, the release-head-retaining member 118 may be shaped, sized, and/or positioned, etc., to selectively engage only the individual unit regions 101c, but not a remainder of the molded panel 101 (e.g. remainder of the inner portion 101b of the molded panel 101 outside of and/or between the individual unit regions 101c). Accordingly, in these embodiments, after the thermal release adhesive tape 102 has been heated to the heat release temperature at the release workstation 110, the release-head-retaining member 118 may separate or lift only the individual unit regions 101c of the molded panel 101 away from the carrier-support deck 111 (e.g. either one-by-one in sequence, or all at once as a group or as a whole) and the carrier 103 remaining thereon. In other words, in various embodiments, the cut portion of the molded panel 101 (e.g. the inner portion 101b as a whole, or each Q-panel) may be released or detached from the carrier 103. In various embodiments, the remainder of the molded panel 101 left on the carrier-support deck 111 may be selectively removed from the processing system 1000 at the release workstation 110 or may be handled, processed and/or output together with the carrier 103 (e.g. through the offload workstation 140).

Similarly, in various embodiments, when the cutter workstation 170 is configured to singulate or cut out a plurality of the individual unit regions 101c (i.e. Q-panels) from the molded panel 101, each of the panel-support-deck-retaining member 123 and/or the panel-handling-head-retaining member 128 may be configured (e.g. positioned, shaped, and/or sized, etc.) to interface with and/or releasably retain only the individual unit regions 101c of the molded panel 101 (e.g. either one-by-one in sequence, or all at once as a group or as a whole). For instance, when each of the panel-support-deck-retaining member 123 and/or the panel-handling-head-retaining member 128 includes vacuum suction holes serving as the respective retaining members, the layout and/or position of these vacuum suction holes may correspond to (e.g. may match) a layout and/or position of the plurality of individual unit regions 101c of the molded panel 101 cut into the Q-panels (e.g. as it is conveyed or transported through/downstream of the processing system 1000).

Referring back to FIG. 3A, according to various embodiments, the control unit 180 of the processing system 1000 may be configured to transmit the various signals (or instructions or commands)—such as the movement signals and/or control signals (e.g. heating-control signal, temperature-regulation-control signal, pre-heating-control signal, retaining-control signal, cutter-control signal)—to the respective workstations and/or respective components within the processing system 1000. Accordingly, in various embodiments, the control unit 180 may be communicatively coupled to the respective workstations and/or components within the processing system 1000 so as to be capable of instructing and/or controlling operation of these workstations and/or components. As an example, according to various embodiments, each or any movable component of the processing system 1000 may be actuated or movable via a corresponding or respective actuator which may be controllable by the control unit 180.

FIG. 4 shows a schematic perspective diagram of a processing system (or a panel release system) 4000, according to various embodiments.

According to various embodiments, the processing system 4000 may include any one or more or all features of the processing system 1000 and/or 2000, and vice versa.

According to various embodiments, the processing system 4000 may differ from the processing system 2000 of FIG. 2A in that the processing system 4000 may (e.g. optionally) further include a cutter workstation 470, which may include any one or more or all features of the cutter workstation 170.

According to various embodiments, the cutter workstation 470 may be upstream (e.g. immediately or indirectly upstream) of the release workstation 210.

According to various embodiments, the processing system 4000 may include a conveying mechanism 4001 that may be operable to transfer the intermediate panel-carrier assembly 104 (e.g. with its molded panel 103 cut, for example, with at least one individual unit region 101c) to the carrier-support deck 111 positioned within the release workstation 210. In various embodiments, the conveying mechanism 4001 may include one or more movable decks and/or actuation members of the processing system 4000.

As an example, with reference to FIG. 4, the cutter workstation 470 may be linked to the feeder workstation 260 in a manner such that when the intermediate panel-carrier assembly 104 is fed or input into the processing system 4000 at the feeder workstation 260, it may be conveyed from the feeder workstation 260 to (e.g. directly to) the cutter workstation 470 for the cutting operation described above to be performed on the molded panel 101 of the intermediate panel-carrier assembly 104. For example, both the cutter workstation 470 and the pre-heating workstation 250 may be linked (e.g. directly linked) with the feeder workstation 260, at different sides or faces of the feeder workstation 260, as shown in FIG. 4. As a non-limiting example, the cutter workstation 470 may be directly linked with the feeder workstation 260 via an alignment-head of the feeder workstation 260 (e.g. similar or identical to the alignment-head 166 of FIG. 3H) which may be laterally movable between the feeder workstation 260 and the cutter workstation 470. On the other hand, the pre-heating workstation 250 may be directly linked with the feeder workstation 260 via a feeding mechanism of the feeder workstation 260 (e.g. similar or identical to the feeding mechanism 161 of FIG. 3H) which may be movable between the feeder workstation 260 and the pre-heating workstation 250.

Thereafter, the molded panel 101 (e.g. cut into the Q-panels adhered on the carrier 103) may be conveyed from the cutter workstation 470 to the pre-heating workstation 250 (e.g. by moving or passing through the feeder workstation 260 to reach the pre-heating workstation 250) for a pre-heating operation to be performed on the intermediate panel-carrier assembly 104 (e.g. with the Q-panels of the molded panel 101). According to various embodiments, both the pre-heating workstation 250 and the cutter workstation 470 may be linked to the feeder workstation 260, for example with the feeder workstation 260 between the pre-heating workstation 250 and the cutter workstation 470. However, it is also envisaged that, in various other embodiments, any other suitable arrangement of the cutter workstation 470 may be implemented. For instance, in various other embodiments (not shown), the cutter workstation 470 may be immediately downstream of the feeder workstation 260, while the pre-heating workstation 250 may be immediately downstream of the cutter workstation 470. As another example, according to various other embodiments (not shown), the cutter workstation 470 may be immediately upstream of the release workstation 210.

After the pre-heating operation has been performed on the intermediate panel-carrier assembly 104 (e.g. having the Q-panels of the molded panel 101), the intermediate panel-carrier assembly 104 may be conveyed from the pre-heating workstation 250 to the release workstation 210 for a release operation to be performed on the intermediate panel-carrier assembly 104. At the release workstation 210, the molded panel 101 (e.g. either as a whole or in the form of the Q-panels) may be separated (e.g. detached) from the thermal release adhesive tape 102 and the carrier 103. In various embodiments, when the cutter workstation 470 has cut out individual unit regions 101c (i.e. Q-panels) of the molded panel 101, separating of the molded panel 101 from the thermal release adhesive tape 102 and the carrier 103 at the release workstation 210 may involve separating only the individual unit regions 101c of the molded panel 101 (e.g. either one-by-one in sequence, or all at once as a group or as a whole) from the thermal release adhesive tape 102 and the carrier 103.

Thereafter, the separated molded panel 101 or the Q-panels thereof may be conveyed to the panel-handling workstation 220, while the thermal release adhesive tape 102, the carrier 103 and/or any remaining portion of the molded panel 101 thereon may be conveyed to the carrier-handling workstation 230 before being offloaded via the offload workstation 240.

As shown in FIG. 4, the processing system 4000 may further include a control unit 480, which may include any one or more or all features of the control unit 180. In various embodiments, the control unit 480 may be configured to transmit the various signals (or instructions or commands)—such as the movement signals and/or control signals (e.g. heating-control signal, temperature-regulation-control signal, pre-heating-control signal, retaining-control signals, cutter control signals)—to the respective workstations and/or respective components within the processing system 4000. Accordingly, in various embodiments, the control unit 480 may be communicatively coupled to the respective workstations and/or respective components within the processing system 4000 for controlling operation of these workstations and/or respective components. In various embodiments, each movable component of the processing system 4000 may be actuated or movable via a corresponding or respective actuator which may be controllable and/or operable by the control unit 480.

According to various embodiments, the processing system 4000 (and/or its constituent workstation(s), such as the release workstation 210, the panel-handling workstation 220, the carrier-handling workstation 230, the offload workstation 240, the pre-heating workstation 250, the feeder workstation 260, and/or the cutter workstation 470) may be implemented in a modular architecture. For instance, any one or more suitable workstations may be omitted, repositioned, or substituted, etc., as required.

According to various embodiments, there may be provided a method of processing (e.g. automated processing) of the intermediate panel-carrier assembly 104 or the molded panel 101 (e.g. either as a whole or in the form of the Q-panels) (e.g. with or using the processing systems 1000, 2000, 4000). In various embodiments, the method may include heating the intermediate panel-carrier assembly 104 (i.e. which includes the molded panel 101 attached to the carrier 103 via the thermal release adhesive tape 102)—with the intermediate panel-carrier assembly 104 in an orientation with the molded panel 101 at the topside—while being supported or disposed on the deck surface 111a of the carrier-support deck 111, via (or using) the heater 112 of the carrier-support deck 111 (e.g. within or at the release workstation 110) to the heat release temperature of the thermal release adhesive tape 102. In various embodiments, the method may include moving the release-head 116 towards the intermediate panel-carrier assembly 104 on the deck surface 111a of the carrier-support deck 111 to engage the molded panel 101 of the intermediate panel-carrier assembly 104. In particular, the method may include moving the release-head 116 of the release unit 115 of the release workstation 110 towards the deck surface 111a of the carrier-support deck 111 to engage the intermediate panel-carrier assembly 104 on the deck surface 111a of the carrier-support deck 111, when the carrier-support deck 111 is aligned with the release-head 116 within the release workstation 110. In various embodiments, the method may further include, thereafter, using the release-head 116 to releasably retain the molded panel 101 to the engagement surface 116a of the release-head 116 and moving the release-head 116 away from the deck surface 111a of the carrier-support deck 111, with the release-head-retaining member 118 releasably securing the molded panel 101 (e.g. only the molded panel 101, for example, either as a whole or in the form of the Q-panels) to the engagement surface 116a of the release-head 116 (i.e. after the heater 112 has heated the intermediate panel-carrier assembly 104 to the heat release temperature, for the predetermined duration), thereby separating (e.g. detaching) the molded panel 101 from the carrier 103 (e.g. such that the molded panel 101 may be at the engagement surface 116a of the release-head 116, and the thermal release adhesive tape 102 and the carrier 103 may be or may remain on the deck surface 111a of the carrier-support deck 111). Accordingly, according to various embodiments, at least the thermal release adhesive tape 102 and the carrier 103 (i.e. not lifted by the release-head 116) may remain on the carrier-support deck 111. In various embodiments, this operation may be referred to as a “release operation” or a “heating-and-release operation”.

In various embodiments, the method (or the heating-and-release operation) may further include using the heater 117 of the release-head 116 to cooperatively heat the intermediate panel-carrier assembly 104—together with the heater 112 of the carrier-support deck 111—to the heat release temperature (e.g. for the predetermined duration), before (or prior to) separating (e.g. detaching) the molded panel 101 from the thermal release adhesive tape 102 and the carrier 103. In various embodiments, this cooperative heating may be performed within the release workstation 110.

According to various embodiments, the method may further include moving or positioning the panel-support deck 121 into or within the release workstation 110, to align with the release-head 116 within the release workstation 110, to receive the separated molded panel 101 (e.g. either as a whole or in the form of the Q-panel) from the release-head 116. In various embodiments, this may be performed after the heating-and-release operation has been completed. Thereafter, the method may include moving the panel-support deck 121, with the separated molded panel 101 supported thereon, to the panel-handling workstation 120, thereby conveying the separated molded panel 101 from the release workstation 110 to the panel-handling workstation 120.

In various embodiments, the method may further include regulating a temperature of the separated molded panel 101 between the heat release temperature and the ambient temperature using the temperature-regulating heater 122 of the panel-support deck 121, with the separated molded panel 101 supported on the panel-support deck 121 and/or while the panel-support deck 121 conveys or moves the separated molded panel 101 from the release workstation 110 to the panel-handling workstation 120. In various embodiments, this operation may be referred to as a “temperature-regulation operation”. Accordingly, in various embodiments, the temperature-regulation operation may be performed after the heating-and-release operation.

In various embodiments, the method may further include using the panel-handling head 126 to engage and/or releasably retain the separated molded panel 101 to the engagement surface 126a of the panel-handling head 126 (e.g. within the panel-handling workstation 120). In particular, the panel-handling head 126 may lift the separated molded panel 101 from the panel-support deck 121 (e.g. at the panel-handling workstation 120) and may, thereafter, transfer the molded panel 101 out of the processing system 1000.

In various embodiments, the method (or the temperature-regulation operation) may further include regulating a temperature of the separated molded panel 101 between the heat release temperature and the ambient temperature using the temperature-regulating heater 127 of the panel-handling head 126, when the panel-handling head 126 is engaged with and/or releasably retaining the separated molded panel 101 to its engagement surface 126a. In various embodiments, this may be performed separately from the temperature-regulation operation which may be performed by the temperature-regulating heater 122 of the panel-support deck 121. In other words, in various embodiments, temperature-regulation by the temperature-regulating heater 127 of the panel-handling head 126 may be performed after the separated molded panel 101 is lifted away from the panel-support deck 121 by the panel-handling head 126.

In various embodiments, the method may further include moving the carrier-support deck 111 (i.e. with the thermal release adhesive tape 102 and the carrier 103 remaining and/or supported thereon) from the release workstation 110 to the carrier-handling workstation 130, thereby conveying the thermal release adhesive tape 102 and carrier 103 from the release workstation 110 to the carrier-handling workstation 130. Thus, in various embodiments, this may be performed after the molded panel 101 has been separated from the thermal release adhesive tape 102 and the carrier 103 at the release workstation 110. Thereafter, the method may further include using the carrier-handling head 136 to engage and/or releasably retain the thermal release adhesive tape 102 and the carrier 103 to the engagement surface 136a of the carrier-handling head 136 and/or lifting the thermal release adhesive tape 102 and the carrier 103 away from the carrier-support deck 111 (e.g. at the carrier-handling workstation 130). Thereafter, in various embodiments, the carrier-support deck 111 (i.e. without the thermal release adhesive tape 102 and the carrier 103 thereon) may be moved out of the carrier-handling workstation 130 (e.g. back to the release workstation 110).

In various embodiments, at the carrier-handling workstation 130, and before the thermal release adhesive tape 102 and the carrier 103 is engaged with and/or lifted by the carrier-handling head 136, the method may include (e.g. optionally and/or further include) using the adhesive-removal tool 131 to remove the thermal release adhesive tape 102 that remains on the carrier 103. In various embodiments, this operation may be referred to as an “adhesive-removal operation”. In various embodiments, the adhesive-removal operation may be performed on the carrier 103 and the remaining thermal release adhesive tape 102 after the heating-and-release operation has been performed.

In various embodiments, the method may further include moving or positioning the offload tray 141 into or within the carrier-handling workstation 130, to align with the carrier-handling head 136 (i.e. releasably holding the separated carrier 103) within the carrier-handling workstation 130, to receive the carrier 103 from the carrier-handling head 136. Thereafter, the method may include moving the offload tray 141, with the carrier 103 disposed thereon by the carrier-handling head 136, to the offload workstation 140 (e.g. for transferring the carrier 103 out of the processing system 1000).

In various embodiments, the method may further include pre-heating the intermediate panel-carrier assembly 104 before (e.g. immediately before) the heating-and-release operation. In particular, the method may include initially disposing or placing the intermediate panel-carrier assembly 104 onto the pre-heating deck 151 and using the pre-heating heater 152 of the pre-heating deck 151 to pre-heat the intermediate panel-carrier assembly 104 to the intermediate temperature below the heat release temperature. In various embodiments, this operation may be referred to as a “pre-heating operation”. In various embodiments, the pre-heating deck 151, with the intermediate panel-carrier assembly 104 supported thereon, may be moved from the pre-heating workstation 150 to the release workstation 110. In various embodiments, the pre-heating operation may be performed at the pre-heating workstation 150 (e.g. with the cooperation of the pre-heating deck 151 and the pre-heating head 156) and/or may be performed while the pre-heating deck 151 is moved from the pre-heating workstation 150 to the release workstation 110 (e.g. by the pre-heating deck 151 alone).

In various embodiments, the method (or the pre-heating operation) may further include using the pre-heating heater 157 of the pre-heating head 156 to cooperatively pre-heat the intermediate panel-carrier assembly 104—together with the pre-heater of the pre-heating deck 151—within the pre-heating workstation 150.

In various embodiments, before the heating-and-release operation, the method may further include using the control unit 180 of the processing systems 1000, 2000 (or the control unit 480 of the processing system 4000) to control (e.g. direct or indirect) performance of a mechanical action (or to cause a mechanical action to be performed) on the intermediate panel-carrier assembly 104 (or at least the thermal release adhesive tape 102 of the intermediate panel-carrier assembly 104) to disturb and/or to weaken an adhesive bond or adhesive strength of the thermal release adhesive tape 102 between the carrier 103 and the molded panel 101 of the intermediate panel-carrier assembly 104. In various embodiments, this operation may be referred to as a “release-initiation operation”. As some examples, according to various embodiments, the release-initiation operation may be initiated or performed immediately before the heating-and-release operation or before (or prior to) the pre-heating operation.

In various embodiments, the method (or the release-initiation operation) may include moving the carrier-support deck 111 relative to the release-head 116, while the release-head-retaining member 118 releasably retains the molded panel 101 of the intermediate panel-carrier assembly 104 to the engagement surface 116a of the release-head 116 and while the carrier-support-deck-retaining member 113 releasably retains the thermal release adhesive tape 102 and the carrier 103 of the intermediate panel-carrier assembly 104 to the deck surface 111a of the carrier-support deck 111. According to various embodiments, this may occur within the release workstation 110.

In various embodiments, the method (or the release-initiation operation) may include cutting the peripheral edge portion 101a and/or individual unit regions 101c of the molded panel 101 (e.g. using the cutter 179 of the cutter workstation 170). Thereafter, the cut molded panel 101 (e.g. with the cut peripheral edge portion 101a and/or cut into Q-panels), which may still remain adhered to the carrier 103 by the thermal release adhesive tape 102, may be conveyed or moved to another workstation (e.g. the pre-heating workstation 150, for further processing).

In various embodiments, the method may include initially feeding the intermediate panel-carrier assembly 104 into the processing system 1000 via the feeder workstation 160. In particular, according to various embodiments, the method may include feeding or inputting the intermediate panel-carrier assembly 104 to the cutter workstation 170, the pre-heating workstation 150, or the release workstation 110 (e.g. based on the overall setup of the processing system 1000 and/or process), via the feeder workstation 160.

In various embodiments, the method may involve conveying the intermediate panel-carrier assembly 104, the molded panel 101 (e.g. either as a whole or in the form of the Q-panels), and carrier 103 (e.g. either alone or together with the thermal release adhesive tape 102 adhered thereon) through (e.g. downstream of) the processing system 1000 via one or more movable decks and/or actuation members of the processing system 1000.

FIG. 5A to FIG. 5F show schematic diagrams of a first releasing process 300 and a second releasing process 320, according to various embodiments.

FIG. 5A shows that multiple semiconductor dies or chips 302 may be mounted on a first carrier 306. Subsequently, a first molding layer 304 may be formed via a first molding process for encapsulating the semiconductor dies 302. Accordingly, a first molded panel 301a may be formed, in which the first molded panel 301a may include both the semiconductor dies 302 and the first molding layer 304.

According to various embodiments, a first heat release tape 308 may previously or initially be applied onto the first carrier 306 for adhering the semiconductor dies 302 in place (e.g. so that they do not move during the first molding process). In particular, the first heat release tape 308 may include a heat-sensitive layer (e.g. similar or identical to the heat-sensitive layer 102a shown in FIG. 1A) and a pressure-sensitive layer (e.g. similar or identical to the pressure-sensitive layer 102b shown in FIG. 1A) opposing to or opposite each other. According to various embodiments, in this stage, the first heat release tape 308 may be applied in such a way that the heat-sensitive layer and the pressure-sensitive layer may be in contact with and adhered to the carrier 306 and the first molded panel 301a, respectively.

In various embodiments, the first molded panel 301a may have a panel size smaller than a tape size of the first heat release tape 308 so that a peripheral potion 3082 of the first heat release tape 308 may not be in contact with the first molded panel 301a.

Accordingly, in various embodiments, a first intermediate panel-carrier assembly 504a may be formed, in which the first intermediate panel-carrier assembly may include the first molded panel 301a, the first carrier 306 and the first heat release tape 308.

FIG. 5B shows the first releasing process 300 during which the first intermediate panel-carrier assembly 504a may be heated at a first heat release temperature of the first heat release tape 308. Under the first heat release temperature, the heat-sensitive layer may lose its adhesivity or adhesiveness to the first carrier 306 while the pressure-sensitive layer may still remain or be adhered to the first molded panel 301a. Accordingly, the first molded panel 301a together with the first heat release tape 308 adhered thereto may be released or detached from the first carrier 306, as depicted in FIG. 5B.

FIG. 5C shows the first heat release tape 308 in the process of being removed from the first molded panel 301a. According to various embodiments, the molded panel 101 may initially or first be flipped with its active panel surface 3012 facing upward. Then, a pushing pin 310 (or other suitable mechanics, such as a rod or a bar) which may be movable upwardly and downwardly may be used to push the peripheral potion 3082 of the first heat release tape 308 to create a raised segment 312, since the peripheral potion 3082 may not be engaged with nor blocked by the first molded panel 301a. Subsequently, an adhesive-removal tool 314 (e.g. which may operate similarly or identically to the adhesive-removal tool 131 as described above) may be configured to grip the raised segment 312 and then peel the first heat release tape 308 away from and across the first molded panel 301a until the first heat release tape 308 is completely removed from the first molded panel 301a. Accordingly, the active panel surface 3012 of the first molded panel 301a may be exposed for subsequent processes.

FIG. 5D shows the first molded panel 301a subsequently mounted on a second carrier 322 with the active panel surface 3012 facing away therefrom. A second heat release tape 324 similar to the first heat release tape 308 may be applied to the second carrier 322. However, in this stage, the second heat release tape 324 may be applied in a contrasting (or inverse or opposite) manner to that of the first heat release tape 308 as described in FIG. 5A, with its heat-sensitive layer and pressure-sensitive layer in contact with and adhered to the first molded panel 301a and the carrier 322, respectively. Then, panel-level circuits 326 are formed at the active panel surface 3012 of the first molded panel 301a.

FIG. 5E shows a second molding layer 328 formed via a second molding process for encapsulating the semiconductor dies 302, the first molding layer 304 and the panel-level circuits 326. Accordingly, a second intermediate panel-carrier assembly 504b may be formed. The second intermediate panel-carrier assembly 504b may include a second molded panel 301b (including the first molded panel 301a, the panel-level circuits 326 and the second molding layer 328), the second carrier 322 and the second heat release layer 324. According to various embodiments, the second intermediate panel-carrier assembly 504b may correspond to the intermediate panel-carrier assembly 104 described above with reference to FIG. 1A to FIG. 4.

FIG. 5E shows the second releasing process 320 during which the second intermediate panel-carrier assembly 504b may be heated at a second heat release temperature of the second heat release tape 324. Under the second heat release temperature, the heat-sensitive layer may lose its adhesivity or adhesiveness to the second molded panel 301b while the pressure-sensitive layer may still remain or be adhered to the second carrier 322. Accordingly, the second molded panel 301b may be released or detached from both the second carrier 322 and the second heat release tape 334.

Subsequently, the second heat release tape 334 may be detached or removed from the second carrier 332, for example, by applying a force (such as a lateral force, according to a peeling motion) to the second heat release tape 334. However, in various embodiments, the second heat release tape 334 may have a tape size equal or substantially equal to a carrier size of the second carrier 322. In other words, the second heat release tape 334 may fully or substantially fully cover the second carrier 322. Accordingly, in these embodiments, there may not be any second heat release tape 334 extending out of the edges of the second carrier 322 (e.g. such as a feature similar to the peripheral potion 3082 of the first heat release tape 308, described earlier with reference to FIG. 5C). Therefore, in various embodiments, it may not be possible nor feasible to remove the second heat release tape 324 with the pushing pin 310 as described previously in FIG. 5C. In various embodiments, to solve this issue, the separation-facilitating tool 132 (as described in previously in FIG. 1H) may be used to create the raised segment 1026 for initiating or facilitating the removal of the second heat release tape 334. Accordingly, the release workstation 110—and the processing systems 1000, 2000, 4000 which may include the release workstation 110, and all the methods associated with (e.g. of operating) the release workstation 110 and the respective or corresponding processing systems 1000, 2000, 4000—as described above may be particularly well-suited for removing the second heat release tape 324 (i.e. corresponding to the thermal release adhesive tape 102) from the second carrier 322 (i.e. corresponding to the carrier 103), for the second releasing process 320 (i.e. following FIG. 5F).

While the invention has been particularly shown and described with reference to specific embodiments, it should be understood by those skilled in the art that various changes, modification, variation in form and detail may be made therein without departing from the scope of the invention as defined by the appended claims. The scope of the invention is thus indicated by the appended claims and all changes which come within the meaning and range of equivalency of the claims are therefore intended to be embraced.

1. A release workstation for processing an intermediate panel-carrier assembly, comprising:
a carrier-support deck comprising
a deck surface capable of supporting the intermediate panel-carrier assembly thereon, the intermediate panel-carrier assembly comprising a molded panel attached to a carrier via a thermal release adhesive tape, and
a release-deck-heater associated with the deck surface and operable to heat the intermediate panel-carrier assembly to a heat release temperature of the thermal release adhesive tape of the intermediate panel-carrier assembly, when the intermediate panel-carrier assembly is supported on the deck surface; and
a release unit comprising
a release-head movable towards the deck surface of the carrier-support deck to engage the molded panel of the intermediate panel-carrier assembly on the deck surface, wherein the release-head comprises
a release-head-retaining member configured to releasably retain the molded panel to an engagement surface of the release-head, when the release-head is moved to engage with the separated molded panel,
wherein the release-head is further movable away from the deck surface of the carrier-support deck, with the release-head-retaining member of the release-head releasably retaining the molded panel to the engagement surface of the release-head, after the release-deck-heater of the carrier-support deck has heated the intermediate panel-carrier assembly to the heat release temperature, thereby separating the molded panel from the carrier such that the separated molded panel is at the engagement surface of the release-head and the carrier with the thermal release adhesive tape on the deck surface of the carrier-support deck.

2. The release workstation of claim 1,
wherein the release-head further comprises
a release-head-heater associated with the engagement surface of the release-head and operable to cooperatively heat the intermediate panel-carrier assembly together with the release-deck-heater of the carrier-support deck, when the intermediate panel-carrier assembly is sandwiched between the carrier-support deck and the release-head.

3. The release workstation of claim 1, further comprising:
an adhesive-removal tool operable to remove the thermal release adhesive tape, wherein the adhesive-removal tool further comprises
a separation-facilitating tool configured to induce a raised segment of the thermal release adhesive tape, and
an attachment mechanism configured to hold the raised segment for initiating removal of the thermal release adhesive tape.

4. The release workstation of claim 3, wherein
the separation-facilitating tool is configured to move laterally against a peripheral portion of the thermal release adhesive tape for inducing formation of the raised segment of the thermal release adhesive tape.

5. The release workstation of claim 1, wherein
the thermal release adhesive tape comprises a heat-sensitive layer and a pressure-sensitive layer, and
the thermal release adhesive tape is configured to be sandwiched between the molded panel and the carrier in a manner such that the heat-sensitive layer and the pressure-sensitive layer are adhered to the molded panel and the carrier, respectively.

6. A panel release system for processing an intermediate panel-carrier assembly, comprising:
the release workstation of claim 1;
a panel-handling workstation capable of receiving the separated molded panel from the release workstation, the panel-handling workstation comprising
a panel-support deck movable between the panel-handling workstation and the release workstation,
wherein, when the panel-support deck is positioned within the release workstation to align with the release-head of the release unit of the release workstation, the release-head is operable to release the separated molded panel onto the panel-support deck,
wherein, with the separated molded panel released onto the panel-support deck at the release workstation, the panel-support deck is operable to be moved from the release workstation to the panel-handling workstation, thereby conveying the separated molded panel from the release workstation to the panel-handling workstation; and
a panel-handling unit comprising
a panel-handling head movable towards the panel-support deck, when the panel-support deck is within the panel-handling workstation with the separated molded panel thereon, to engage the separated molded panel, the panel-handling head comprising
a panel-handling-head-retaining member configured to releasably retain the separated molded panel to an engagement surface of the panel-handling head of the panel-handling unit, when the panel-handling-head is moved to engage with the separated molded panel, and moving the separated molded panel, releasably retained thereto, away from the panel-support deck for transferring the separated molded panel out of the panel release system.

7. The panel release system of claim 6,
wherein the panel-handling head further comprises a temperature-regulating heater associated with the engagement surface of the panel-handling head,
wherein the temperature-regulating heater is operable to regulate a temperature of the separated molded panel between the heat release temperature and an ambient temperature, when the engagement surface of the panel-handling head is engaged with the separated molded panel.

8. The panel release system of claim 6,
wherein the panel-support deck comprises
a deck surface for supporting the separated molded panel thereon, and
a heater associated with the deck surface of the panel-support deck and operable to maintain a temperature of the separated molded panel between the heat release temperature and an ambient temperature, when the separated molded panel is supported on the deck surface of the panel-support deck.

9. The panel release system of claim 6, further comprising:
a carrier-handling workstation;
wherein the carrier-support deck is movable between the release workstation and the carrier-handling workstation;
wherein the carrier-handling workstation comprises
a carrier-handling unit which includes
a carrier-handling head movable towards the carrier-support deck to engage the carrier, when the carrier-support deck with the carrier thereon is positioned within the carrier-handling workstation to align with the carrier-handling head, wherein the carrier-handling head comprises
a carrier-handling-head-retaining member configured to releasably retain the carrier to an engagement surface of the carrier-handling head, when the carrier-handling-head is moved to engage with the carrier, and moving the carrier, releasably retained thereto, away from the carrier-support deck.

10. The panel release system of claim 9, further comprising:
an offload tray that is movable into the carrier-handling workstation to receive the carrier from the carrier-handling head, when the offload tray is aligned with the carrier-handling head within the carrier-handling workstation, and movable out of the carrier-handling workstation after receiving the carrier from the carrier-handling head for transferring the carrier out of the panel release system.

11. The panel release system of claim 9,
wherein the thermal release adhesive tape remains on the carrier after the molded panel is separated from the carrier at the release workstation;
wherein the carrier-handling workstation further comprises
an adhesive-removal tool operable to remove a remaining thermal release adhesive tape from the carrier, when the carrier-support deck supporting the carrier with the remaining thermal release adhesive tape is positioned within the carrier-handling workstation together with the adhesive-removal tool, prior to the carrier-handling head releasably retaining and moving the carrier away from the carrier-support deck,
wherein the adhesive-removal tool is movable between a first edge portion of the carrier and a second edge portion of the carrier, while the adhesive-removal tool engages a peripheral portion of the thermal release adhesive tape, to remove the thermal release adhesive tape across the carrier from the first edge portion to the second edge portion.

12. The panel release system of claim 11,
wherein the adhesive-removal tool comprises a clamping mechanism to grip the peripheral portion of the thermal release adhesive tape.

13. The panel release system of claim 9,
wherein the panel-support deck is movable along a panel-support-deck-movement plane,
wherein the carrier-support deck is movable along a carrier-support-deck-movement plane,
wherein the carrier-support deck and the panel-support deck are movable in a synchronous manner and in non-parallel directions to each other, along the carrier-support-deck-movement plane and the panel-support-deck-movement plane, respectively.

14. The panel release system of claim 13,
wherein the carrier-support-deck-movement plane is parallel to the panel-support-deck-movement plane.

15. The panel release system of claim 6, further comprising:
a cutter workstation upstream of the release workstation and operable to process the intermediate panel-carrier assembly prior to transferring the intermediate panel-carrier to the release workstation, the cutter workstation comprising
a cutter operable to cut at least one individual unit region from the molded panel; and
a conveying mechanism that is operable to transfer the intermediate panel-carrier assembly with the molded panel cut with at least one individual unit region to the carrier-support deck positioned within the release workstation for the release-deck-heater of the carrier-support deck to heat the intermediate panel-carrier assembly to the heat release temperature.

16. The panel release system of claim 6, further comprising:
a pre-heating workstation upstream of the release workstation, the pre-heating workstation comprising
a pre-heating deck comprising
a deck surface capable of supporting the intermediate panel-carrier assembly thereon in the orientation with the molded panel at a topside, and
a pre-heating heater of the pre-heating deck associated with the deck surface and operable to pre-heat the intermediate panel-carrier assembly to an intermediate temperature below the heat release temperature, when the intermediate panel-carrier assembly is on the deck surface of the pre-heating deck,
wherein the pre-heating deck is movable from the pre-heating workstation to the release workstation to convey the intermediate panel-carrier assembly from the pre-heating workstation to the release workstation,
wherein, when the pre-heating deck with the intermediate panel-carrier assembly thereon is moved from the pre-heating workstation into the release workstation, to align with the release-head of the release workstation, the release-head is movable towards the pre-heating deck to engage the intermediate panel-carrier assembly, releasably retain the intermediate panel-carrier assembly to the engagement surface of the release-head, and to move the intermediate panel-carrier assembly away from the pre-heating deck for the release-head to subsequently release the intermediate panel-carrier assembly onto the carrier-support deck when the carrier-support deck is aligned with the release-head within the release workstation.

17. The panel release system of claim 16, wherein the pre-heating workstation further comprises
a pre-heating unit which includes
a pre-heating head movable towards the deck surface of the pre-heating deck to engage the intermediate panel-carrier assembly thereon, when the pre-heating deck with the intermediate panel-carrier assembly thereon is positioned within the pre-heating workstation and aligned with the pre-heating head, the pre-heating head comprising
a pre-heating heater of the pre-heating head associated with an engagement surface of the pre-heating head and operable to cooperatively heat the intermediate panel-carrier assembly together with the pre-heating heater of the pre-heating deck, when the intermediate panel-carrier assembly is between the pre-heating deck and the pre-heating head.

18. The panel release system as claimed in claim 17, further comprising:
a feeder workstation comprising
a feeding mechanism capable of receiving and supporting the intermediate panel-carrier assembly thereon,
wherein the feeding mechanism is movable from the feeder workstation to the pre-heating workstation to convey the intermediate panel-carrier assembly from the feeder workstation to the pre-heating workstation;
wherein the pre-heating head further comprises a pre-heating-head-retaining member configured to releasably retain the intermediate panel-carrier assembly to the engagement surface of the pre-heating head of the pre-heating unit, when the pre-heating head is moved to engage with the intermediate panel-carrier assembly,
wherein, when the feeding mechanism with the intermediate panel-carrier assembly thereon is moved from the feeder workstation into the pre-heating workstation, to align with the pre-heating head of the pre-heating workstation, the pre-heating head is movable towards the feeding mechanism to engage the intermediate panel-carrier assembly, releasably retain the intermediate panel-carrier assembly to the engagement surface of the pre-heating head, and move the intermediate panel-carrier assembly away from the feeding mechanism for the pre-heating head to subsequently release the intermediate panel-carrier assembly onto the pre-heating deck when the pre-heating deck is aligned with the pre-heating head within the pre-heating workstation.

19. A method of operating the panel release system of claim 6, comprising:
heating, via the release-deck-heater associated with the deck surface of the carrier-support deck, the intermediate panel-carrier assembly, when the intermediate panel-carrier assembly is supported on the deck surface of the carrier-support deck, wherein the intermediate panel-carrier assembly is heated to the heat release temperature of the thermal release adhesive tape;
moving the release-head of the release unit of the release workstation towards the deck surface of the carrier-support deck to engage the intermediate panel-carrier assembly on the deck surface of the carrier-support deck, when the carrier-support deck is aligned with the release-head within the release workstation, and releasably retaining the molded panel to the engagement surface of the release-head; and
moving the release-head with the molded panel releasably retained thereto, away from the deck surface of the carrier-support deck, after the release-deck-heater of the carrier-support deck has heated the intermediate panel-carrier assembly to the heat release temperature, thereby separating the molded panel from the carrier such that the separated molded panel is at the engagement surface of the release-head and the carrier with the thermal release adhesive tape on the deck surface of the carrier-support deck.

20. The method of operating the panel release system of claim 19, further comprising:
positioning the panel-support deck within the release workstation to align with the release-head, having the separated molded panel releasably retained to the engagement surface of the release-head, and thereafter, releasing the separated molded panel from the release-head onto the deck surface of the panel-support deck, and thereafter,
moving the panel-support deck, with the separated molded panel thereon, from the release workstation to the panel-handling workstation, and thereafter,
moving the panel-handling head of the panel-handling unit of the panel-handling workstation towards the deck surface of the panel-support deck to engage the separated molded panel on the deck surface of the panel-support deck, when the panel-support deck is aligned with the panel-handling head within the panel-handling workstation, and releasably retaining the separated molded panel to the engagement surface of the panel-handling head for transferring the separated molded panel out of the panel release system via the panel-handling head.
